(19) United States
(12) Patent Application Publication
(10) Pub. No.: US 2024/0118508 A1
(43) Pub. Date: Apr. 11, 2024

(54) MICRO LED ARRAY FOR OPTICAL COMMUNICATION

(71) Applicant: KYOCERA SLD Laser, Inc., Goleta, CA (US)

(72) Inventors: Nicholas J. Pfister, Goleta, CA (US); James W. Raring, Santa Barbara, CA (US)

(73) Assignee: KYOCERA SLD Laser, Inc., Goleta, CA (US)

(21) Appl. No.: 18/392,922

(22) Filed: Dec. 21, 2023

Related U.S. Application Data
(63) Continuation-in-part of application No. 17/962,379, filed on Oct. 7, 2022.

(51) Int. Cl. G02B 6/43; G02B 6/42; H01L 25/075; H04B 10/40; H04B 10/80

(52) U.S. Cl. CPC G02B 6/43; G02B 6/425; H01L 25/0753; H04B 10/40; H04B 10/801

(57) ABSTRACT

A system with optical interconnects includes first and second optical transceivers. The first optical transceiver includes a first array of micro light emitting diodes (LEDs) arranged on a first carrier substrate, a first array of photodetectors (PDs), and a first driver integrated circuit (IC). The second optical transceiver includes a second array of micro LEDs arranged on a second carrier substrate, a second array of PDs, and a second driver IC. The system also includes at least one multicore fiber cable arranged to optically couple the first array of micro LEDs with the second array of PDs and to optically couple the second array of micro LEDs with the first array of PDs.

### CROSS-REFERENCE TO RELATED APPLICATIONS

This application is a continuation-in-part of U.S. application Ser. No. 17/962,379, filed Oct. 7, 2022, the contents of which are incorporated herein by reference in their entirety for all purposes.

### BACKGROUND

By 2030, global data is forecasted to grow by ˜one yottabyte each year. Total general computing power will see a 10× increase and reach 3.3 ZFLOPS, and artificial intelligence (AI) computing power will increase by a factor of 500× to more than 100 ZFLOPS. This increased demand in computing power will consume up to 15% of the world's electricity. This increasing demand will require new higher performance computing networks (HPC) and hyperscale datacenters with improved computing powers and higher bandwidth.

Traditional semiconductor technologies used in these applications leverage system-on-chip (SoC) solutions and are approaching their physical limits (and cost). This has led to the development of a variety of powerful, high-throughput, system-in-package (SiP) architectures to support this increasing demand in computing power.

Multiple integrated circuits (ICs) are connected in SiP's using electrical interconnects. The interconnects between the die in the SiP's are important. They must be power efficient, have low latency, and provide high bandwidth to transfer large amounts of data between the ICs. Currently, very dense electrical interconnects are being used that often have issues with parasitic resistance, inductance, and capacitance. To minimize these issues, the chips need to be mounted very closely together. This limits the number of ICs that can be integrated into the SiP. In addition, the wiring density poses constraints on the data rates between the ICs. As speeds increases, the parasitics generally become worse and additional power is consumed in the serializer-deserializer (SERDES) to multiplex data to higher rates.

### SUMMARY

These issues can be overcome by using a larger number of optical interconnects at lower speeds in parallel. With this approach, SERDES can be eliminated and higher data rates can be achieved with lower power consumption. In addition, there are no parasitic circuit limitations or electrical cross talk in optical links.

In addition to providing interconnect for ICs in SiP architectures, the optical interconnects can also be used in other applications such as between multi-chip-modules (MCM's) mounted on circuit boards and rack-to-rack communications in data centers.

Some embodiments described herein use optical interconnects that include arrays of micro light emitting diodes (LEDs) that are coupled via multi-core fiber bundles to photo detectors. In some embodiments, these optical interconnects enable ultra-low power links that can provide data transmissions at <1 pJ/bit with up to 10 m reach. For example, in accordance with an embodiment, a system with optical interconnects includes a first optical transceiver having a first array of micro LEDs arranged on a first carrier substrate, each micro LED of the first array of micro LEDs including a first epitaxial material different from a material of the first carrier substrate, the first epitaxial material comprising at least an n-type gallium and nitrogen containing region, a light emitting gallium and nitrogen containing region configured to emit electromagnetic radiation, and a p-type gallium and nitrogen containing region; a first array of photodetectors (PDs) configured to detect the electromagnetic radiation; and a first driver IC electrically coupled to the first array of micro LEDs and configured to individually drive each micro LED of the first array of micro LEDs to generate first data signals using the electromagnetic radiation. The system also includes a second optical transceiver having a second array of micro LEDs arranged on a second carrier substrate, each micro LED of the second array of micro LEDs including a second epitaxial material different from a material of the second carrier substrate, the second epitaxial material comprising at least an n-type gallium and nitrogen containing region, a light emitting gallium and nitrogen containing region configured to emit electromagnetic radiation, and a p-type gallium and nitrogen containing region; a second array of PDs configured to detect the electromagnetic radiation; and a second driver IC electrically coupled to the second array of micro LEDs and configured to individually drive each micro LED of the second array of micro LEDs to generate second data signals using the electromagnetic radiation. The system also includes at least one multicore fiber cable arranged to optically couple the first array of micro LEDs with the second array of PDs so that the first data signals generated by the first array of micro LEDs are transmitted to the second array of PDs, and to optically couple the second array of micro LEDs with the first array of PDs so that the second data signals generated by the second array of micro LEDs are transmitted to the first array of PDs.

In an embodiment, at least some of the micro LEDs of the first array of micro LEDs are configured to emit the electromagnetic radiation at a first wavelength in a range of between 400 nm to 480 nm or between 500 nm to 560 nm, and at least some of the micro LEDs of the second array of micro LEDs are configured to emit the electromagnetic radiation at a second wavelength in the range of between 400 nm to 480 nm or between 500 nm to 560 nm.

In another embodiment, the first carrier substrate and the second carrier substrate are each selected from a silicon wafer, a sapphire wafer, a glass wafer, a glass ceramics wafer, a quartz wafer, a high purity fused silica wafer, a silicon carbide wafer, an aluminum nitride wafer, a germanium wafer, an aluminum oxynitride wafer, a gallium arsenide wafer, a diamond wafer, a gallium nitride wafer, an indium phosphide wafer, a flexible member, a circuit board member, a silicon wafer with CMOS circuitry, silicon on insulator (SOI) wafer, or a gallium nitride on silicon wafer.

In another embodiment, the at least one multicore fiber cable optically couples each micro LED of the first array of micro LEDs with one corresponding PD of the second array of PDs, and optically couples each micro LED of the second array of micro LEDs with a corresponding PD of the first array of PDs.

In another embodiment, the at least one multicore fiber cable includes a first multicore fiber cable and a second multicore fiber cable, first multicore fiber cable optically coupling each micro LED of the first array of micro LEDs with one corresponding PD of the second array of PDs, and the second multicore fiber cable optically coupling each micro LED of the second array of micro LEDs with a corresponding PD of the first array of PDs.

In another embodiment, the first array of micro LEDs and the first array of PDs are part of a first interdigitated array of micro LEDs and PDs, and the second array of micro LEDs and the second array of PDs are part of a second interdigitated array of micro LEDs and PDs.

In another embodiment, the system also includes a first IC electrically coupled to the first driver IC, and a second IC electrically coupled to the second driver IC, wherein the first driver IC is configured to drive the first array of micro LEDs to generate the first data signals based on first electrical signals received from the first IC, and the second driver IC is configured to drive the second array of micro LEDs to generate the second data signals based on second electrical signals received from the second IC. In some embodiments, the first driver IC is configured to convert the second data signals received at the first array of PDs to first electrical signals and to provide the first electrical signals to the first IC, the second driver IC is configured to convert the first data signals received at the second array of PDs to second electrical signals and to provide the second electrical signals to the second IC.

In another embodiment, each PD of the first array of PDs includes a first gallium and nitrogen containing material, and each PD of the second array of PDs includes a second gallium and nitrogen containing material, and wherein the first array of PDs is arranged on the first carrier substrate, and the second array of PDs is arranged on the second carrier substrate.

In another embodiment, the system also includes an interposer substrate, wherein the first optical transceiver and the second optical transceiver are coupled to the interposer substrate.

In another embodiment, the system also includes a first optical interconnect configured to couple the first optical transceiver to the at least one multicore fiber cable, and a second optical interconnect configured to couple the second optical transceiver to the at least one multicore fiber cable.

In another embodiment, the system also includes a first interposer electrically coupled to the first optical transceiver; a first plurality of ICs electrically coupled to the first interposer; a second interposer electrically coupled to the second optical transceiver; and a second plurality of ICs electrically coupled to the second interposer; wherein first electrical signals from the first plurality of ICs are transmitted to the first optical transceiver via the first interposer, and the first optical transceiver is configured to generate the first data signals based on the first electrical signals; and wherein second electrical signals from the second plurality of ICs are transmitted to the second optical transceiver via the second interposer, and the second optical transceiver is configured to generate the second data signals based on the second electrical signals. Some embodiments also include a printed circuit board (PCB), wherein the first interposer and the second interposer are coupled to the PCB.

In another embodiment, the first optical transceiver is part of a first server and the second optical transceiver is part of a second server, and the multicore fiber cable optically couples the first server to the second server.

In yet another embodiment, the first optical transceiver is part of a first server rack and the second optical transceiver is part of a second server rack, and the multicore fiber cable optically couples the first server rack to the second server rack.

In accordance with another embodiment, a system with optical interconnects includes a first array of micro LEDs arranged on a first carrier substrate, each micro LED of the first array of micro LEDs including a first epitaxial material different from a material of the first carrier substrate, the first epitaxial material comprising at least an n-type gallium and nitrogen containing region, a light emitting gallium and nitrogen containing region configured to emit electromagnetic radiation, and a p-type gallium and nitrogen containing region; a first array of PDs configured to detect the electromagnetic radiation; a first driver integrated circuit (IC) electrically coupled to the first array of micro LEDs and configured to individually drive each micro LED of the first array of micro LEDs to generate first data signals using the electromagnetic radiation; a second array of micro LEDs arranged on a second carrier substrate, each micro LED of the second array of micro LEDs including a second epitaxial material different from a material of the second carrier substrate, the second epitaxial material comprising at least an n-type gallium and nitrogen containing region, a light emitting gallium and nitrogen containing region configured to emit electromagnetic radiation, and a p-type gallium and nitrogen containing region; a second array of PDs configured to detect the electromagnetic radiation; a second driver IC electrically coupled to the second array of micro LEDs and configured to individually drive each micro LED of the second array of micro LEDs to generate second data signals using the electromagnetic radiation; and at least one waveguide arranged to optically couple the first array of micro LEDs with the second array of PDs so that the first data signals generated by the first array of micro LEDs are transmitted to the second array of PDs, and to couple the second array of micro LEDs with the first array of PDs so that the second data signals generated by the second array of micro LEDs are transmitted to the first array of PDs.

In an embodiment, the at least one waveguide comprises a two-dimensional (2D) planar waveguide or a three-dimensional (3D) waveguide.

In another embodiment, the at least one waveguide comprises an optical fiber.

In accordance with yet another embodiment, a system with optical includes a first IC and a first optical transceiver electrically coupled to the first IC. The first optical transceiver includes a first array of micro LEDs arranged on a first carrier substrate, each micro LED of the first array of micro LEDs including a first epitaxial material different from a material of the first carrier substrate, the first epitaxial material comprising at least an n-type gallium and nitrogen containing region, a light emitting gallium and nitrogen containing region configured to emit electromagnetic radiation, and a p-type gallium and nitrogen containing region; a first array of PDs configured to detect the electromagnetic radiation; and a first driver IC electrically coupled to the first array of micro LEDs and configured to individually drive each micro LED of the first array of micro LEDs to generate first data signals using the electromagnetic radiation, the first data signals generated based on first electrical signals received from the first IC. The system also includes a second IC and a second optical transceiver electrically coupled to the second IC. The second optical transceiver includes a second array of micro LEDs arranged on a second carrier substrate, each micro LED of the second array of micro LEDs including a second epitaxial material different from a material of the second carrier substrate, the second epitaxial material comprising at least an n-type gallium and nitrogen containing region, a light emitting gallium and nitrogen containing region configured to emit electromagnetic radiation, and a p-type gallium and nitrogen containing region; a second array of PDs configured to detect the electromagnetic radiation; and a second driver IC electrically coupled to the second array of micro LEDs and configured to individually drive each micro LED of the second array of micro LEDs to generate second data signals using the electromagnetic radiation, the second data signals generated based on second electrical signals received from the second IC. The system also includes at least one multicore fiber cable arranged to optically couple the first array of micro LEDs with the second array of PDs so that the first data signals generated by the first array of micro LEDs are transmitted to the second array of PDs, and to couple the second array of micro LEDs with the first array of PDs so that the second data signals generated by the second array of micro LEDs are transmitted to the first array of PDs.

In an embodiment, the first IC comprises a plurality of first ICs, and the second IC comprises a plurality of second ICs.

### BRIEF DESCRIPTION OF THE DRAWINGS

FIG. 1A is a simplified cross-sectional diagram of a SiP with optical interconnects in accordance with some embodiments, and FIGS. 1B-1C provide examples of simplified plan views of arrays of micro LEDs and arrays of photodetectors in accordance with some embodiments.

FIG. 2A is a simplified cross-sectional diagram of a SiP with optical transceivers each having an array of interdigitated photodetectors and micro LEDs in accordance with some embodiments, and FIGS. 2B-2C provide examples of simplified plan views of arrays of interdigitated photodetectors and micro LEDs in accordance with some embodiments.

FIG. 3 is a simplified cross-sectional diagram of micro LEDs that have been transferred to a CMOS driver IC in accordance with some embodiments.

FIG. 4 is a simplified cross-sectional diagram of a micro LED that has been transferred to an optical transceiver IC with a photodetector device layer in accordance with some embodiments.

FIG. 5 is a simplified cross-sectional diagram of a micro LED and photodetector that have been transferred to an optical transceiver IC in accordance with some embodiments.

FIG. 6 is a simplified cross-sectional diagram illustrating an exemplary transfer process in accordance with some embodiments.

FIG. 7A is a simplified cross-sectional diagram of an optical interconnect for chip-to-chip communication using a 2D planar waveguide in accordance with some embodiments, and FIG. 7B is a simplified cross-sectional diagram of an optical interconnect for chip-to-chip communication using an optical fiber in accordance with some embodiments.

FIG. 8 is a simplified cross-sectional diagram of a micro LED-based optical interconnect for multi-chip module (MCM) to multi-chip module (MCM) communication in accordance with some embodiments.

FIG. 9 is a simplified perspective view of optical interconnects providing inter-rack and intra-rack connections in a data center in accordance with some embodiments.

FIG. 10A is a simplified process flow for epitaxial preparation in an example of the present invention.

FIG. 10B is a simplified process flow for epitaxial preparation in an example using active region protect layers of the present invention.

FIG. 11A is a simplified process flow for bonding and then etching the sacrificial regions in an example of the present invention.

FIG. 11B is a simplified process flow for partially or nearly completely etching the sacrificial region and then bonding wherein the unetched regions act as anchors used for mechanical support to epitaxial mesas in an example of the present invention.

FIG. 11C is a simplified process flow for etching the sacrificial region and then bonding wherein non semiconductor anchor features are used for mechanical support to epitaxial mesas in an example of the present invention.

FIG. 11D is a simplified process flow for etching the sacrificial region and then bonding wherein semiconductor anchor features are used for mechanical support to epitaxial mesas in an example of the present invention.

FIG. 11E is a simplified top-view schematic of semiconductor anchor features providing mechanical support to epitaxial mesas in an example of the present invention.

FIG. 11F is a simplified side-view schematic of process flow for using semiconductor anchor features providing mechanical support to epitaxial mesas in an example of the present invention.

FIG. 11G is a simplified top-view schematic of metal anchor features providing mechanical support to epitaxial mesas in an example of the present invention.

FIG. 11H is a simplified side-view schematic of process flow for using metal anchor features providing mechanical support to epitaxial mesas in an example of the present invention.

FIG. 11I is a simplified schematic of electrical circuit formed during PEC etching with metal anchors connecting the anode and cathode in an example of the present invention.

FIG. 12 is a simplified side view of a selective area bonding process in an example of the present invention.

FIGS. 13A-13E are simplified schematics of exemplary epitaxial structures of LED devices according to some embodiments of the present invention.

FIG. 13F is a simplified schematic illustration of die expansion of an LED device epitaxial structure with a non-rectangular shape in an example of the present invention.

FIG. 13G is a simplified schematic illustrating an example of a multiplexing configuration in a transferred micro LED array according to this invention.

FIG. 13H is a simplified schematic illustrating an example of a multiplexing configuration in a transferred micro LED array according to this invention.

FIG. 14A is a simplified schematic of an LED epitaxial structure in an example of the present invention.

FIG. 14B is a simplified schematic of an LED epitaxial structure transferred to a carrier wafer in an example of the present invention.

FIG. 15A is a simplified schematic of an epitaxial structure of a p-n diode power device according to an example of the present invention.

FIG. 15B is a simplified schematic cross-section of a structure of a p-n diode power device on a carrier wafer according to an example of the present invention.

FIG. 15C is a simplified schematic of an epitaxial structure of a p-n diode power device according to an example of the present invention.

FIG. 15D is a simplified schematic cross-section of a structure of a p-n diode power device on a carrier wafer according to an example of the present invention.

FIGS. 15E-15F illustrate methods by which p-n diode devices are formed on a gallium and nitrogen containing or foreign wafer and transferred to a carrier wafer according to examples of the present invention.

FIGS. 16A-16C are flowcharts of exemplary methods that include screening die during a transfer process in accordance with some embodiments.

FIGS. 17A-17D are simplified cross sectional diagrams illustrating a process of selective anchor removal in accordance with an embodiment.

FIGS. 18-19 are simplified cross sectional diagrams illustrating some of the challenges with bonding die to a carrier wafer in a transfer process.

FIGS. 20A-20D are simplified cross sectional diagrams illustrating a process for transferring die having a large pitch on a donor substrate to a carrier substrate at a smaller pitch in accordance with an embodiment.

FIGS. 21A-21F are simplified cross sectional diagrams illustrating a process for transferring die from a donor substrate to a carrier substrate by varying bond pad thickness on the carrier substrate in accordance with an embodiment.

FIGS. 22A-22D are simplified cross sectional diagrams illustrating a process for transferring die from a donor substrate to a carrier substrate by varying die height in accordance with an embodiment.

FIGS. 23A-23I are simplified cross sectional diagrams illustrating a process for transferring die from a donor substrate to a carrier substrate by varying die height in accordance with another embodiment.

FIGS. 24A-24C are simplified cross sectional diagrams illustrating a round robin sequence for transferring die from a donor substrate to a carrier substrate in accordance with an embodiment.

### DETAILED DESCRIPTION

Some embodiments described herein use optical interconnects that include arrays of micro LEDs that are coupled via multi-core fiber bundles to photodetectors. The arrays of micro LEDs may be formed using a transfer process that is highly efficient and cost effective. Optical interconnects using these micro LEDs can provide, for example, low power data transmissions at <1 pJ/bit at distances of up to 10 m or more.

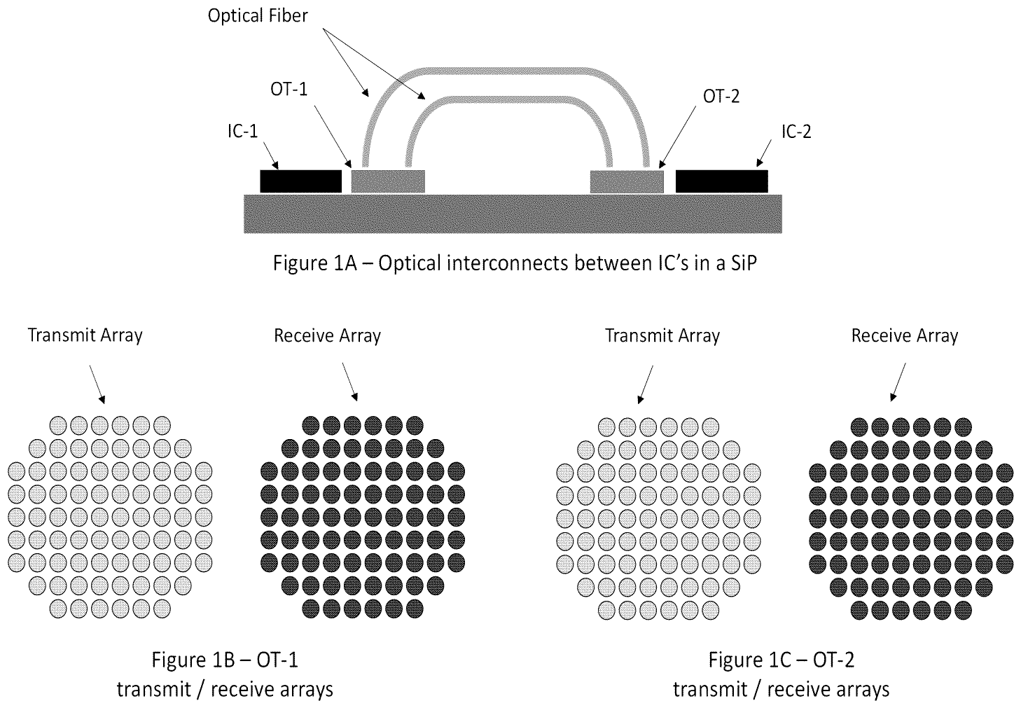

FIG. 1A is a simplified cross-sectional diagram of a SiP with optical interconnects in accordance with an embodiment. In this example, the SiP includes a first integrated circuit (IC-1) that may be, for example, an application-specific integrated circuit (ASIC) used to perform logic, processing, memory, and/or other functions. The IC-1 is electrically coupled to a first optical transceiver (OT-1) that may be, for example, an optical transceiver integrated circuit (OTIC). The OT-1 includes a first driver IC that is electrically coupled to a first array of micro LEDs. FIG. 1B provides an example of a simplified plan view of the first array of micro LEDs (Transmit Array) in accordance with an embodiment. The first array of micro LEDs are optically coupled to a first multicore fiber cable. The first array of micro LEDs are driven by the first driver IC to transmit data signals via the first multicore fiber cable. The OT-1 can also receive data signals from a second optically coupled multicore fiber cable using a first array of photodetectors electrically coupled to amplifier and/or readout circuitry. FIG. 1B also provides an example of a simplified plan view of the first array of photodetectors (Receive Array) in accordance with an embodiment.

In this example, a second optical transceiver (OT-2) includes a second array of photodetectors configured to receive the data signals from the OT-1 via the first multicore fiber cable. The OT-2 may be, for example, an optical transceiver integrated circuit (OTIC). FIG. 1C provides an example of a simplified plan view of the second array of photodetectors (Receive Array) in accordance with an embodiment. The second array of photodetectors may also be coupled to amplifier and/or readout circuitry. A second integrated circuit (IC-2) is electrically coupled to the OT-2. The IC-2 may be, for example, an application-specific integrated circuit (ASIC) used to perform logic, processing, memory, and/or other functions. The OT-2 includes a second driver IC that is electrically coupled to a second array of micro LEDs. FIG. 1C also provides an example of a simplified plan view of the second array of micro LEDs (Transmit Array) in accordance with an embodiment. The second array of micro LEDs are optically coupled to the second multicore fiber cable. The second array of micro LEDs are driven by the second driver IC to transmit data signals via the second multicore fiber cable.

The multicore fiber cables maintain channels of data streams between the optical transceivers. Each micro LED and associated photodetector may be associated with a distinct channel. Embodiments described herein are not limited to a particular type of fiber and the multicore fiber may include a single fiber, a fiber bundle, or combinations thereof.

A micro LED may be differentiated from a standard LED by having an emitting region of less than about 100 um×100 um and can be made with areas of less than about 20 um×20 um or even less than 1 um×1 um. The micro LEDs in accordance with some embodiments can support speeds per optical link of greater than 1 Gbps, greater than 5 Gbps, or greater than 10 Gbps or more. In some embodiments a micro LED array may consist of 1 to 1000 or more optical links. An array of optical links can create optical interconnects with multi-Tbps speeds in accordance with some embodiments. The length of the optical interconnects can be less than 1 mm, less than 1 m, or less than about 10 m.

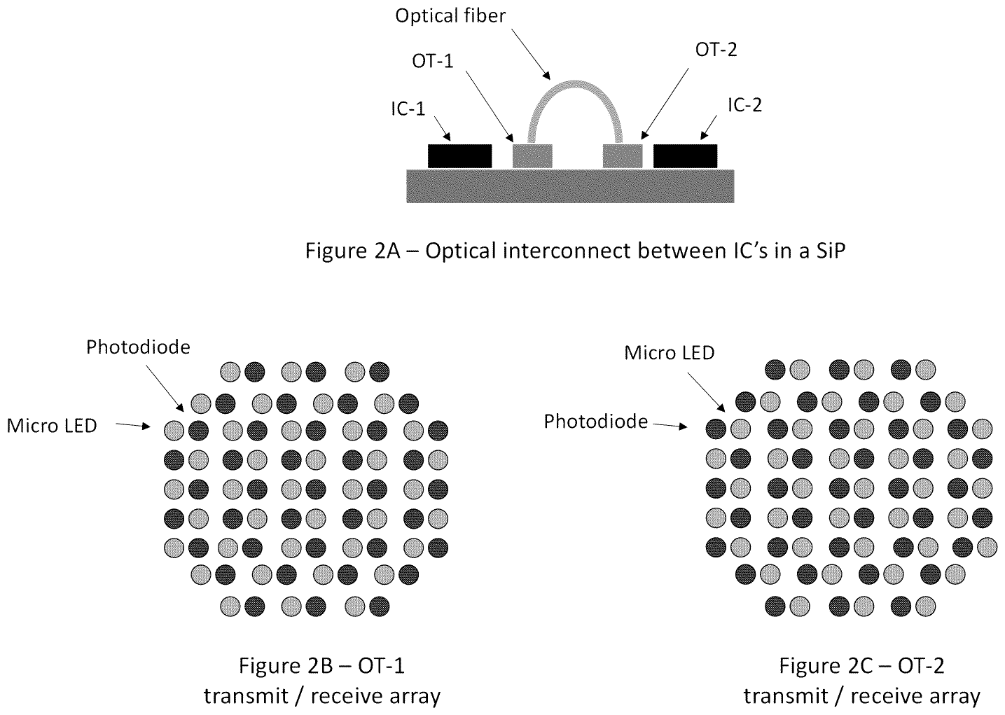

The SiP in FIG. 1A has an architecture that utilizes optical transceivers with separate arrays of photodetectors and micro LEDs. In another embodiment, the optical transceivers can have a single array of interdigitated photodetectors and micro LEDs to minimize size and components. An example of this configuration is shown in FIGS. 2A-2C. In this example, an OT-1 includes an array of interdigitated photodetectors and micro LEDs. An example of a simplified plan view of the array of interdigitated photodetectors and micro LEDs of OT-1 is shown in FIG. 2B. An OT-2 also includes an array of interdigitated photodetectors and micro LEDs. An example of a simplified plan view of the array of interdigitated photodetectors and micro LEDs of OT-2 is shown in FIG. 2C. A single multicore fiber cable may be used to transmit and receive data signals as shown in this example.

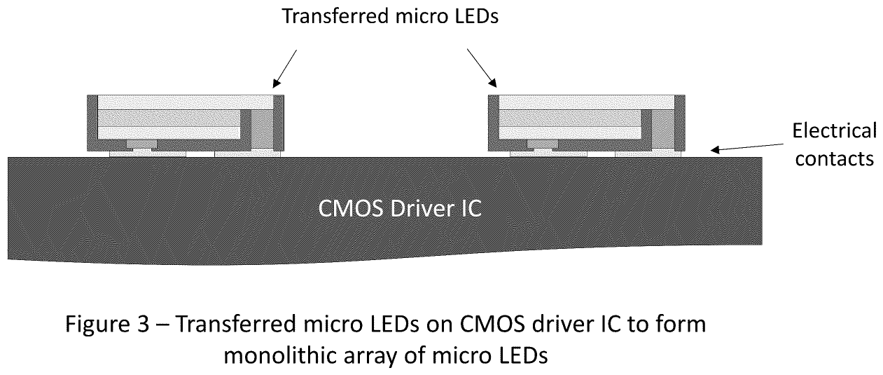

In some embodiments, the micro LEDs may be coupled to a CMOS driver IC using a device transfer process. Exemplary transfer processes that may be used for the optical interconnect applications are described below. The micro LEDs may be at least partially formed before the transfer process and additional processing may be performed after the transfer process as necessary. FIG. 3 is a simplified cross-sectional diagram that shows micro LEDs that have been transferred directly to a CMOS driver IC in accordance with an embodiment. In this example, n- and p-contacts are disposed on the same side of the micro LEDs. This can be beneficial in minimizing processing after the transfer and attach processes. In other embodiments, topside and bottom side contacts may be used to electrically couple the micro LEDs to the CMOS driver IC. The bottom side contact may be formed during the attach process by mechanically attaching the micro LED to the CMOS driver IC and by forming an electrical connection. The topside contact may be formed after the transfer using conventional redistribution layer (RDL) approaches.

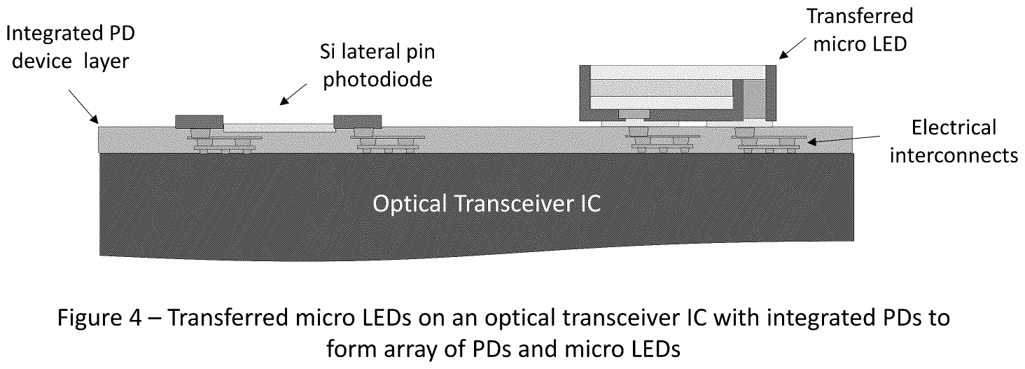

In other embodiments, the micro LEDs may be transferred onto an optical transceiver integrated circuit (OTIC) with a photodetector (e.g., photodiode) device layer to form an interdigitated array of photodiodes (PDs) and micro LEDs. An example of this configuration is shown in FIG. 4. In this example, the PDs (e.g., silicon-based lateral pin photodiodes) may be fabricated on an upper region of an OTIC and electrically connected using electrical interconnects. In an embodiment, the layout of the PDs can be selected so that the micro LEDs can be transferred directly on a top surface the PD device layer. Electrical interconnects can be integrated in the PD device layer to electrically couple the transferred micro LEDs to the OTIC. Different types of PDs can be used and embodiments described herein are not limited to silicon-based lateral pin photodiodes.

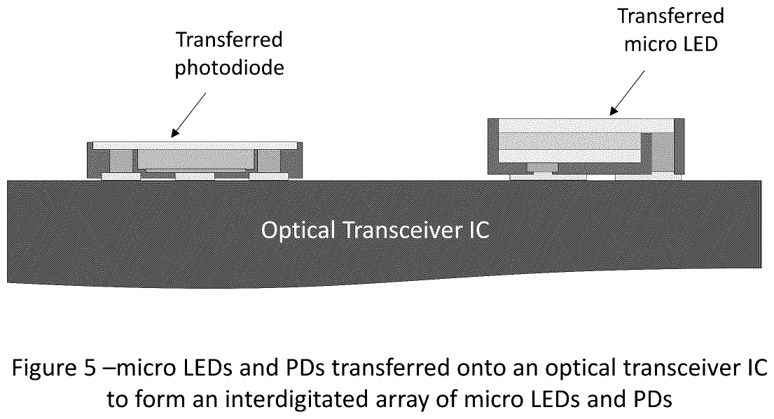

In other embodiments, the PDs may be coupled to the CMOS driver IC or OTIC using a device transfer process. Exemplary transfer processes that may be used for the optical interconnect applications are described below. The PDs may be at least partially formed before the transfer process and additional processing may be performed after the transfer process as necessary. An example of this configuration is shown in FIG. 5. In some embodiments, transferred gallium and nitrogen containing PDs may be configured to operate at emission wavelengths of transferred gallium and nitrogen containing micro LEDs. The PDs and micro LEDs can be transferred directly to an OTIC, to separate amplifier circuitry, to a read out IC, or the like. High speed gallium and nitrogen containing PDs can operate at speeds of >10 Ghz and have high responsivity at the emission wavelength of gallium and nitrogen containing micro LEDs enabling high data rates per optical link.

Gallium and nitrogen containing micro LEDs and PDs (e.g., photodiodes) can be formed on GaN, Si, sapphire, or other substrates. In some embodiments, the transfer process may involve lifting off the gallium and nitrogen containing devices from donor substrates and bonding the gallium and nitrogen containing devices to a driver IC. The bonding may be performed at a wafer level due to a size of the devices and the need to bond many at the same time to be compatible with high volume production. Some bonding processes may transfer the devices from the donor substrates to the driver IC at the same the pitch. As explained previously, micro LEDs can be about 1 um×1 um or smaller, and a pitch of the array on the driver IC can be on the order of 10's to 100's of microns. As a result, there may be a substantial amount of unused gallium and nitrogen containing material on the donor substrates that is not transferred. This can be an inefficient use of expensive gallium and nitrogen containing donor substrates.

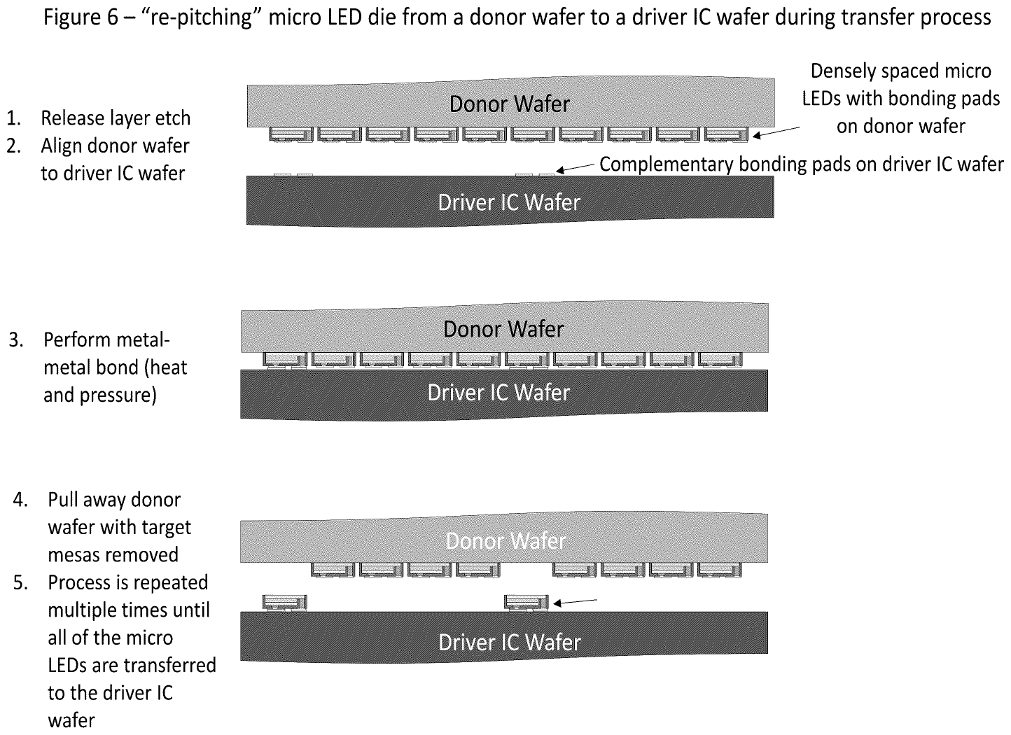

In some embodiments, the micro LEDs and/or PDs may be “re-pitched” during the transfer process. This can enable high utilization of gallium and nitrogen containing donor substrates while still enabling a parallel transfer process for high volume production. An example is shown in FIG. 6, where the micro LEDs are densely spaced on the gallium and nitrogen containing donor substrate. In an embodiment, a release layer is etched to enable transfer of the micro LEDs. Following release layer etch, the donor substrate and the driver IC substrate are aligned so that the micro LED bonding pads are aligned to the complementary bonding pads on the driver IC substrate. The pitch of the bonding pads on the driver IC substrate can be larger than the pitch of the micro LEDs on the donor substrate. After aligning, the micro LEDs are bonded using, for example, a metal-metal thermocompression bond. After the bonding process, the donor substrate can be separated from the driver IC substrate leaving the bonded micro LEDs on the driver IC substrate. This process is repeated across the driver IC substrate until all of the micro LEDs in the array are transferred from the gallium and nitrogen containing donor substrate. The PDs (e.g., photodiodes) may be formed and transferred using similar processes.

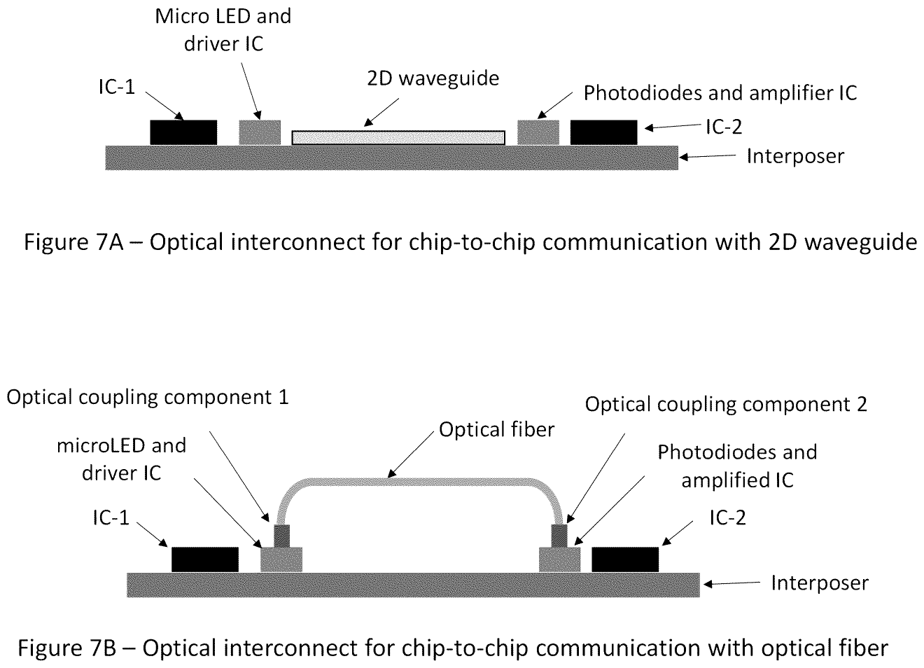

Some embodiments provide optical interconnects between ICs attached to interposers or package substrates. FIG. 7A is an example of an optical interconnect for chip-to-chip communication using a 2D planar waveguide. An integrated circuit (IC-1), that may be configured to perform logic, process, memory, or other functions, is coupled to an interposer, and a micro LED array integrated onto a driver IC is also attached to the interposer. The interposer electrically couples the IC-1 chip to the driver IC. The driver IC drives the micro LED array based on data from the IC-1 chip. A data signal generated by the micro LEDs is then coupled into the planar waveguide integrated onto the interposer. The data signal is received by a photodiode array connected to an amplifier IC. The amplifier IC is electrically connected via the interposer to a second integrated circuit (IC-2) chip that may be configured to perform logic, process, memory, or other functions. Some embodiments provide transfer of light (e.g., electromagnetic radiation) between the micro LED array and the photodiode array using free-space, 2D waveguides, 3D waveguides, or some combination. FIG. 7B shows another embodiment of the chip-to-chip communication with an optical fiber instead of a planar waveguide. This approach uses optical coupling components to vertically launch the data signal between the micro LED array and photodiode array.

In some embodiments, an optical transceiver chip can perform both transmit and receive functions by integrating the micro LED array, driver IC, photodiode array, and amplifier IC.

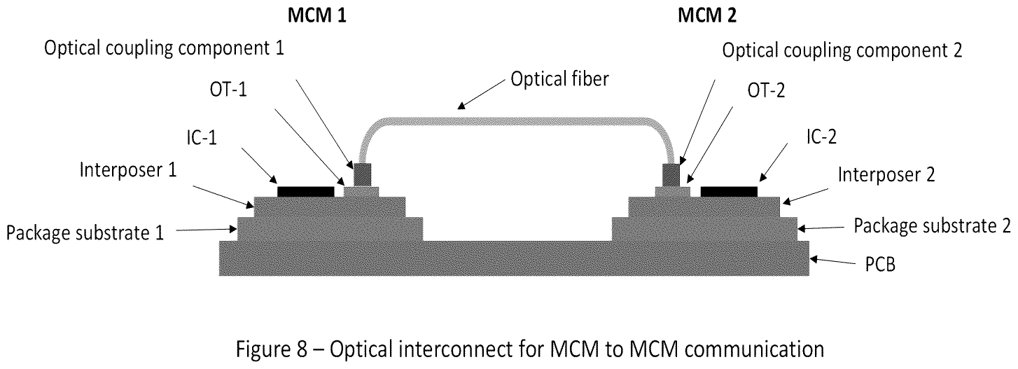

In some embodiments, a micro LED-based optical interconnect can be used for multi-chip module (MCM) to multi-chip module communication. FIG. 8 is a simplified diagram providing an example of two MCMs on a printed circuit board (PCB) in accordance with an embodiment. In this example, the optical transceiver ICs (OT-1 and OT-2) use optical interconnects with an optical fiber. Both MCMs are coupled to a common PCB. The MCMs may include an interposer attached to a package substrate. The interposer can electrically connect multiple ICs (e.g., IC-1 and IC-2) serving various functions (logic, process, memory, other). The ICs can be electrically connected to an optical transceiver chip (e.g., OT-1 and OT-2). The optical transceiver chips are optically coupled to an optical fiber with an optical coupling component. Data signals can be optically transmitted between both MCM 1 and MCM 2 shown in this example.

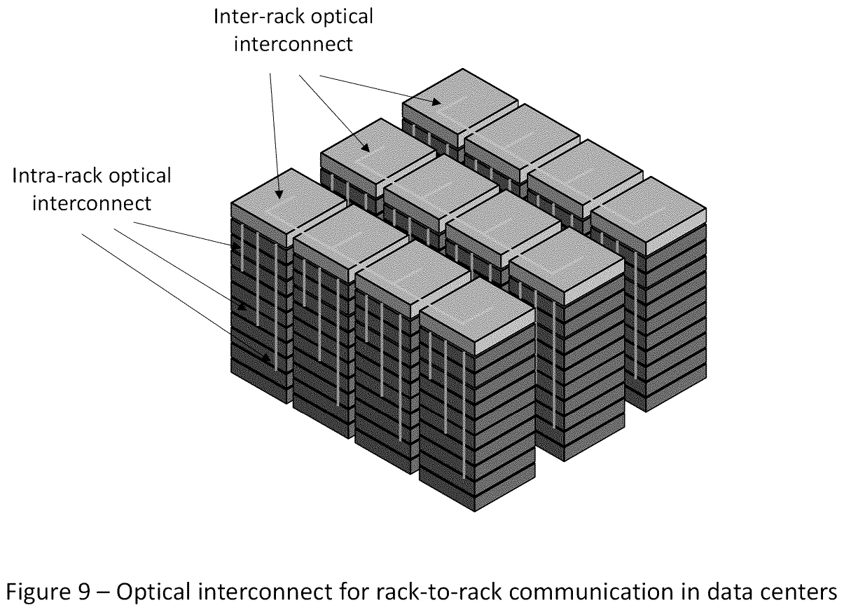

In other embodiments, optical interconnects can be used for making inter-rack and/or intra-rack connections in a data center. An example of this configuration is shown in FIG. 9. This application enables data centers having disaggregated designs. Disaggregated data centers can offer flexibility for resource allocation and hence resource utilization can be improved. Traditional data center designs locate all resources such as CPU, memory, and storage on each blade server. Disaggregated data centers have a single resource on each blade server or a single resource on each rack to improve resource utilization. An issue with disaggregation is that communications between different resources face latency and transmission bandwidth issues. In particular the CPU-memory interconnects in fully disaggregated data centers require low latency and high transmission bandwidth to prevent performance degradation. The optical interconnect configurations described herein can reduce these issues and support inter-rack and intra-rack communications within about a ten meter or greater reach. Ten meters is generally sufficient to support these very short reach (VSR) links.

In accordance with the embodiments described herein, the data signal from the micro LEDs can be modulated in any available modulation format to transmit the data. For example, the modulation can be amplitude modulation (AM) or frequency modulation (FM). Common AM modulation schemes include, double-sideband modulation (DSB), double-sideband modulation with carrier (DSB-WC) (used on the AM radio broadcasting band), double-sideband suppressed-carrier transmission (DSB-SC), double-sideband reduced carrier transmission (DSB-RC), single-sideband modulation (SSB, or SSB-AM), single-sideband modulation with carrier (SSB-WC), single-sideband modulation suppressed carrier modulation (SSB-SC), vestigial sideband modulation (VSB, or VSB-AM), quadrature amplitude modulation (QAM), pulse amplitude modulation (PAM). Similarly, common digital FM modulation techniques are based on keying including PSK (phase-shift keying) where a finite number of phases are used, FSK (frequency-shift keying) where a finite number of frequencies are used, ASK (amplitude-shift keying) where a finite number of amplitudes are used, and QAM (quadrature amplitude modulation) where a finite number of at least two phases and at least two amplitudes are used. There are several variations of each of these listed digital modulation techniques, which can be included in the various embodiments. The most common variant of ASK is simple on-off keying (OOK). Additional modulation schemes include continuous phase modulation (CPM) methods, minimum-shift keying (MSK), Gaussian minimum-shift keying (GMSK), continuous-phase frequency-shift keying (CPFSK), orthogonal frequency-division multiplexing (OFDM) modulation, discrete multitone (DMT), including adaptive modulation and bit-loading, and wavelet modulation.

Embodiments of the invention provide methods for fabricating semiconductor devices based on gallium and nitrogen containing epitaxial materials grown on bulk gallium and nitrogen containing substrates. Typically these devices are fabricated using an epitaxial deposition on a gallium and nitrogen containing substrate followed by processing steps on the epitaxial substrate and overlying epitaxial material. In some embodiments for the fabrication of devices such as LEDs the gallium and nitrogen containing epitaxial materials could be provided by heteroepitaxial growth on a substrate that is not gallium nitride. These heteroepitaxial substrates may include sapphire, SiC, gallium oxide, spinel, lanthanum aluminate, magnesium oxide, and silicon among others. By using a selective etch process such as a photoelectrochemical (PEC) etch combined with a bonding process at least a portion of the epitaxial material is transferred to one or more carrier wafers. Subsequently, the carrier wafer with the bonded epitaxial material is subjected to processing steps to form semiconductor devices including optical devices such as light emitting diodes. In other embodiments the semiconductor devices are fully or partially formed in the epitaxial material before transfer to a carrier wafer or to an integrated circuit. In other embodiments, different types of semiconductor devices are configured on a common carrier using the selective bonding and etching process to form an integrated device. Merely by way of example, the invention can be applied to applications such as optical data communications. What follows is a general description of the typical configuration and fabrication of these devices.

The invention involves a semiconductor device wafer composed of one or more sacrificial layers and one or more device layers overlying the surface region of a substrate wafer. The substrate wafer comprising a bulk gallium and nitrogen containing material such as GaN, but can be others. In the example of a GaN substrate, the GaN substrate can be configured with a polar surface such as a c-plane surface, a nonpolar surface such as an m-plane surface, or a semipolar surface such as a {30-32}, {20-21}, {30-31}, {50-51}, {30-3-2}, {20-2-1}, {30-3-1}, {50-5-1}, {11-22}, or {10-1-1}. In some embodiments the substrate surface orientation is configured with an offcut of less than about 10 degrees toward a c-direction, a-direction, and/or m-direction a c-plane surface, a nonpolar surface such as an m-plane surface, or a semipolar surface such as a {30-32}, {20-21}, {30-31}, {50-51}, {30-3-2}, {20-2-1}, {30-3-1}, {50-5-1}, {11-22}, or {10-1-1}.

Current state of the art is to use bulk GaN substrates produced by growth of reduced defect density boules either by hydride vapor phase epitaxy or ammonothermal growth. In both cases relatively large (e.g. typically two inch diameter or greater) GaN c-plane substrates can be produced which have relatively low density of uniformly distributed defects. Growth on c-plane wafers is advantageous to growth on non-polar and semi-polar oriented GaN wafers only in the aspect that two-inch and greater diameter c-plane wafers are currently available and non-polar and semi-polar orientations are generally restricted in size due to their being crosscut from c-plane oriented boules.

Polar c-plane GaN wafers with no offcut are oriented primarily with the surface normal parallel to the direction of the wurtzite crystal lattice. The wafer may have an offcut, where the surface normal of the wafer is tilted towards one or a combination of the <11-20> or <10-10> directions. For an arbitrary offcut direction one would normally specify the tilt towards orthogonal pairs of directions found in the <11-20> and <10-10> families. For example, [10-10] and [1-210] are orthogonal and might be used to specify an arbitrary offcut. In general, offcuts will be predominantly towards only one of the <11-20> or <10-10> directions, with only relatively small deviations. For example, a c-plane wafer may have an offcut between 0.1 and 10 degrees towards the [10-10] direction or it may have an offcut between 0.1 and 10 degrees towards the [11-20] direction. Though larger and smaller offcuts would be possible, a wafer with an offcut less than 0.1 degrees would be considered to be nominally on-axis.

Wafer offcut is important because it will determine both the density of atomic steps on the wafer surface as well as the termination of the step edges. Because an arbitrarily oriented surface of a crystal is likely to have a high surface energy, a crystal will tend to form an approximation of an inclined face using a collection of low energy planes. In general, an offcut c-plane wafer would result in a stepped surface comprised of step surfaces and step-edges composed of prismatic planes (i.e. (11-20) or (10-10)). Due to anisotropy in the crystal structure the number and configuration of dangling bonds at (11-20) step edges will be different from those at a (10-10) step edge. Since the direction and magnitude of the offcut controls the density and orientation of the step edges, a large amount of control over the chemical character of the substrate can be affected by offcut. Many growth processes such as chemical ordering, incorporation of volatile species and formation of stacking faults can be linked to the way atoms incorporate at the edges of steps. Therefore, proper selection of substrate offcut is critical to achieving the best epitaxial film quality.

Though c-plane wafers are larger than non-polar and semi-polar oriented wafers and offer a cost advantage, they have a severe drawback is in some semiconductor devices that result from internal fields originating from spontaneous and piezo induced polarization fields. In light emitting devices that use quantum wells, the internal polarization field result in a spatial separation of electron and hole states within the quantum wells that negatively impacts the radiative recombination efficiency. Using narrow wells has been the approach taken in both LED and laser devices based on polar GaN. In LEDs, the narrow quantum wells lead to high carrier density, which exacerbates the droop phenomenon that leads to the nonlinear light output versus current input of LEDs, and ultimately limits the efficiency. By using nonpolar or semipolar GaN substrate orientations for LEDs and laser diodes, these internal fields can be reduced and improved performance is possible. Similarly, in electronic devices there are aspects wherein having reduced internal fields or reduced polarization fields, semiconductor electronic devices with improved performance can be formed.

The limited currently available size and increased cost of nonpolar and semipolar substrates limits their practicality for deployment in commercial semiconductor devices. A powerful breakthrough enabled by this present invention is the use of nonpolar or semipolar substrates at a low cost since die expansion can be used, substrates can be re-used, and the overlying epitaxy of small wafers can be transferred onto larger carrier wafers for device fabrication. In a specific embodiment, the gallium nitride substrate member is a bulk GaN substrate characterized by having a semipolar or non-polar crystalline surface region, but can be others. In a specific embodiment, the bulk nitride GaN substrate comprises nitrogen and has a surface dislocation density between about 10E5 cm⁻² and about 10E7 cm⁻² or below 10E5 cm⁻². The nitride crystal or wafer may comprise AlₓIn_{y}Ga_{1-x-y}N, where 0≤x, y, x+y≤1. In one specific embodiment, the nitride crystal comprises GaN. In one or more embodiments, the GaN substrate has threading dislocations, at a concentration between about 10E5 cm⁻² and about 10E8 cm⁻², in a direction that is substantially orthogonal or oblique with respect to the surface. As a consequence of the orthogonal or oblique orientation of the dislocations, the surface dislocation density is between about 10E5 cm⁻² and about 10E7 cm⁻² or below about 10E5 cm⁻².

Of course, in some embodiments for the fabrication of devices such as LEDs or power electronic devices the gallium and nitrogen containing epitaxial materials could be provided by heteroepitaxial growth on a substrate that is not gallium nitride. These heteroepitaxial substrates may include sapphire, SiC, gallium oxide, spinel, lanthanum aluminate, magnesium oxide, and silicon among others. In a preferred embodiment, the gallium and nitrogen containing epitaxial materials are deposited on sapphire or SiC due to their relatively low cost and ability to achieve relatively low defectivity and low strain epitaxial films. In a less preferred embodiment the gallium and nitrogen containing epitaxial materials are deposited on silicon wafers due to the low cost of silicon wafers and availability of large area silicon wafers; i.e. wafers with greater than 150 mm diameter.

Another advantage offered by the present invention is the ability to access either the Ga-face or the N-face of the gallium and nitrogen containing epitaxial device layers for device fabrication and contact formation. For example, if the epitaxial layers are grown on a Ga-face substrate the epitaxial layers will be formed terminating with a Ga-face surface. After the epitaxy is transferred to the carrier wafer for process the N-face will be exposed for process. The N-face may provide an advantage to the device such as an improved contact property or an improved behavior for the semiconductor layers. In the case where it is desirable to do the device fabrication with the Ga-face on the surface, semiconductor process steps may be performed on the epitaxial wafers prior to transfer to the carrier wafer. The order of the epitaxial stack can be arranged to provide the most benefit to the device.

Following the growth of the epitaxial layers on the bulk gallium and nitrogen containing substrate, the semiconductor device layers are separated from the substrate by a selective wet etching process such as a PEC etch configured to selectively remove the sacrificial layers and enable release of the device layers to one or more carrier wafers. In one embodiment, a bonding material is deposited on the surface overlying the semiconductor device layers. A bonding material is also deposited either as a blanket coating or patterned on a carrier wafer. Standard lithographic processes are used to selectively mask the semiconductor device layers. The wafer is then subjected to an etch process such as dry etch or wet etch processes to define via structures that expose the one or more sacrificial layers on the sidewall of the mesa structure. As used herein, the term mesa region or mesa is used to describe the patterned epitaxial material on the gallium and nitrogen containing substrate and prepared for transfer to the carrier wafer. The mesa region can be any shape or form including a rectangular shape, a square shape, a triangular shape, a circular shape, an elliptical shape, a polyhedron shape, or other shape. The term mesa shall not limit the scope of the present invention.

Following the definition of the mesa, a selective etch process is used to fully or partially remove the one or more sacrificial layers while leaving the semiconductor device layers intact. The resulting structure comprises undercut mesas comprised of epitaxial device layers. The undercut mesas correspond to dice from which semiconductor devices will be formed on. In some embodiments a protective passivation layer can be employed on the sidewall of the mesa regions to prevent the device layers from being exposed to the selective etch when the etch selectivity is not perfect. In other embodiments a protective passivation is not needed because the device layers are not sensitive to the selective etch or measures are taken to prevent etching of sensitive layers such as shorting the anode and cathode. The undercut mesas corresponding to device dice are then transferred to the carrier wafer using a bonding technique wherein the bonding material overlying the semiconductor device layers is joined with the bonding material on the carrier wafer. The resulting structure is a carrier wafer comprising gallium and nitrogen containing epitaxial device layers overlying the bonding region.

In a preferred embodiment PEC etching is deployed as the selective etch to remove the one or more sacrificial layers. PEC is a photo-assisted wet etch technique that can be used to etch GaN and its alloys. The process involves an above-band-gap excitation source and an electrochemical cell formed by the semiconductor and the electrolyte solution. In this case, the exposed (Al,In,Ga)N material surface acts as the anode, while a metal pad deposited on the semiconductor acts as the cathode. The above-band-gap light source generates electron-hole pairs in the semiconductor. Electrons are extracted from the semiconductor via the cathode while holes diffuse to the surface of material to form an oxide. Since the diffusion of holes to the surface requires the band bending at the surface to favor a collection of holes, PEC etching typically works only for n-type material although some methods have been developed for etching p-type material. The oxide is then dissolved by the electrolyte resulting in wet etching of the semiconductor. Different types of electrolyte including HCl, KOH, and HNO₃ have been shown to be effective in PEC etching of GaN and its alloys. The etch selectivity and etch rate can be optimized by selecting a favorable electrolyte. It is also possible to generate an external bias between the semiconductor and the cathode to assist with the PEC etching process.

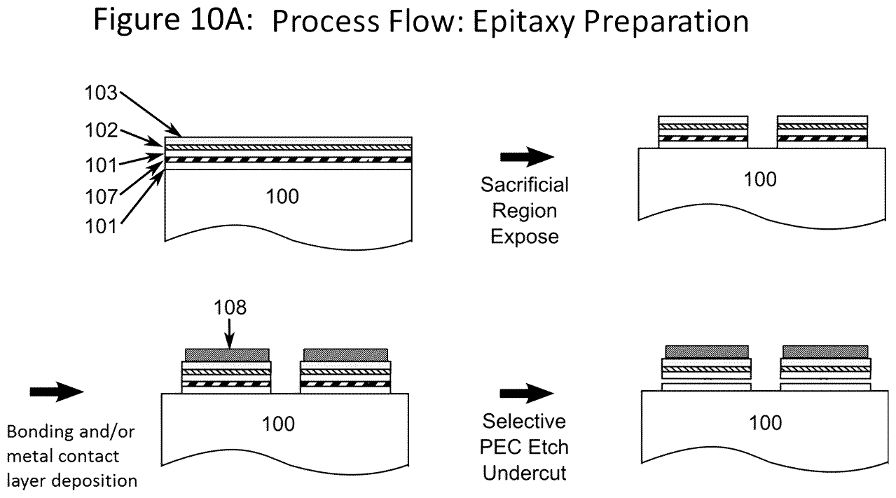

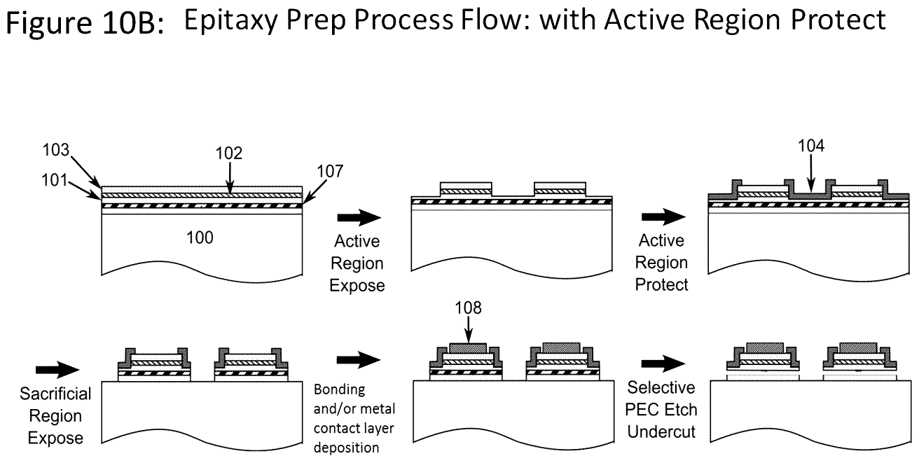

The preparation of the epitaxy wafer is shown in FIG. 10A. A substrate 100 is overlaid by a buffer layer 101, a selectively removable sacrificial layer 107, a buffer layer 101, a collection of device layers 102 and a contact layer 103. The sacrificial region is exposed by etching of vias that extend below the sacrificial layer and segment the layers 101, 102, 103, and 107 into mesas. A layer composed of bonding media 108 is deposited overlaying the mesas. In some embodiments the bonding layer is deposited before the sacrificial layer is exposed. Finally, the sacrificial layer is removed via a selective process. This process requires the inclusion of a buried sacrificial region, which can be PEC etched selectively by bandgap. For GaN based semiconductor devices, InGaN layers such as quantum wells have been shown to be an effective sacrificial region during PEC etching. The first step depicted in FIG. 10A is a top down etch to expose the sacrificial layers, followed by a bonding metal deposition as shown in FIG. 10A. With the sacrificial region exposed a bandgap selective PEC etch is used to undercut the mesas. In one embodiment, the bandgaps of the sacrificial region and all other layers are chosen such that only the sacrificial region will absorb light, and therefor etch, during the PEC etch. Another embodiment of the invention involving light emitting devices uses a sacrificial region with a higher bandgap than the active region such that both layers are absorbing during the bandgap PEC etching process.

In one embodiment involving light emitting devices, the active region can be prevented from etching during the bandgap selective PEC etch using an insulating protective layer on the sidewall, as shown in FIG. 10B. The device layers 102 are exposed using an etch and an etch resistant protect layer 104 is deposited overlaying the edges of the device layers such that they are not exposed to the etch chemicals. The sacrificial layer is then exposed by an etch of vias. A bonding layer 108 is deposited and a selective etch process is used to remove the sacrificial layers. In some embodiments the bonding layer is deposited after the selective etch. This workflow is advantageous when the device layers are susceptible to damage from the etch process used to remove the sacrificial layer. With the sacrificial region exposed a bandgap selective PEC etch is used to undercut the mesas. At this point, the selective area bonding process shown in FIG. 10B is used to continue fabricating devices. In another embodiment the active region is exposed by the dry etch and the active region and sacrificial regions both absorb the pump light. A conductive path is fabricated between the p-type and n-type cladding surrounding the active region. As in a solar cell, carriers are swept from the active region due to the electric field in the depletion region. By electrically connecting the n-type and p-type layers together holes can be continually swept from the active region, slowing or preventing PEC etching. In other embodiments involving electronic devices or power electronic devices that do not contain light emitting layers, no special measures need to be taken to protect the semiconductor device layers during the selective etch.

In one embodiment thermocompression bonding is used to transfer the gallium and nitrogen epitaxial semiconductor layers to the carrier wafer. In this embodiment thermocompression bonding involves bonding of the epitaxial semiconductor layers to the carrier wafer at elevated temperatures and pressures using a bonding media disposed between the epitaxial layers and handle wafer. The bonding media may be comprised of a number of different layers, but typically contain at least one layer (the bonding layer) that is composed of a relatively ductile material with a high surface diffusion rate. In many cases this material is comprised of Au, Al or Cu. The bonding stack may also include layers disposed between the bonding layer and the epitaxial materials or handle wafer that promote adhesion. For example, an Au bonding layer on a Si wafer may result in diffusion of Si to the bonding interface, which would reduce the bonding strength. Inclusion of a diffusion barrier such as silicon oxide or nitride would limit this effect. Relatively thin layers of a second material may be applied on the top surface of the bonding layer in order to promote adhesion between the bonding layers disposed on the epitaxial material and handle. Some bonding layer materials of lower ductility than gold (e.g. Al, Cu etc.) or which are deposited in a way that results in a rough film (for example electrolytic deposition) may require planarization or reduction in roughness via chemical or mechanical polishing before bonding, and reactive metals may require special cleaning steps to remove oxides or organic materials that may interfere with bonding.

Thermocompressive bonding can be achieved at relatively low temperatures, typically below 500 degrees Celsius and above 200. Temperatures should be high enough to promote diffusivity between the bonding layers at the bonding interface, but not so high as to promote unintentional alloying of individual layers in each metal stack. Application of pressure enhances the bond rate, and leads to some elastic and plastic deformation of the metal stacks that brings them into better and more uniform contact. Optimal bond temperature, time and pressure will depend on the particular bond material, the roughness of the surfaces forming the bonding interface and the susceptibility to fracture of the handle wafer or damage to the device layers under load.

The bonding interface need not be composed of the totality of the wafer surface. For example, rather than a blanket deposition of bonding metal, a lithographic process could be used to deposit metal in discontinuous areas separated by regions with no bonding metal. This may be advantageous in instances where defined regions of weak or no bonding aid later processing steps, or where an air gap is needed. One example of this would be in removal of the GaN substrate using wet etching of an epitaxially grown sacrificial layer. To access the sacrificial layer one must etch vias into either of the two surfaces of the epitaxial wafer, and preserving the wafer for re-use is most easily done if the vias are etched from the bonded side of the wafer. Once bonded, the etched vias result in channels that can conduct etching solution from the edges to the center of the bonded wafers, and therefore the areas of the substrate comprising the vias are not in intimate contact with the handle wafer such that a bond would form.

The bonding media can also be an amorphous or glassy material bonded either in a reflow process or anodically. In anodic bonding the media is a glass with high ion content where mass transport of material is facilitated by the application of a large electric field. In reflow bonding the glass has a low melting point and will form contact and a good bond under moderate pressures and temperatures. All glass bonds are relatively brittle, and require the coefficient of thermal expansion of the glass to be sufficiently close to the bonding partner wafers (i.e. the GaN wafer and the handle). Glasses in both cases could be deposited via vapor deposition or with a process involving spin on glass. In both cases the bonding areas could be limited in extent and with geometry defined by lithography or silk-screening process.

Gold-gold metallic bonding is used as an example in this work, although a wide variety of oxide bonds, polymer bonds, wax bonds, etc., are potentially suitable. Submicron alignment tolerances are possible using commercially available die bonding equipment. In another embodiment of the invention the bonding layers can be a variety of bonding pairs including metal-metal, oxide-oxide, soldering alloys, photoresists, polymers, wax, etc. Only epitaxial die which are in contact with a bond bad on the carrier wafer will bond. Sub-micron alignment tolerances are possible on commercially available die or flip chip bonders.

In an example, an oxide is overlaid on an exposed planar n-type or p-type gallium and nitrogen containing material or over an exposed planar n-type or p-type gallium and nitrogen containing material using direct wafer bonding of the surface of the gallium and nitrogen containing material to the surface of a carrier wafer comprised primarily of an oxide or a carrier wafer with oxide layers disposed on them. In both cases the oxide surface on the carrier wafer and the exposed gallium and nitrogen containing material are cleaned to reduce the hydrocarbons, metal ions and other contaminants on the bonding surfaces. The bonding surfaces are then brought into contact and bonded at elevated temperature under applied pressure. In some cases the surfaces are treated chemically with one or more of acids, bases or plasma treatments to produce a surface that yields a weak bond when brought into contact with the oxide surface. For example, the exposed surface of the gallium containing material may be treated to form a thin layer of gallium oxide, which being chemically similar to the oxide bonding surface will bond more readily. Furthermore, the oxide and now gallium oxide terminated surface of the gallium and nitrogen containing material may be treated chemically to encourage the formation of dangling hydroxyl groups (among other chemical species) that will form temporary or weak chemical or van der Waals bonds when the surfaces are brought into contact, which are subsequently made permanent when treated at elevated temperatures and elevated pressures.

The carrier wafer can be chosen based on any number of criteria including but not limited to cost, thermal conductivity, thermal expansion coefficients, size, electrical conductivity, optical properties, and processing compatibility. The patterned epitaxy wafer is prepared in such a way as to allow subsequent selective release of bonded epitaxy regions. The patterned carrier wafer is prepared such that bond pads are arranged in order to enable the selective area bonding process. These wafers can be prepared by a variety of process flows, some embodiments of which are described below. In the first selective area bond step, the epitaxy wafer is aligned with the pre-patterned bonding pads on the carrier wafer and a combination of pressure, heat, and/or sonication is used to bond the mesas to the bonding pads.

In one embodiment of the invention the carrier wafer is another semiconductor material, a metallic material, or a ceramic material. Some potential candidates include silicon, glass, gallium arsenide, sapphire, silicon carbide, diamond, gallium nitride, AlN, polycrystalline AlN, indium phosphide, germanium, quartz, copper, gold, silver, aluminum, aluminum oxynitride, stainless steel, or steel.

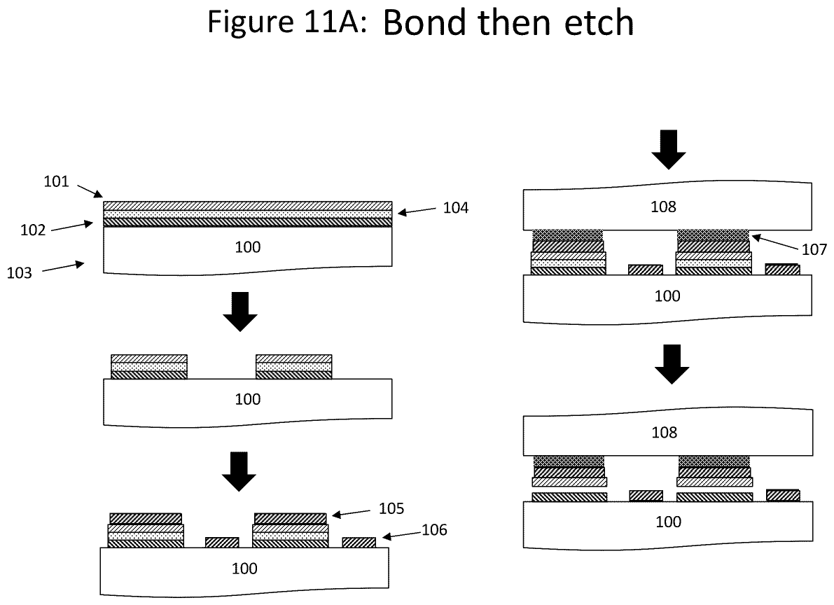

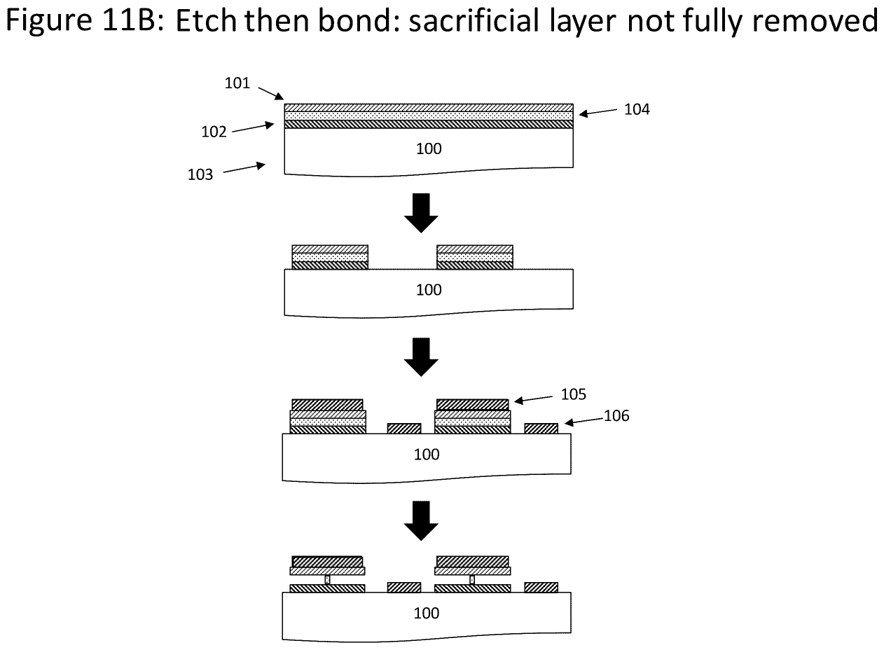

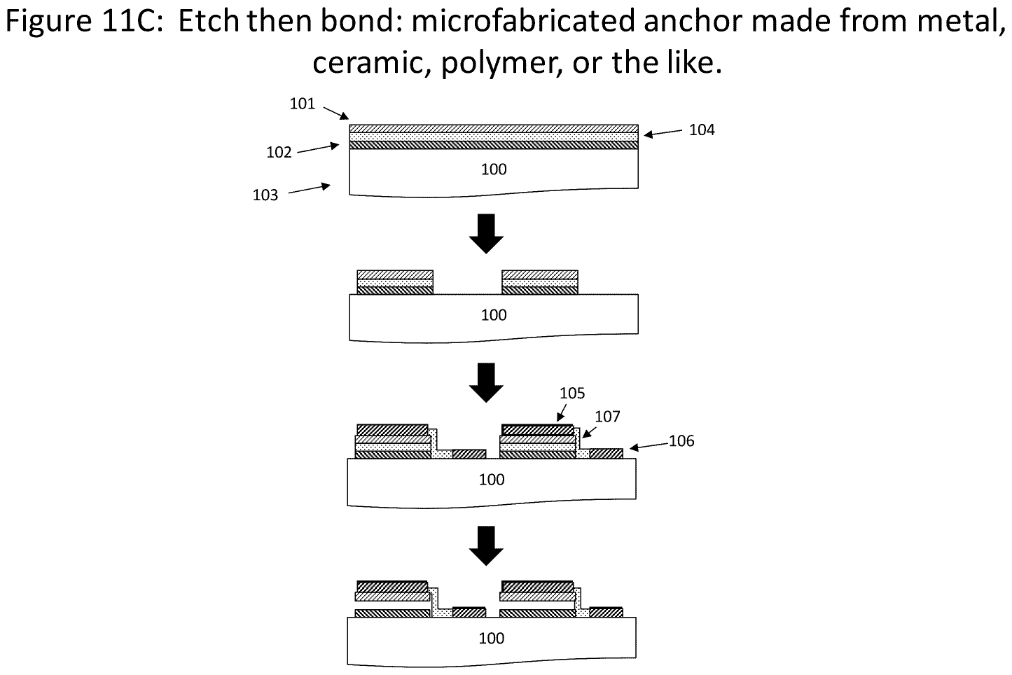

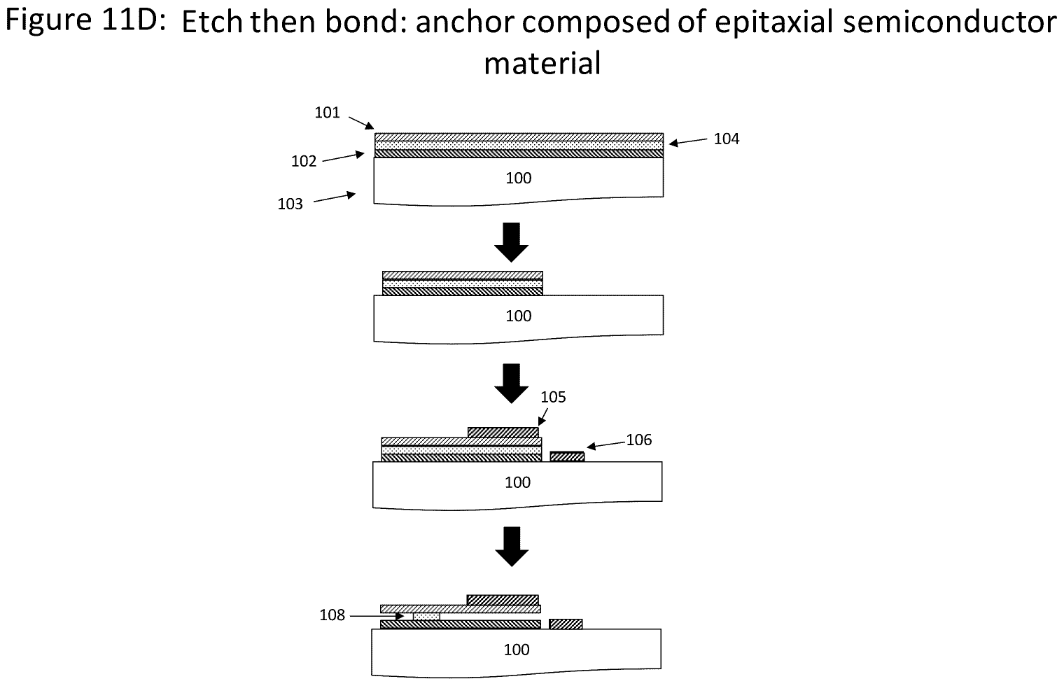

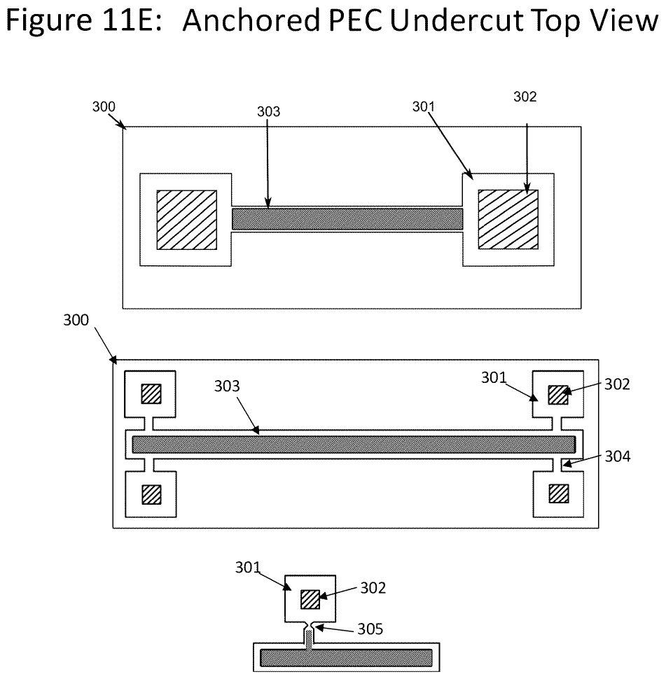

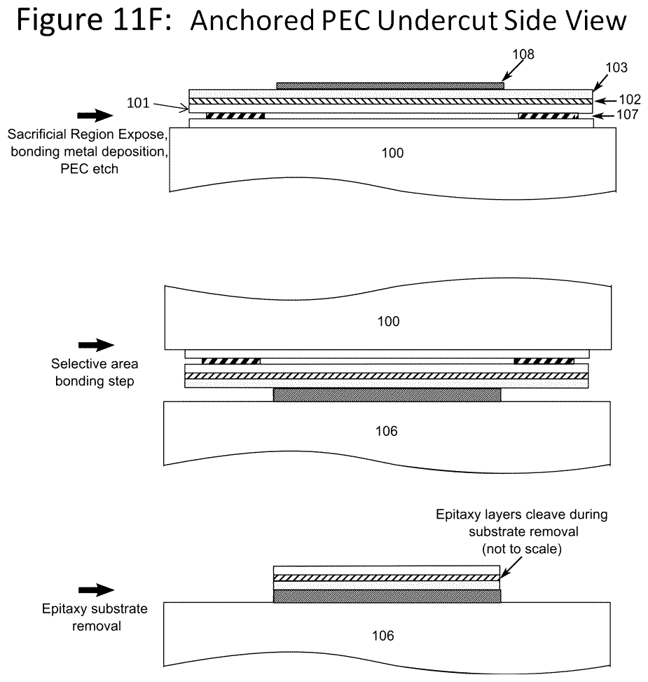

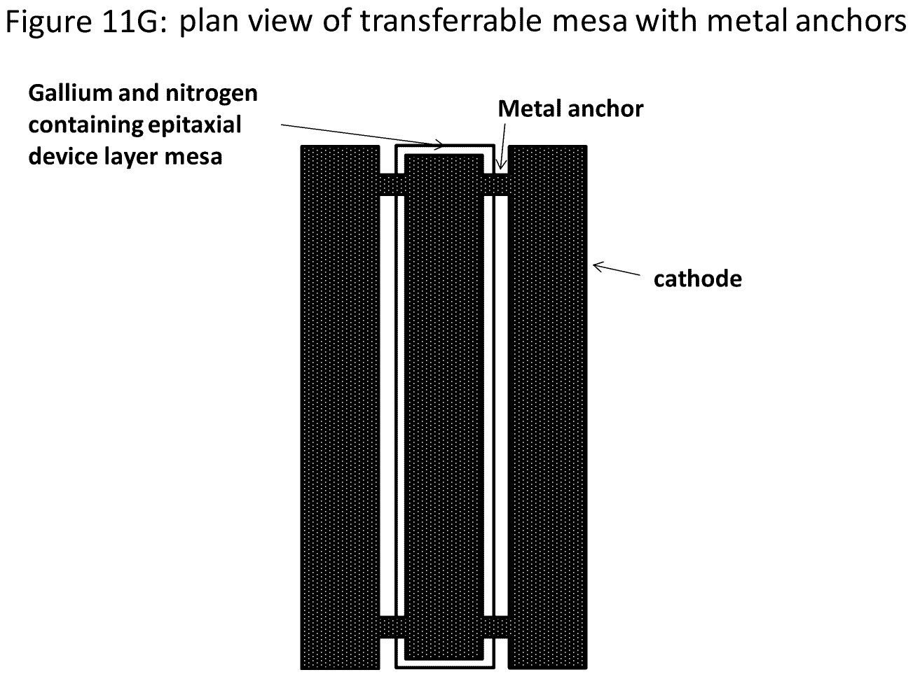

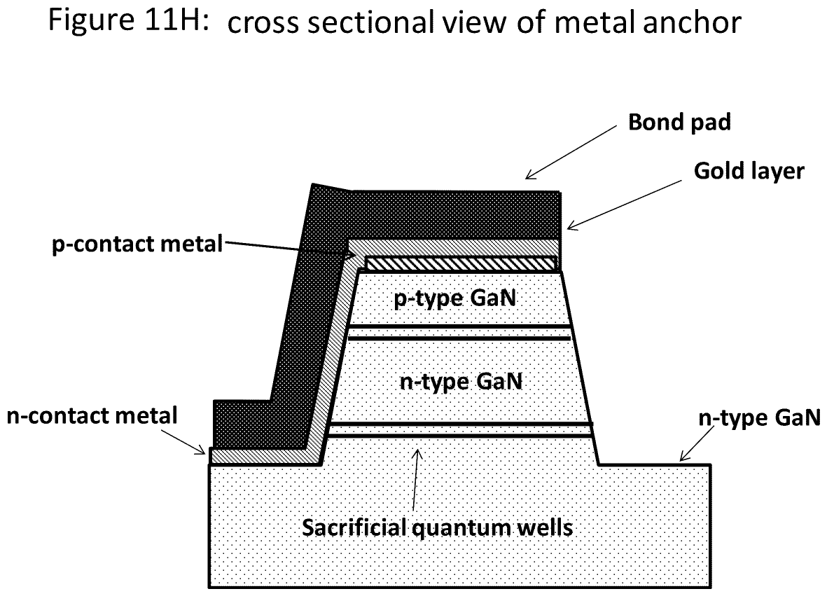

In one embodiment of this invention, the bonding of the semiconductor device epitaxial material to the carrier wafer process can be performed prior to the selective etching of the sacrificial region and subsequent release of the gallium and nitrogen containing substrate. FIG. 11A is a schematic illustration of a process comprised of first forming the bond between the gallium and nitrogen containing epitaxial material formed on the gallium and nitrogen containing substrate and then subjecting the release material to the PEC etch process to release the gallium and nitrogen containing substrate. In this embodiment, an epitaxial material is deposited on the gallium and nitrogen containing substrate, such as a GaN substrate, through an epitaxial deposition process such as metal organic chemical vapor deposition (MOCVD), molecular beam epitaxy (MBE), or other. The epitaxial material consists of at least a sacrificial release layer and one or more device layers. In some embodiments a buffer layer is grown on between the substrate surface region and the sacrificial release region. In FIG. 11A substrate wafer 101 is overlaid by a buffer layer 102, a selectively etchable sacrificial layer 104 and a collection of device layers 101. The sacrificial layer is exposed using the process described in FIG. 10A. The bond layer 105 is deposited along with a cathode metal 106 that will be used to facilitate the photoelectrochemical etch process for selectively removing the sacrificial layer.

FIGS. 11A-11I, as well as the other figures in this application, are for illustrative purposes only and the physical dimensions and proportions are not intended to be exact for an LED.

The device layers can be comprised of many configurations suited for the specific semiconductor device. For example, an LED device structure would be comprised of one or more n-type gallium and nitrogen containing layers, an active region comprised of one or more quantum well layers, and one or more p-type gallium and nitrogen layers. The epitaxial material is subjected to processing steps such as metal and dielectric deposition steps, lithography, and etching steps to form mesa regions with a bond region on the top. The carrier wafer 108 which is patterned with bond pads 107 is brought into contact with the bond layers 105 using a precision alignment process. After the bonding process is complete, the sacrificial etch is carried out. The selective etch of the sacrificial layer releases the mesas from the substrate.

In a preferred embodiment of this invention, the bonding process is performed after the selective etching of the sacrificial region. This embodiment offers several advantages. One advantage is easier access for the selective etchant to uniformly etch the sacrificial region across the semiconductor wafer comprising a bulk gallium and nitrogen containing substrate such as GaN and bulk gallium and nitrogen containing epitaxial device layers. A second advantage is the ability to perform multiple bond steps. In an example, FIG. 11B is a schematic representation of the “etch then bond” process flow where the mesas are retained on the substrate by controlling the etch process such that not all of the sacrificial layer is removed. A substrate wafer 101 is overlaid by a buffer layer 102, a selectively etchable sacrificial layer 104 and a collection of device layers 101. The sacrificial layer is exposed using the process described in FIG. 10A. The bond layer 105 is deposited along with a cathode metal 106 that will be used to facilitate the photoelectrochemical etch process for selectively removing the sacrificial layer. The selective etch process is carried out to the point where only a small fraction of the sacrificial layer is remaining, such that the mesas are retained on the substrate, but the unetched portions of the sacrificial layer are easily broken during or after the mesas are bonded to the carrier wafer.

A critical challenge of the etch then bond embodiment is mechanically supporting the undercut epitaxial device layer mesa region from spatially shifting prior to the bonding step. If the mesas shift the ability to accurately align and arrange them to the carrier wafer will be compromised, and hence the ability to manufacture with acceptable yields. This challenge mechanically fixing the mesa regions in place prior to bonding can be achieved in several ways. In a preferred embodiment anchor regions are used to mechanically support the mesas to the gallium and nitrogen containing substrate prior to the bonding step wherein they are releases from the gallium and nitrogen containing substrate and transferred to the carrier wafer.

Anchor regions are special features that can be designed into the photo masks which attach the undercut device layers to the gallium and nitrogen containing substrate, but which are too large to themselves be undercut, or which due to the design of the mask contain regions where the sacrificial layers are not removed or these features may be composed of metals or dielectrics that are resistant to the etch. In some embodiments, the anchor regions may be formed using passivating dielectric layers. A reflective coating on top of the dielectric layers may assist with light extraction. These features act as anchors, preventing the undercut device layers from detaching from the substrate and prevent the device layers from spatially shifting. This attachment to the substrate can also be achieved by incompletely removing the sacrificial layer, such that there is a tenuous connection between the undercut device layers and the substrate which can be broken during bonding. The surfaces of the bonding material on the carrier wafer and the device wafer are then brought into contact and a bond is formed which is stronger than the attachment of the undercut device layers to the anchors or remaining material of the sacrificial layers. After bonding, the separation of the carrier and device wafers transfers the device layers to the carrier wafer.

In one embodiment the anchor region is formed by features that are wider than the device layer mesas such that the sacrificial region in these anchor regions is not fully removed during the undercut of the device layers. FIG. 11C is a schematic representation of the “etch then bond” process flow where the mesas are retained on the substrate by deposition of an etch resistant material acting as an anchor by connecting the mesas to the substrate. A substrate wafer 101 is overlaid by a buffer layer 102, a selectively etchable sacrificial layer 104 and a collection of device layers 101. The sacrificial layer is exposed using the process described in FIG. 10A. The bond layer 105 is deposited along with a cathode metal 106 that will be used to facilitate the photoelectrochemical etch process for selectively removing the sacrificial layer. A layer of etch resistant material 107, which may be composed of metal, ceramic, polymer or a glass, is deposited such that it connects to both the mesa and the substrate. The selective etch process is carried out such that the sacrificial layer is fully removed and only the etch-resistant layer 107 connects the mesa to the substrate.

FIG. 11D is a simplified schematic representation of the “etch then bond” process flow where the mesas are retained on the substrate by use of an anchor composed of epitaxial material. A substrate wafer 101 is overlaid by a buffer layer 102, a selectively etchable sacrificial layer 104 and a collection of device layers 101. The sacrificial layer is exposed using the process described in FIG. 10A. The bond layer 105 is deposited along with a cathode metal 106 that will be used to facilitate the photoelectrochemical etch process for selectively removing the sacrificial layer. The anchor is shaped such that during the etch, a small portion of the sacrificial layer remains unetched 108 and creates a connection between the undercut mesa and the substrate wafer.

In one embodiment the anchors are positioned either at the ends or sides of the undercut die such that they are connected by a narrow undercut region of material. FIG. 11E shows this configuration as the “peninsular” anchor. The narrow connecting material 304 is far from the bond metal and is design such that the undercut material cleaves at the connecting material rather than across the die. This has the advantage of keeping the entire width of the die undamaged, which would be advantageous. In another embodiment, geometric features are added to the connecting material to act as stress concentrators 305 and the bond metal is extended onto the narrow connecting material. The bond metal reinforces the bulk of the connecting material. Adding these features increases the control over where the connection will cleave. These features can be triangles, circles, rectangles or any deviation that provides a narrowing of the connecting material or a concave profile to the edge of the connecting material.

In another embodiment the anchors are of small enough lateral extent that they may be undercut, however a protective coating is used to prevent etch solution from accessing the sacrificial layers in the anchors. This embodiment is advantageous in cases when the width of the die to be transferred is large. Unprotected anchors would need to be larger to prevent complete undercutting, which would reduce the density of die and reduce the utilization efficiency of epitaxial material.

In another embodiment, the anchors are located at the ends of the die and the anchors form a continuous strip of material that connects to all or a plurality of die. This configuration is advantageous since the anchors can be patterned into the material near the edge of wafers or lithographic masks where material utilization is otherwise poor. This allows for utilization of device material at the center of the pattern to remain high even when die sizes become large.

In a preferred embodiment the anchors are formed by depositing regions of an etch-resistant material that adheres well to the epitaxial and substrate material. These regions overlay a portion of the semiconductor device layer mesa and some portion of the structure that will not be undercut during the etch such as the substrate. These regions form a continuous connection, such that after the semiconductor device layer mesa is completely undercut they provide a mechanical support preventing the semiconductor device layer mesa from detaching from the substrate. Metal layers are then deposited on the top of semiconductor device layer mesa, the sidewall of the semiconductor device layer mesa and the bottom of the etched region surrounding the mesa such that a continuous connection is formed. As an example, the metal layers could comprise about 20 nm of titanium to provide good adhesion and be capped with about 500 nm of gold, but of course the choice of metal and the thicknesses could be others. In an example, the length of the semiconductor device die sidewall coated in metal is about 1 nm to about 40 nm, with the upper thickness being less than the width of the semiconductor device die such that the sacrificial layer is etched completely in the region near the metal anchor where access to the sacrificial layer by etchant will be limited.

FIG. 11E shows a top-view schematic of an example of a transferable mesa of GaN epitaxial material with a metal anchor bridging between the bond metal on the top of the mesa and the cathode metal in the etched field. FIG. 11F presents a cross-sectional view of an example of a transferable semiconductor device layer mesa at the location of a metal anchor. Here the mesa is formed by dry or wet chemical etching, and for an example of an LED structure includes the one or more p-type GaN layers, the light emitting layers, and the one or more n-type GaN layers, the sacrificial layer, and a portion of the n-type GaN epitaxial layer beneath the sacrificial layer. A p-contact metal is first deposited on the p-type GaN in order to form a high quality electrical contact with the p-type GaN. A second metal stack is then patterned and deposited on the mesa, overlaying the p-contact metal. The second metal stack consists of an n-contact metal, forming a good electrical contact with the n-type GaN beneath the sacrificial layer, as well as a relatively thick metal layer that acts as both the mesa bond pad as well as the cathode metal. The bond/cathode metal also forms a thick layer overlaying the edge of the mesa and providing a continuous connection between the mesa top and the substrate. After the sacrificial layer is removed by selective photochemical etching the thick metal provides mechanical support to retain the mesa in position on the GaN wafer until the bonding to the carrier wafer is carried out.

FIG. 11G is a simplified top-view schematic of metal anchor features providing mechanical support to epitaxial mesas in an example of the present invention. FIG. 11H is a simplified side-view schematic of process flow for using metal anchor features providing mechanical support to epitaxial mesas in an example of the present invention.

FIG. 11I is a schematic representation of charge flow in a device using a metal anchor during PEC etching of the sacrificial layer. It is possible to selectively etch the sacrificial layer even if the pump light is absorbed by the active region. Etching in the PEC process is achieved by the dissolution of AlInGaN materials at the wafer surface when holes are transferred to the etching solution. These holes are then recombined in the solution with electrons extracted at the cathode metal interface with the etching solution. Charge neutrality is therefore achieved. Selective etching is achieved by electrically shorting the anode to the cathode. Electron hole pairs generated in the device light emitting layers are swept out of the light emitting layers by the electric field of the of the p-n junction. Since holes are swept out of the active region, there is little or no etching of the light emitting layer. The buildup of carriers produces a potential difference that drives carriers through the metal anchors where they recombine. The flat band conditions in the sacrificial region result in a buildup of holes that result in rapid etching of the sacrificial layers.

The use of metal anchors as shown have several advantages over the use of anchors made from the epitaxial device material. The first is density of the transferrable mesas on the donor wafer containing the epitaxial semiconductor device layers and the gallium and nitrogen containing bulk substrate or on the foreign substrate in the case of hetereopitaxy. Anchors made from the epitaxial material must be large enough to not be fully undercut by the selective etch, or they must be protected somehow with a passivating layer. The inclusion of a large feature that is not transferred will reduce the density of mesas in one or more dimensions on the epitaxial device wafer. The use of metal anchors is preferable because the anchors are made from a material that is resistant to etch and therefore can be made with small dimensions that do not impact mesa density. The second advantage is that it simplifies the processing of the mesas because a separate passivating layer is no longer needed to isolate the active region from the etch solution. Removing the active region protecting layer reduces the number of fabrication steps while also reducing the size of the mesa required.

In a particular embodiment, the cathode metal stack also includes metal layers intended to increase the strength of the metal anchors. For example, the cathode metal stack might consist of 100 nm of Ti to promote adhesion of the cathode metal stack and provide a good electrical contact to the n-type cladding. The cathode metal stack could then incorporate a layer of tungsten, which has an elastic modulus on the order of four times higher than gold. Incorporating the tungsten would reduce the thickness of gold required to provide enough mechanical support to retain the mesas after they are undercut by the selective etch.

In another embodiment of the invention the sacrificial region is completely removed by PEC etching and the mesa remains anchored in place by any remaining defect pillars. PEC etching is known to leave intact material around defects which act as recombination centers. Additional mechanisms by which a mesa could remain in place after a complete sacrificial etch include static forces or Van der Waals forces. In one embodiment the undercutting process is controlled such that the sacrificial layer is not fully removed.

In a preferred embodiment, the semiconductor device epitaxy material with the underlying sacrificial region is fabricated into a dense array of mesas on the gallium and nitrogen containing bulk substrate or foreign substrate with the overlying semiconductor device layers. The mesas are formed using a patterning and a wet or dry etching process wherein the patterning comprises a lithography step to define the size and pitch of the mesa regions. Dry etching techniques such as reactive ion etching, inductively coupled plasma etching, or chemical assisted ion beam etching are candidate methods. Alternatively, a wet etch can be used. The etch is configured to terminate at or below the one or more sacrificial region below the device layers. This is followed by a selective etch process such as PEC to fully or partially etch the exposed sacrificial region such that the mesas are undercut. This undercut mesa pattern pitch will be referred to as the ‘first pitch’. The first pitch is often a design width that is suitable for fabricating each of the epitaxial regions on the substrate, while not large enough for the desired completed semiconductor device design, which often desire larger non-active regions or regions for contacts and the like. For example, these mesas would have a first pitch ranging from about 5 microns to about 500 microns or to about 5000 microns. Each of these mesas is a ‘die’.

In a preferred embodiment, these die are transferred to a carrier wafer at a second pitch using a selective bonding process such that the second pitch on the carrier wafer is greater than the first pitch on the gallium and nitrogen containing substrate. In this embodiment the die are on an expanded pitch for so called “die expansion”. In an example, the second pitch is configured with the die to allow each die with a portion of the carrier wafer to be a semiconductor device, including contacts and other components. For example, the second pitch would be about 50 microns to about 1000 microns or to about 5000 microns but could be as large at about 3-10 mm or greater in the case where a large semiconductor device chip is required for the application. The larger second pitch could enable easier mechanical handling without the expense of the costly gallium and nitrogen containing substrate and epitaxial material, allow the real estate for additional features to be added to the semiconductor device chip such as bond pads that do not require the costly gallium and nitrogen containing substrate and epitaxial material, and/or allow a smaller gallium and nitrogen containing epitaxial wafer containing epitaxial layers to populate a much larger carrier wafer for subsequent processing for reduced processing cost. For example, a 4 to 1 die expansion ratio would reduce the density of the gallium and nitrogen containing material by a factor of 4, and hence populate an area on the carrier wafer 4 times larger than the gallium and nitrogen containing substrate. This would be equivalent to turning a 2″ gallium and nitrogen substrate into a 4″ carrier wafer. In particular, the present invention increases utilization of substrate wafers and epitaxy material through a selective area bonding process to transfer individual die of epitaxy material to a carrier wafer in such a way that the die pitch is increased on the carrier wafer relative to the original epitaxy wafer. The arrangement of epitaxy material allows device components which do not require the presence of the expensive gallium and nitrogen containing substrate and overlying epitaxy material often fabricated on a gallium and nitrogen containing substrate to be fabricated on the lower cost carrier wafer, allowing for more efficient utilization of the gallium and nitrogen containing substrate and overlying epitaxy material.

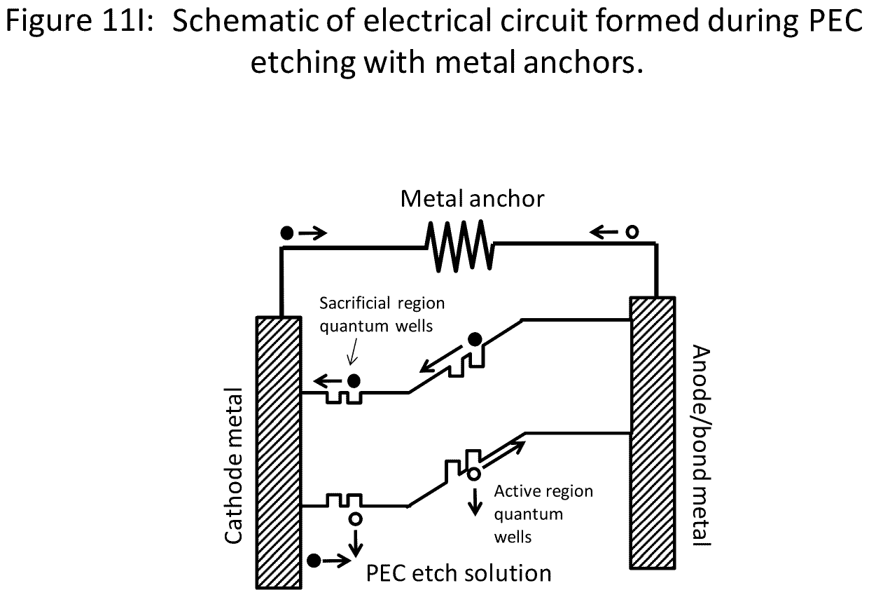

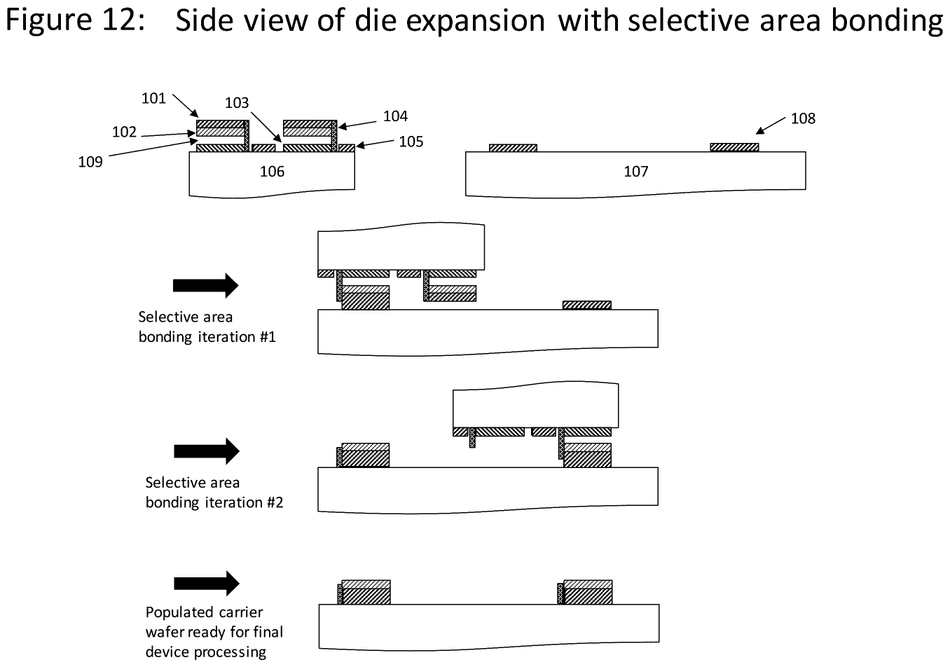

FIG. 12 is a schematic representation of the die expansion process with selective area bonding according to the present invention. A device wafer is prepared for bonding in accordance with an embodiment of this invention. The wafer consists of a substrate 106, buffer layers 103, the fully removed sacrificial layer 109, the device layers 102, the bonding media 101, the cathode metal utilized in the PEC etch removal of the sacrificial layer and the anchor material 104. The mesa regions formed in the gallium and nitrogen containing epitaxial wafer form dice of epitaxial material and release layers defined through processing. Individual epitaxial material die are formed at first pitch. A carrier wafer is prepared consisting of the carrier wafer 107 and bond pads 108 at second pitch. The substrate is aligned to the carrier wafer such that a subset of the mesa on the gallium and nitrogen containing substrate with a first pitch align with a subset of bond pads on the carrier at a second pitch. Since the first pitch is greater than the second pitch and the mesas will comprise device die, the basis for die expansion is established. The bonding process is carried out and upon separation of the substrate from the carrier wafer the subset of mesas are selectively transferred to the carrier. The process is then repeated with a second set of mesas and bond pads on the carrier wafer until the carrier wafer is populated fully by epitaxial mesas. The gallium and nitrogen containing epitaxy substrate 201 can now optionally be prepared for reuse.

In the example depicted in FIG. 12, one quarter of the epitaxial die are transferred in this first selective bond step, leaving three quarters on the epitaxy wafer. The selective area bonding step is then repeated to transfer the second quarter, third quarter, and fourth quarter of the epitaxial die to the patterned carrier wafer. This selective area bond may be repeated any number of times and is not limited to the four steps depicted in FIG. 12. The result is an array of epitaxial die on the carrier wafer with a wider die pitch than the original die pitch on the epitaxy wafer. The die pitch on the epitaxial wafer will be referred to as pitch 1, and the die pitch on the carrier wafer will be referred to as pitch 2, where pitch 2 is greater than pitch 1.

In one embodiment the bonding between the carrier wafer and the gallium and nitrogen containing substrate with epitaxial layers is performed between bonding layers that have been applied to the carrier and the gallium and nitrogen containing substrate with epitaxial layers. The bonding layers can be a variety of bonding pairs including metal-metal, oxide-oxide, soldering alloys, photoresists, polymers, wax, etc. Only epitaxial die which are in contact with a bond bad on the carrier wafer will bond. Sub-micron alignment tolerances are possible on commercial die bonders. The epitaxy wafer is then pulled away, breaking the epitaxy material at a weakened epitaxial release layer such that the desired epitaxial layers remain on the carrier wafer. Herein, a ‘selective area bonding step’ is defined as a single iteration of this process.

In one embodiment, the carrier wafer is patterned in such a way that only selected mesas come in contact with the metallic bond pads on the carrier wafer. When the epitaxy substrate is pulled away the bonded mesas break off at the weakened sacrificial region, while the un-bonded mesas remain attached to the epitaxy substrate. This selective area bonding process can then be repeated to transfer the remaining mesas in the desired configuration. This process can be repeated through any number of iterations and is not limited to the two iterations depicted in FIG. 12. The carrier wafer can be of any size, including but not limited to about 2 inch, 3 inch, 4 inch, 6 inch, 8 inch, and 12 inch. After all desired mesas have been transferred, a second bandgap selective PEC etch can be optionally used to remove any remaining sacrificial region material to yield smooth surfaces. At this point standard semiconductor device processes can be carried out on the carrier wafer. Another embodiment of the invention incorporates the fabrication of device components on the dense epitaxy wafers before the selective area bonding steps.

In an example, the present invention provides a method for increasing the number of gallium and nitrogen containing semiconductor devices which can be fabricated from a given epitaxial surface area; where the gallium and nitrogen containing epitaxial layers overlay gallium and nitrogen containing substrates. The gallium and nitrogen containing epitaxial material is patterned into die with a first die pitch; the die from the gallium and nitrogen containing epitaxial material with a first pitch is transferred to a carrier wafer to form a second die pitch on the carrier wafer; the second die pitch is larger than the first die pitch.

In an example, each epitaxial device die is an etched mesa with a pitch of between about 1 μm and about 100 μm wide or between about 100 micron and about 500 microns wide or between about 500 micron and about 3000 microns wide and between about 100 and about 3000 μm long. In an example, the second die pitch on the carrier wafer is between about 100 microns and about 200 microns or between about 200 microns and about 1000 microns or between about 1000 microns and about 3000 microns. In an example, the second die pitch on the carrier wafer is between about 2 times and about 50 times larger than the die pitch on the epitaxy wafer. In an example, semiconductor LED devices or electronic devices are fabricated on the carrier wafer after epitaxial transfer. In an example, the semiconductor devices contain GaN, AlN, InN, InGaN, AlGaN, InAlN, and/or InAlGaN. In an example, the gallium and nitrogen containing material are grown on a polar, nonpolar, or semipolar plane. In an example, one or multiple semiconductor devices are fabricated on each die of epitaxial material. In an example, device components, which do not require epitaxy material are placed in the space between epitaxy die.

In one embodiment, device dice are transferred to a carrier wafer such that the distance between die is expanded in both the transverse as well as lateral directions. This can be achieved by spacing bond pads on the carrier wafer with larger pitches than the spacing of device die on the substrate.

In another embodiment of the invention device dice from a plurality of epitaxial wafers are transferred to the carrier wafer such that each design width on the carrier wafer contains dice from a plurality of epitaxial wafers. When transferring die at close spacings from multiple epitaxial wafers, it is important for the un-transferred die on the epitaxial wafer to not inadvertently contact and bond to die already transferred to the carrier wafer. To achieve this, die from a first epitaxial wafer are transferred to a carrier wafer using the methods described above. A second set of bond pads are then deposited on the carrier wafer and are made with a thickness such that the bonding surface of the second pads is higher than the top surface of the first set of transferred die. This is done to provide adequate clearance for bonding of the die from the second epitaxial wafer. A second substrate transfer a second set of die to the carrier. Finally, the semiconductor devices are fabricated and passivation layers are deposited followed by electrical contact layers that allow each dice to be individually driven. The die transferred from the first and second substrates are spaced at a pitch which is smaller than the second pitch of the carrier wafer. This process can be extended to transfer of die from any number of substrates, and to the transfer of any number of devices per dice from each substrate.

In some embodiments, multiple semiconductor device die are transferred to a single carrier wafer and placed within close proximity to each other. Dice in close proximity are preferably within one millimeter of each other but could be other.

In another embodiment of the invention individual PEC undercut etches are used after each selective bonding step for etching away the sacrificial release layer of only bonded mesas. Which epitaxial die get undercut is controlled by only etching down to expose the sacrificial layer of mesas which are to be removed on the current selective bonding step. The advantage of this embodiment is that only a very coarse control of PEC etch rates is required. This comes at the cost of additional processing steps and geometry constrains.

An important breakthrough of this technology is enabling the die expansion technology as described above. By enabling the gallium and nitrogen containing epitaxial layer dice to be transferred to the carrier wafer at a larger pitch the expensive gallium and nitrogen containing substrate and epitaxial device layers can be more efficiently utilized. Additionally, a larger area will be required on the carrier wafer than the area of the gallium and nitrogen containing substrate.

With the basics of the invention describing the transfer of the gallium and nitrogen containing device layers from the bulk gallium and nitrogen containing substrate to a carrier wafer using a PEC undercut and bonding technology described that enables die expansion, leveraging of large carrier wafer size for fabrication, re-use of native gallium and nitrogen containing substrates, and integration of multiple functionality semiconductor devices, specific examples of device layers and the resulting devices can now be described. This invention can be extended to many and almost all semiconductor devices so the descriptions provided here are merely examples and there could be many others.

In an embodiment of this invention, the epitaxial device layers comprise an AlInGaN light emitting diode (LED). AlInGaN LEDs contain n-type and p-type cladding layers surrounding light emitting layers. The p-GaN is typically kept thin with p-GaN thicknesses typically on the order of 100-300 nm and preferably on the order of 0.5 to 1.5 times the wavelength in GaN of the light emitted from the LED. The p-contact metal is usually either highly reflective, such as Ag or Al, a diffusion Bragg reflector (DBR), or in the case where light is extracted through the p-GaN surface, the p-contact is formed from a transparent conductive oxide (i.e., ITO or ZnO) such that adequate current spreading is achieved in the relatively resistive but thin p-GaN. The n-type cladding is normally thicker than the p-type. Often the surface of the n-type GaN is roughened or the interface between the n-type GaN and a heteroepitaxial substrate (as in the case of GaN grown on sapphire) is roughened so as to scatter light out of the crystal.

AlInGaN LEDs are typically more efficient as the operational current density is reduced. In order to produce useful amounts of light with high efficiency, LED die tend to be relatively large compared to other devices such as laser diodes. State of the art LEDs often have areas bigger than 1 mm2, and at industry standard operating currents of 350, 750 and 1000 mA operate at current densities of 35, 75 and 100 A/cm2. These current densities are 1-2 orders of magnitude lower than typical operational current densities for state of the art high-power blue-light-emitting GaN laser diodes. Due to the large amount of epitaxial material used in LEDs it is highly advantageous for manufacturers to utilize as high a fraction of the epitaxial material as possible from each wafer, and unlike a conventional laser diode the majority of the device area is light emitting.

In an embodiment of this invention, a gallium and nitrogen containing substrate is overlaid with epitaxially grown device layers. Overlaying the substrate is a n-type GaN buffer layer which may vary in thickness from 0.25 to 5 microns. Overlaying the n-type GaN buffer is a sacrificial region composed of one or more InGaN quantum wells with InN concentrations of approximately 10%. These sacrificial wells may vary in thickness from 1 to 10 nm or larger depending on composition. The sacrificial wells are selectively etchable, relative to the surrounding GaN, using a photoelectrochemical (PEC) etch process where the sacrificial InGaN is optically pumped with wavelengths of light shorter than 450 nm. Overlying the sacrificial InGaN layers are an n-type contact layer and an n-type GaN current spreading layer. The contact layer is highly doped with a carrier concentration of 1E18 to 1E20 cm−3, while the n-type current spreading layer is more lightly doped with carrier concentrations from 1E17 to 5E18 cm−3. The n-type current spreading layer may vary in thickness from 0.25 to 5 microns but will typically be on the order of 2 microns. Above the n-type current spreading layer is an n-type InGaN buffer layer. The n-InGaN buffer will have a total thickness of 25 to 100 nm and may be either a single InGaN layer of low composition (<10% InN) or may consist of a short-period superlattice of alternating GaN and InGaN layers. Overlaying the n-InGaN buffer is an active region consisting of one or more InGaN quantum wells with thickness between 1.5 and 10 nm separated by barriers of substantially wider bandgap. Typically the barriers will be formed from GaN. Overlying the active region is a GaN upper barrier with thickness varying from 5 to 50 nm. Overlaying the GaN upper barrier is an electron blocking layer with thickness of 10 to 50 nm. Typically the electron blocking layer (EBL) will be composed of a material with a wider bandgap than GaN. In many cases this is AlGaN, with typical compositions ranging from 10 to 30% AlN. In some embodiments the EBL will be composed of a AlGaInN quaternary alloy. In general the EBL is doped highly p-type, with Mg concentrations on the order of 3E18 cm−3 or higher. Overlaying the EBL is a p-type GaN layer ranging in thickness from 50 to 400 nm. The upper 10-50 nm of the p-type GaN consists of a p-contact layer that is heavily doped with Mg concentrations typically above 1E20 cm−3. The n-type InGaN buffer is typically included to improve the internal quantum efficiency of the LED. Many explanations are given for the mechanism behind this improvement, including relaxation of strain in the active region quantum wells, a surfactant effect of the indium resulting in advantageous surface morphology during active region growth and alteration of the electric fields in the active region.

In an alternative embodiment the gallium and nitrogen containing epitaxial LED device layers could be provided by heteroepitaxial growth on a substrate that is not gallium nitride. These heteroepitaxial substrates may include sapphire, SiC, gallium oxide, spinel, lanthanum aluminate, magnesium oxide, and silicon among others. In one embodiment, the gallium and nitrogen containing epitaxial materials are deposited on sapphire or SiC due to their relatively low cost and ability to achieve relatively low defectivity and low strain epitaxial films. In an alternative embodiment the gallium and nitrogen containing epitaxial materials are deposited on silicon wafers due to the low cost of silicon wafers and availability of large area silicon wafers; i.e. wafers with greater than 150 mm diameter. The epitaxial layer structure would look very similar to that described above wherein the GaN substrate would be replaced by the foreign substrate such as sapphire, SiC, or silicon. Further, in many embodiments of hetereoepitaxial growth a nucleation layer would be included on the foreign substrate underlying the buffer layer.

In another embodiment of this invention, a gallium and nitrogen containing substrate is overlaid with epitaxially grown device layers. Overlaying the substrate is a n-type GaN buffer layer which may vary in thickness from 0.25 to 5 microns. Overlaying the n-type GaN buffer is an n-type InGaN buffer layer. The n-InGaN buffer will have a total thickness of 25 to 100 nm and may be either a single InGaN layer of low composition (<10% InN) or may consist of a short-period superlattice of alternating GaN and InGaN layers. Overlaying the n-InGaN buffer is a sacrificial region composed of one or more InGaN quantum wells with InN concentrations of approximately 10%. These sacrificial wells may vary in thickness from 1 to 10 nm or larger depending on composition. The sacrificial wells are selectively etchable, relative to the surrounding GaN, using a photoelectrochemical etch process where the sacrificial InGaN is optically pumped with wavelengths of light shorter than 450 nm. Overlying the sacrificial InGaN layers are an n-type contact layer and an n-type GaN current spreading layer. The contact layer is highly doped with a carrier concentration of 1E18 to 1E20 cm−3, while the n-type current spreading layer is more lightly doped with carrier concentrations from 1E17 to 5E18 cm−3. The n-type current spreading layer may vary in thickness from 0.25 to 5 microns but will typically be on the order of 2 microns. Above the n-type current spreading layer is an active region consisting of one or more InGaN quantum wells with thickness between 1.5 and 10 nm separated by barriers of substantially wider bandgap. Typically the barriers will be formed from GaN. Overlying the active region is a GaN upper barrier with thickness varying from 5 to 50 nm. Overlaying the GaN upper barrier is an electron blocking layer with thickness of 10 to 50 nm. Typically the electron blocking layer (EBL) will be composed of a material with a wider bandgap than GaN. In many cases this is AlGaN, with typical compositions ranging from 10 to 30% AlN. In some embodiments the EBL will be composed of a AlGaInN quaternary alloy. In general the EBL is doped highly p-type, with Mg concentrations on the order of 3E18 cm−3 or higher. Overlaying the EBL is a p-type GaN layer ranging in thickness from 50 to 400 nm. The upper 10-50 nm of the p-type GaN consists of a p-contact layer that is heavily doped with Mg concentrations typically above 1E20 cm−3.

In an alternative embodiment the gallium and nitrogen containing epitaxial LED device layers could be provided by heteroepitaxial growth on a substrate that is not gallium nitride. These heteroepitaxial substrates may include sapphire, SiC, gallium oxide, spinel, lanthanum aluminate, magnesium oxide, and silicon among others. In one embodiment, the gallium and nitrogen containing epitaxial materials are deposited on sapphire or SiC due to their relatively low cost and ability to achieve relatively low defectivity and low strain epitaxial films. In an alternative embodiment the gallium and nitrogen containing epitaxial materials are deposited on silicon wafers due to the low cost of silicon wafers and availability of large area silicon wafers; i.e. wafers with greater than 150 mm diameter. The epitaxial layer structure would look very similar to that described above wherein the GaN substrate would be replaced by the foreign substrate such as sapphire, SiC, or silicon. Further, in many embodiments of hetereoepitaxial growth a nucleation layer would be included on the foreign substrate underlying the buffer layer.

In an embodiment, blue and green LEDs based on gallium and nitrogen containing epitaxial materials could be provided by heteroepitaxial growth of on a substrate that is not gallium nitride. These heteroepitaxial substrates may include sapphire, SiC, gallium oxide, spinel, lanthanum aluminate, magnesium oxide, and silicon among others. The orientation of these gallium and nitrogen containing epitaxial films may be configured with a polar surface such as a c-plane surface, a nonpolar surface such as an m-plane surface, or a semipolar surface such as a {30-32}, {20-21}, {30-31}, {50-51}, {30-3-2}, {20-2-1}, {30-3-1}, {50-5-1}, {11-22}, or {10-1-1}. In some embodiments the film surface orientation is configured with an offcut of less than about 10 degrees toward a c-direction, a-direction, and/or m-direction a c-plane surface, a nonpolar surface such as an m-plane surface, or a semipolar surface such as a {30-32}, {20-21}, {30-31}, {50-51}, {30-3-2}, {20-2-1}, {30-3-1}, {50-5-1}, {11-22}, or {10-1-1}.

In an example embodiment, a gallium and nitrogen containing epitaxial film is deposited via heteroepitaxial growth on a sapphire substrate. The sapphire substrate is first overlaid with a nitrogen containing nucleation layer. Typically the nucleation layer material is GaN, though it may also be AlN or AlGaN and may also contain a layer provided by converting part of the sapphire wafer surface. For example, the surface of the sapphire wafer could be converted from Al₂O₃ to AlN or AlOₓN_{y} (where x+y=1) by exposing the sapphire substrate to ammonia at high temperatures in the MOCVD reactor. The nucleation layer is grown relatively cold, at a temperature below 700 degrees Celsius. Relatively cold growth is used to produce a high density of individual GaN crystals on the substrate surface. Each crystal of the nucleation layer is partially or fully strain-relaxed, which is accommodated by a network of misfit dislocations that form at the interface between the nucleation layer and the substrate. The substrate is then annealed in the MOCVD reactor at elevated temperature typically above 1000 degrees Celsius. The anneal is intended to refine the grain structure of the nucleation layer by desorbing material such that smaller grains are fully desorbed. After the anneal, a gallium and nitrogen containing “buffer” or “coalescence” layer is grown. The buffer layer is grown under conditions promoting lateral growth of gallium and nitrogen containing crystals preferentially to vertical growth. This results in the coalescence of the individual crystals into a continuous and fully dense film covering the sapphire surface. When individual crystals coalesce into a continuous film the misfit dislocations that relieve strain turn upwards at the boundaries between the individual crystals and form a network of threading dislocations that extend through the thickness of the epitaxial film. Threading dislocation density of the resulting gallium and nitrogen containing film is dependent on three factors: minimizing the number of crystals in the nucleation layer and thereby limiting the amount of interface between coalescing crystals, selecting conditions for nucleation layer growth and anneal that minimize misorientation of the nitrogen containing crystals relative to the heteroepitaxial substrate crystal orientation, and selection of buffer layer growth conditions that cause threading dislocations to bend such that as the epitaxial layers are grown thicker threading dislocations have the opportunity to intersect and either combine or annihilate such that the total threading dislocation density is reduced. By using such techniques, it is possible to achieve threading dislocation densities in the range of 1E7-1E8 cm⁻².

The fully coalesced epitaxial layer is then overlaid with a gallium and nitrogen containing buffer layer where dislocation density is further reduced and surface morphology improved; i.e. made smoother. The buffer layer is overlaid by a sacrificial layer as previously described to be used in the selective removal of the epitaxial device layers from the heteroepitaxial substrate.

In some embodiments, the nucleation and buffer layers are used to chemically passivate the heteroepitaxial substrate. For example, in growth on silicon and SiC it is possible for a gallium-rich environment to result in dissolution of the substrate yielding degradation of the substrate surface morphology as well as subsequent unintentional doping of the heteroepitaxial layers with silicon or carbon. In an example, a nucleation layer of AlN grown under highly nitrogen rich conditions is used as a nucleation layer on Si and SiC substrates to prevent gallium from accessing the substrate surface.

In some cases, the heteroepitaxial gallium and nitrogen containing device layers are highly strained. This can be caused either by growth on a heteroepitaxial substrate with a very large difference in lattice constant relative to GaN or, as is the case silicon when the thermal expansion coefficient of the heteroepitaxial substrate is small relative to GaN and related alloys. In this case, while the heteroepitaxial films may be sufficiently lattice matched to the substrate during growth, after growth is complete and the epitaxial wafer is cooled to room temperature, the gallium and nitrogen containing epitaxial films reduce in lattice constant more than the substrate, which places the films under a large tensile stress. Such large tensile stresses can result in film cracking. In an embodiment, a heteroepitaxial film is grown on silicon such that it is under compressive strain during growth. The compressive strain is chosen such that the film is under a small strain or no strain after cooling to room temperature. In an example, a AlGaN nucleation layer is used or a thick AlGaN buffer layer is grown and partially or fully relaxed and overlaid with a GaN layer. Because the relaxed AlGaN layer has a smaller lattice constant than GaN, the GaN film is grown under compression, such that upon cooldown the net tensile strain imposed by the mismatch in coefficient of thermal expansion with the silicon substrate is partially or fully canceled by the compressive strain of the GaN film.

In another embodiment of this invention the LED device wafer does not contain separate n-InGaN buffer layers and InGaN sacrificial layers. Rather the InGaN buffer layer and the sacrificial layer are the same. In this case either the composition of the InGaN buffer is increased such that it absorbs the pump light for PEC etching, or the wavelength of the PEC etch pump light is shortened to a wavelength absorbed by the n-InGaN buffer.

In an embodiment the LED is fabricated with both a p-contact metal and an n-contact metal before transfer. The carrier wafer has two sets of bond pads that correspond to the on-die p-type bond pad and on-die n-type bond pad respectively. To form the on-die n-type bond pad, a via is etched through the p-type and active region layers exposing the n-type layer. In this depiction, the removed sacrificial layer is shown between the mesa layers and the epitaxial substrate. Metal anchors would be used in this embodiment. The heights of the on-carrier bond-pads are chosen to accommodate the difference in height on wafer of the p-type and n-type on-wafer bond pads and accommodate for any plastic deformation of the bond pad. Bonding alignment tolerances using modern flip-chip bonders is on the order of several microns or less, which is adequate for aligning these types of vias in relatively large area LED mesas. Bonding in this way is advantageous because it allows for immediate on-wafer testing of devices after transfer, exposes the entire n-type GaN surface to allow for roughening to enhance light extraction and does not require any opaque metal features on the n-type GaN surface that might block light. The p-type contact would act as a reflector, and as such must be formed from a material with low absorption of the emitted light. The preferred metal is silver, which has the highest reflectivity in the visible range of light wavelengths. Aluminum could be used but would not form a good electrical contact to p-type GaN by itself. Aluminum would need to be combined with a transparent conductive oxide (TCO) such that the TCO formed a transparent contact to the p-type GaN and the aluminum formed the electrical contact to the TCO as well as the reflective surface. A DBR reflector may also be used. The n-type contact metal can be anything that forms a good electrical contact to n-type GaN, such as Al, Ti, Ni, among others. Ideally the contact would be highly reflective. While the active region is absent in the regions occupied by the n-contacts, laterally guided light may interact with the n-contact metal. Reducing the absorption of this light is therefore highly important for achieving high extraction efficiencies.

In another embodiment the LED is fabricated without an n-contact metal before transfer. The carrier wafer has only one set of bond pads per die corresponding to the on-wafer p-side bond pad. The p-type, active region and n-type layers are only exposed at the edges. Metal anchors would be used in this embodiment. The surface of the n-type layer is exposed. In this embodiment, a transparent or semi-transparent n-type contact would be deposited on the n-type surface in order to make electrical contact to the LED while enabling light to escape from the top of the device. Possible contact materials would be semi-transparent annealed Ni/Au and transparent conducting oxides such as ZnO, indium tin oxide (ITO), gallium oxide, GaZnO, InZnO, AlZnO, AlInGaZnO, among others. The n-contacts may also be formed from high aspect ratio metal features that are limited in area but efficiently and uniformly inject electrons into the n-type material such that the active region is uniformly illuminated. Electrical contact is made to the n-contact material using either inter-connect metal lines deposited with lithography or by wire bonding.

The LED structures are prepared with a lithographically defined etch forming mesas on the epitaxial wafer and exposing the sacrificial layers at the mesa sidewalls. P-type contact metals are deposited on top of the mesas and n-type contact metals are deposited in the trenches between mesas. Metal interconnects are deposited, which connect electrically the p-type and n-type contact metals. These interconnects both electrically short the active region pn-junction, thereby inhibiting PEC etching as described above, and function as non-etchable anchors that retain the mesas on the epitaxial wafer after sacrificial layers are fully removed by the selective PEC etch. The metal stack consists of the p-contact metal and bond pad, the metal anchors and the cathode and n-contact metal. The p-contact and bond pad overlay the LED device mesa, which has a square shape. The mesas may be of the typical dimension of 1×1 mm2 found in many state-of-the-art high-power LEDs, while the trenches between wafers may only be 50 microns or less wide. It is clear that, after singulation of the carrier wafer, a single LED will be bonded to a chip at least four times the area of an individual mesa. The trench area between mesas on the epitaxial wafer will be similar to the kerf loss from sawing or dicing the wafer with a laser, therefore there is little improvement in epitaxial material utilization from transferring the die in this way. There are, however, other advantages. For example, the transfer can be carried out in a highly parallel way, with all die on a wafer transferred in a few (e.g. less than 10) bonding operations depending on the relative decrease of die density from substrate to carrier. This is an improvement over the typical pick-an-place method of transferring die to carrier wafers, which is a serial process. This advantage becomes more significant as the die area is reduced. In an example, one may wish to operate an LED at a fixed current density using a fixed device area. In some applications one may wish the surface brightness of the device to be limited, such that it is advantageous to use a plurality of die with a total area equivalent to the target area but with large spacing between die on the submount such that the average surface brightness is reduced. A similar configuration could be advantageous for the elimination of waste heat in heat-sinks. Many small die widely spaced may be cooled more efficiently than a single die operated at the same power due to the finite thermal conductivity of the LED packaging. It is obvious that in a pick-and-place based die transfer model the number of transfer operations required scales with the number die. This invention is therefore advantageous in that the number of transfer operations scales only with the change in die density from substrate to carrier wafer.

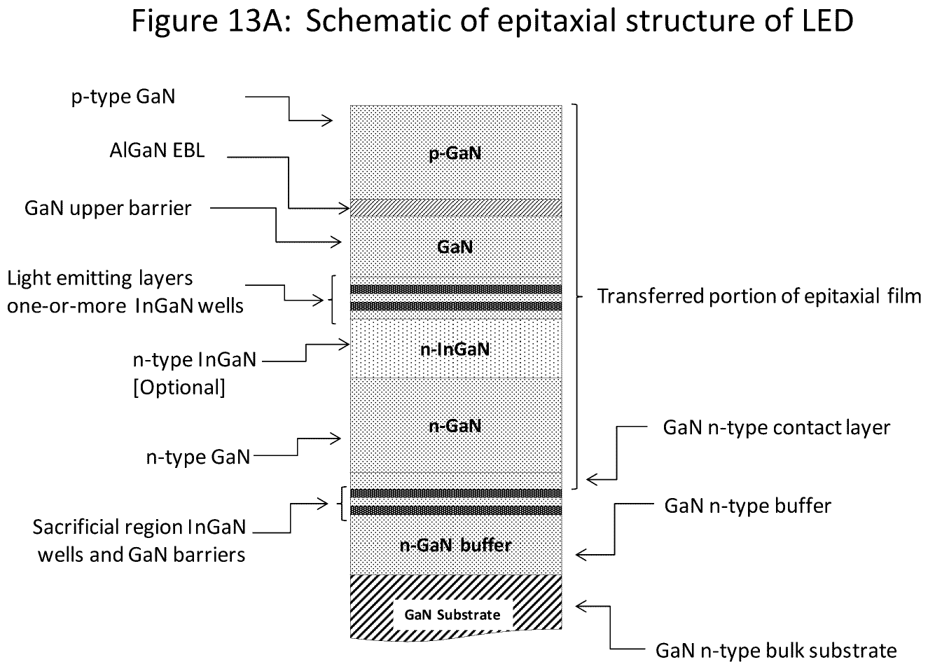

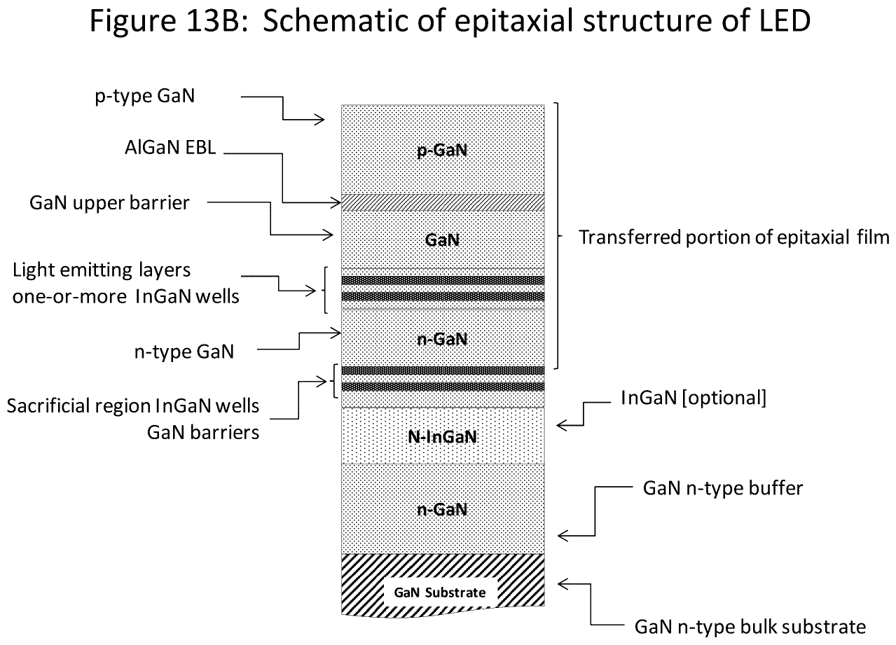

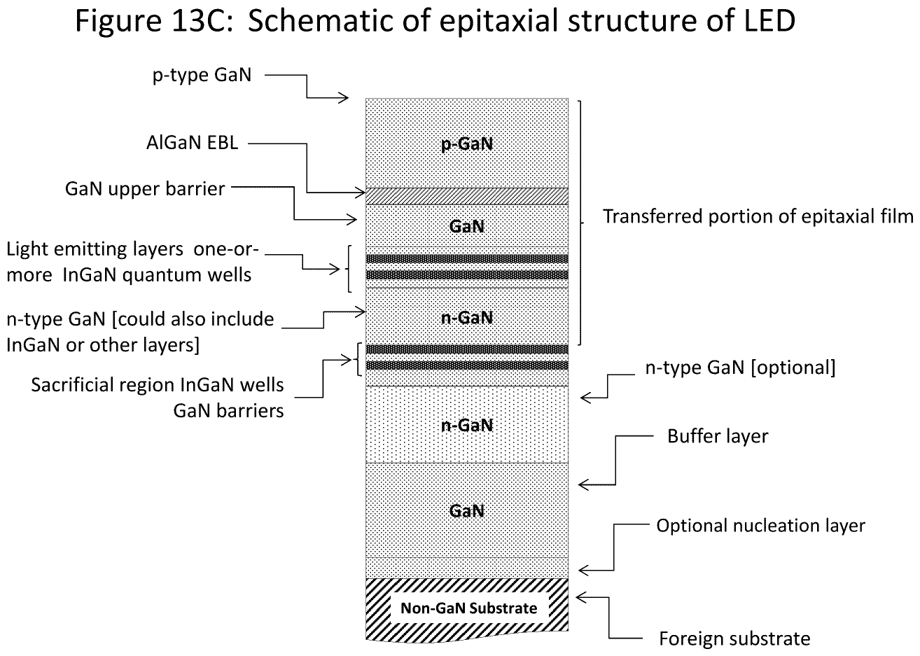

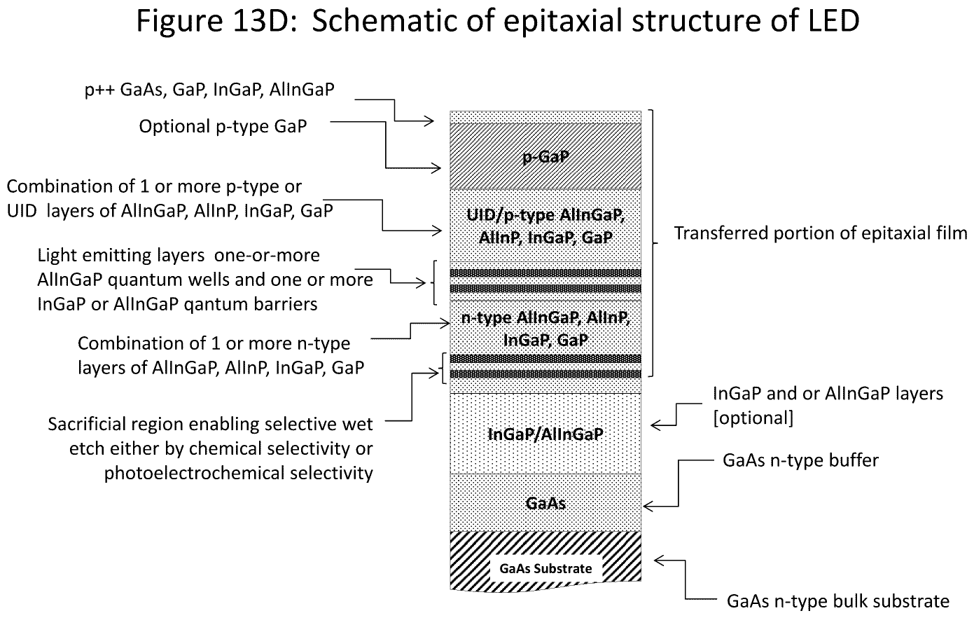

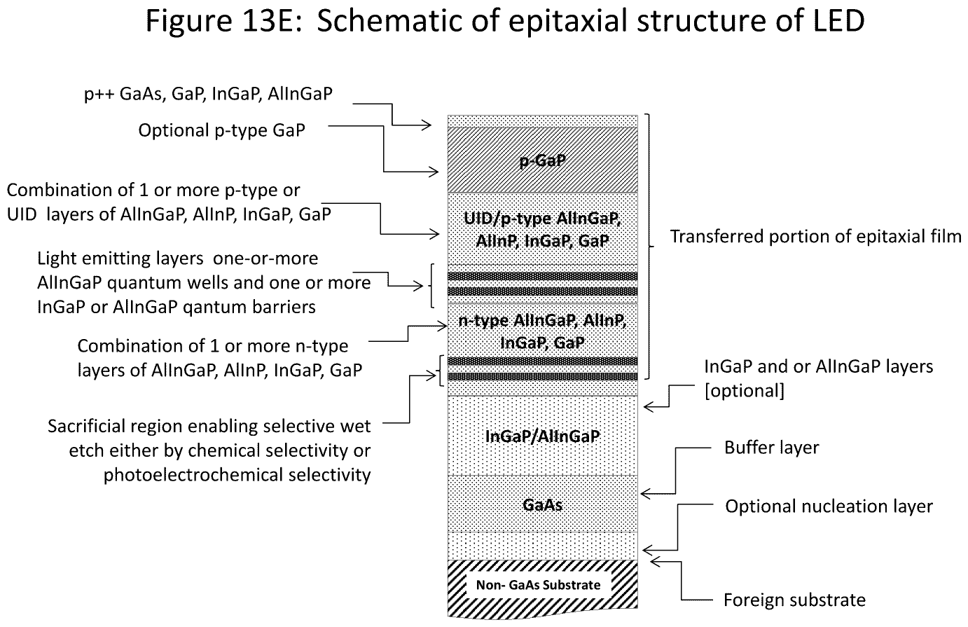

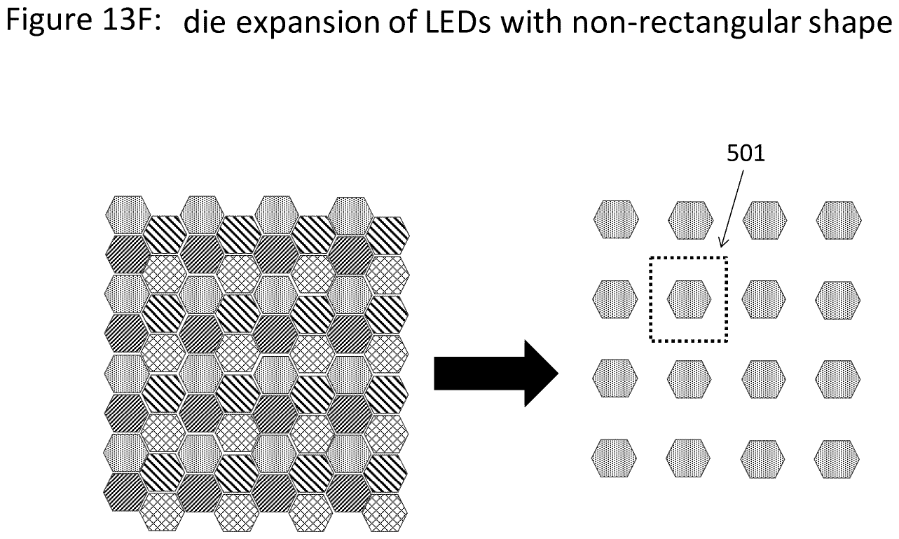

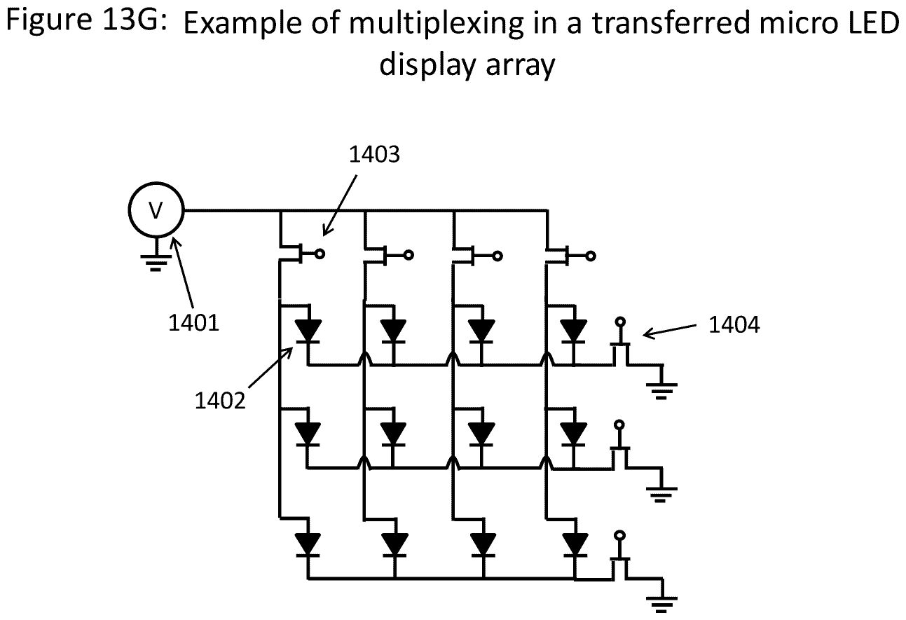

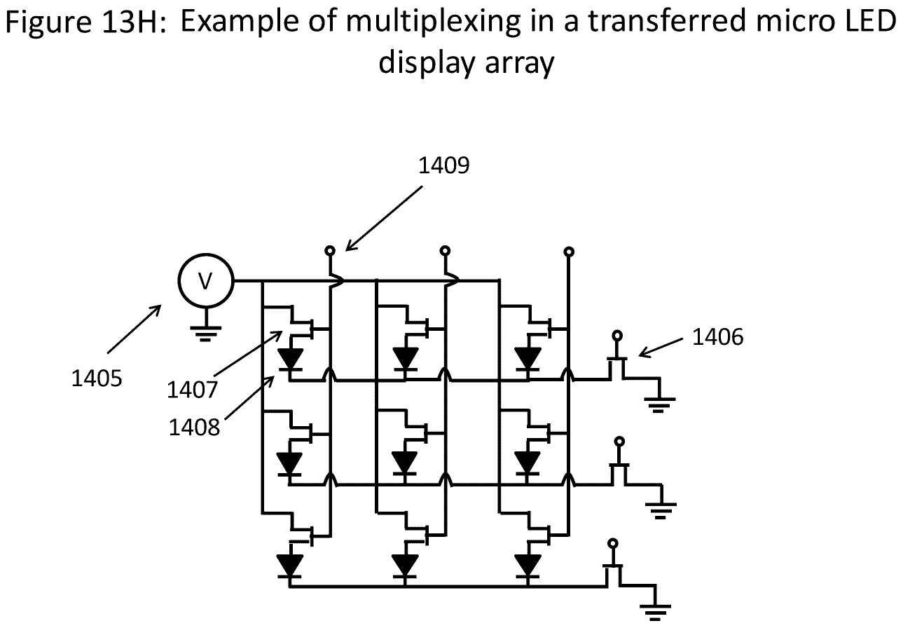

FIG. 13A presents a schematic of an example LED epitaxial structure grown on a bulk GaN substrate. In this example, the gallium and nitrogen containing substrate could be n-type or unintentionally doped. Overlying the substrate may be one or more buffer layers that could be formed from GaN, InGaN, AlGaN, or some combination thereof. Overlying the buffer layer may be a sacrificial region which could contain, for example, one or more InGaN layers separated by barrier layers. The sacrificial region and the entire epi structure allows high selectivity removal in a subsequent step, such as removal by selective chemical etching or photoelectrical chemical etching. Overlying the sacrificial region may be n-type or unintentionally doped layers, or a combination, such as n-type GaN, InGaN, or AlGaN layers, which could also include superlattices. Overlying the n-type or UID layers may be a light emission region configured with InGaN light emission layers such as quantum wells. In some embodiments, the light emission region is comprised of one or more quantum wells with a thickness ranging from about 1 nm to about 10 nm or 20 nm, and with a composition tuned for the proper peak wavelength emission such as blue in the 400 mm to 480 nm range, green in the 500 nm to 560 nm range, or red in the 620 nm to 700 nm range. The quantum well layers may be separated by barrier layers that may be comprised or GaN or InGaN with a thickness of about 1 nm to about 20 nm. In some embodiments, quantum dot layers, quantum wire layers, or other quantum structures may be used for light emission. Overlying the light emission region may be a GaN or InGaN layer that could be UID or p-type, or could be a combination thereof. Overlying these layers may be an electron blocking layer comprised of AlGaN or InAlGaN, and overlying the electron blocking layer may be a p-type layer or combination of p-type layers including p-type GaN, InGaN, and/or AlGaN. Overlying the p-type or p-type layers may be a p++ layer configured with high p-type doping for forming a p-type electrical contact. In some embodiments, growth on porous GaN buffer layers or other types of porous layers may be incorporated in the epi structure to improve the light emission properties of the resulting LED structure.

FIG. 13B presents a schematic of an example LED epitaxial structure grown on bulk GaN. The difference of FIG. 13B from the structure according to FIG. 13A is the inclusion of 1 or more additional layers underlying the sacrificial region. In the example shown in FIG. 13B, an InGaN layer is included below the sacrificial region, but this may be other types of layers or combinations of layers such as superlattices. The inclusion of such layers may improve the crystal quality of the epitaxial stack and/or improve the sacrificial region etch characteristics.

FIG. 13C presents a schematic of an example LED epitaxial structure grown on a foreign, non-bulk GaN substrate. In this example, the substrate could be silicon, sapphire, silicon carbide, germanium, templates such as GaN on sapphire or GaN on silicon templates, or other substrates. In this example structure, there may be an optional nucleation layer overlying the foreign substrate. The nucleation layer may be formed from one or more of a GaN, AlGaN, AlN, InGaN, or other material layer. Overlying the optional nucleation layer may be a buffer region comprised of or more layers made from GaN, AlN, InGaN, AlGaN or other materials. The region may contain superlattices with combinations that may be designed to reduce defects and/or improve surface quality resulting from hetereoepitaxial growth. Techniques with porous GaN may be employed. Overlying the buffer layer may be an optional layer such as a GaN smoothing layer. Overlying the optional layer over the buffer layer would be a sacrificial region. The sacrificial region may be comprised of one or more InGaN layers separated by barrier layers. The sacrificial region and entire epi structure allows high selectivity removal in a subsequent step, such as removal by selective chemical etching or photoelectrical chemical etching. Overlying the sacrificial region may be n-type or unintentionally doped layers, or a combination, such as n-type GaN, InGaN, or AlGaN layers, which could also include superlattices. Overlying the n-type or UID layers may be the light emission region configured with InGaN light emission layers such as quantum wells. In some embodiments, the light emission region may be comprised of one or more multiple wells with a thickness ranging from about 1 nm to about 10 nm or 20 nm, and with a composition tuned for the proper peak wavelength emission such as blue in the 400 mm to 480 nm range, green in the 500 nm to 560 nm range, or red in the 620 nm to 700 nm range. The quantum well layers may be separated by barrier layers that could be comprised from GaN or InGaN with a thickness of about 1 nm to about 20 nm. In some embodiments, quantum dots layers, quantum wire layers, or other quantum structures may be used for light emission. Overlying the light emission region may be a GaN or InGaN layer that could be UID or p-type, or could be a combination thereof. Overlying these layers may be an electron blocking layer comprised of AlGaN or InAlGaN, and overlying the electron blocking layer may be a p-type layer or combination of p-type layers including p-type GaN, InGaN, and/or AlGaN. Overlying the p-type or combination of p-type layers may be a p++ layer configured with high p-type doping for forming a p-type electrical contact. In some embodiments, growth on porous GaN buffer layers or other types of porous layers may be incorporated in the epi structure to improve the light emission properties of the resulting LED structure.

FIG. 13D presents a schematic of an example red LED epitaxial structure grown on a GaAs substrate. The gallium and arsenic containing substrate may be n-type, p-type, or unintentionally doped. In this example according to FIG. 13D, overlying the substrate may be one or more buffer layers that may be formed from GaAs, AlInGaP, AlInP, InGaP, GaP, or some combination thereof. Overlying the buffer layer may be an optional n-type layer or combination thereof selected from InGaP and/or AlInGaP layers, or other layers. Overlying the optional n-type layer may be a sacrificial region which may contain one or more layers separated by barrier layers. The sacrificial region and entire epi structure allows high selectivity removal in a subsequent step, such as removal by selective chemical etching or photoelectrical chemical etching. Overlying the sacrificial region may be n-type or unintentionally doped layers, or a combination, such as one or more n-type layers of AlInGaP, AlInP, InGaP, or GaP layers, which could also include superlattices. In one embodiment, GaP layers may be used to form optical windows to enable light extraction through the n-side of the LED structure. Overlying the n-type or UID layers, may be the light emission region configured with light emitting layers such as one-or-more AlInGaP quantum wells and one or more InGaP or AlInGaP quantum barriers. In some embodiments, the light emission region is comprised of one or more quantum wells with a thickness ranging from about 1 nm to about 10 nm or 20 nm, and with a composition tuned for the proper peak wavelength emission such red in the 620 nm to 700 nm range. In some embodiments, quantum dots layers, quantum wire layers, or other quantum structures may be used for light emission. Overlying the light emission region may be a combination of one or more p-type or UID layers of AlInGaP, AlInP, InGaP, or GaP that could be UID or p-type, or could be a combination thereof. Overlying the p-type or UID layers may be an optional region which may be comprised of p-type GaP, which may form a an optical window region to enable light extraction. Overlying the p-type layer may be a p++ layer configured with high p-type doping such as p++ GaAs, GaP, InGaP, or AlInGaP for forming a p-type electrical contact. In some embodiments, growth on porous buffer layers or other types of porous layers may be incorporated in the epi structure to improve the light emission properties of the resulting LED structure.

FIG. 13E presents a schematic of an example red LED epitaxial structure grown on a foreign, non-GaAs substrate. Such an approach may be applied to the red emitting LED having a wavelength range from about 620 nm to about 700 nm. In this example, the substrate could be silicon, sapphire, silicon carbide, germanium, templates such as GaAs on sapphire or GaAs on silicon templates, or other substrates. In this example structure, there may be an optional nucleation layer overlying the foreign substrate. The nucleation layer may be formed from one or more of AlInGaP, AlInP, InGaP, GaP, AlP, or other materials. Overlying the optional nucleation layer may be a buffer region comprised of AlInGaP, AlInP, InGaP, GaP, AlP, or other materials and superlattices with combinations that reduce defects and/or improve surface quality resulting from hetereoepitaxial growth. Overlying the buffer layer may be an optional UID layer or n-type layer or combination thereof selected from InGaP and/or AlInGaP layers, or other layers. Overlying the optional n-type layer may be a sacrificial region that may contain one or more layers separated by barrier layers. The sacrificial region and entire epi structure allows high selectivity removal in a subsequent step, such as removal by selective chemical etching or photoelectrical chemical etching. Overlying the sacrificial region may be n-type or unintentionally doped layers, or a combination, such as one or more n-type layers of AlInGaP, AlInP, InGaP, GaP layers, which may also include superlattices. In one embodiment, GaP layers may be used to form optical windows to enable light extraction through the n-side of the LED structure. Overlying the n-type or UID layers may be the light emission region configured with light emitting layers such as one-or-more AlInGaP quantum wells and one or more InGaP or AlInGaP quantum barriers. In some preferred embodiments, the light emission region may be comprised of one or more quantum wells with a thickness ranging from about 1 nm to about 10 nm or 20 nm and with a composition tuned for the proper peak wavelength emission such red in the 620 nm to 700 nm range. In some embodiments according to the present invention, quantum dots layers, quantum wire layers, or other quantum structures are used for light emission. Overlying the light emission region may be a combination of one or more p-type or UID layers of AlInGaP, AlInP, InGaP, or GaP that could be UID or p-type, or could be a combination thereof. Overlying the p-type or UID layers may be an optional region that may be comprised of p-type GaP, which may form an optical window region to enable light extraction. Overlying the p-type layer may be a p++ layer configured with high p-type doping such as p++ GaAs, GaP, InGaP, AlInGaP for forming a p-type electrical contact. In some embodiments, growth on porous buffer layers or other types of porous layers may be incorporated in the epi structure to improve the light emission properties of the resulting LED structure.

In another embodiment, the transferred dice have non-rectangular or non-square shapes. FIG. 13F shows an example with hexagonal die. On the left of FIG. 13F is a schematic representation of an array of closely packed hexagonal LED die that are coded to show how all the die may be transferred to carrier wafers in four bonding operations. On the right of FIG. 13F is a schematic representation of a subset of the die transferred to a carrier wafer after a bonding operation. The dotted line 501 indicates the area occupied by a single hexagonal die. In this case the present invention is advantageous in that the die shapes are defined by a lithographic process rather than by a physical sawing or scribing of the epitaxial substrate wafer. Dicing saws blades are relatively large compared to die, such that it would be impossible to singulate a wafer into die of shapes with edges that do not form continuous parallel lines. A laser scribing process may be able to draw guide scribes on the epitaxial substrate, however it is unlikely that the subsequent cleaving process would follow the guide scribes accurately and yield loss would be very high.

Once the carrier wafer is populated with die, wafer level processing can be used to fabricate the die into LED devices. For example, in many embodiments the bonding media and die will have a total thickness of less than about 5 microns, making it possible to use standard photoresist, photoresist dispensing technology and contact and projection lithography tools and techniques to pattern the wafers. The aspect ratios of the features are compatible with deposition of thin films, such as metal and dielectric layers, using evaporators, sputter and CVD deposition tools. In an example wherein the mesa dice are expanded onto a carrier and then fabricated into an array of individual LEDs spaced out on a carrier wafer for enhanced thermal or light extraction performance the packaging would be inherent to the process. Here, then, you would have a truly wafer-scale LED package, fabricated on a wafer level using standard semiconductor manufacturing techniques and equipment, which, once singulated from the carrier wafer, would be ready for encapsulation and combination with phosphor materials.

The present invention enables a highly manufacturable and cost efficient process for producing micro LED based arrays not readily possible with prior art. Specifically, the current invention allows for a wafer level transfer process from a donor LED wafer to a common carrier wafer. Since it is a wafer level process, thousands, tens of thousands, or hundreds of thousands of LEDs can be transferred in one process step (depending on wafer size and pixel pitch) and hence avoiding any one-by-one pick and place techniques or mechanical transfer head techniques. This advantage can enable high throughput for low cost and high alignment tolerances for tight packing of the LEDs. Moreover, since it is a selective transfer process from the donor to the carrier and the pitch of the LEDs from the donor wafer to the carrier wafer can be expanded using the anchor technology, a much higher density of LEDs can be formed on the donor wafers than the final density as expanded on the carrier wafer to form the arrays. This die expansion or transferring at a larger pitch enables an increased use of epitaxial and substrate area of the donor wafer.

With respect to LED devices based on GaAs and/or AlInGaAsP such as red LED devices, these devices include a substrate made of GaAs or Ge, but can be others. As used herein, the term “substrate” can mean the bulk substrate or can include overlying growth structures such as arsenic or phosphorus containing epitaxial region, or functional regions such as n-type GaAs, combinations, and the like. The devices have material overlying the substrate composed of GaAs, AlAs, AlGaAs, InGaAS, InGaP, AlInGaP, AlInGaAs or AlInGaAsP. Typically, each of these regions is formed using at least an epitaxial deposition technique of metal organic chemical vapor deposition (MOCVD), molecular beam epitaxy (MBE), or other epitaxial growth techniques suitable for AlInGaAsP growth. In general, these devices have an n-type and p-type conducting layer which may form part of a n-type cladding layer or p-type cladding layer, respectively, with lower refractive index than the light emitting active region. The n-cladding layers can be composed of an alloy of AlInGaAsP containing aluminum. The devices contain an active region which emits light during operation of the device. The active region may have one or more quantum wells of lower bandgap than surrounding quantum barriers.

Undercut AlInGaAsP based LEDs can be produced in a manner similar to GaN based LEDs described in this invention. There are a number of wet etches that etch some AlInGaAsP alloys selectively. In one embodiment, an AlGaAs or AlGaP sacrificial layer could be grown clad with GaAs etch stop layers. When the composition of AlₓGa₁₋ₓ As and AlₓGa₁₋ₓ P is high (x>0.5) AlGaAs can be etched with almost complete selectivity (i.e. etch rate of AlGaAs>1E6 times that of GaAs) when etched with HF. InGaP and AlInP with high InP and AlP compositions can be etched with HCl selectively relative to GaAs. GaAs can be etched selectively relative to AlGaAs using C₆H₈O₇:H₂O₂:H₂O. There are a number of other combinations of sacrificial layer, etch-stop layer and etch chemistry which are widely known to those knowledgeable in the art of micromachining AlInGaAsP alloys. For example, phosphoric based etches, hydrogen peroxide based etches, hydrochloric acid based etches, and other etches can be employed,

In one embodiment, the AlInGaAsP device layers are exposed to the etch solution which is chosen along with the sacrificial layer composition such that only the sacrificial layers experience significant etching. The active region can be prevented from etching during the compositionally selective etch using an etch resistant protective layer, such as like silicon dioxide, silicon nitride, metals or photoresist among others, on the sidewall. This step is followed by the deposition of a protective insulating layer on the mesa sidewalls, which serves to block etching of the active region during the later sacrificial region undercut etching step. A second top down etch is then performed to expose the sacrificial layers and bonding metal is deposited. With the sacrificial region exposed a compositionally selective etch is used to undercut the mesas. At this point, the selective area bonding process is used to continue fabricating devices. The device layers should be separated from the sacrificial layers by a layer of material that is resistant to etching. This is to prevent etching into the device layers after partially removing the sacrificial layers.

In one embodiment the LED array could include functionality such as photodetectors for monitoring individual LED output, and drive circuitry for the micro LEDs such as thin film transistors or other types of transistors. Transparent p-contacts and substrates (carrier wafers or display panels) may be used for backside emissions. The LEDs would be configured with an interconnection system for electrical addressability based on signals transmitted from a signal processing unit.

In an embodiment, the micro-LED devices are individually addressable via multiplexing. In an example, FIG. 13G shows a circuit diagram for a multiplexing scheme where positive voltage supply lines or anode lines run from a voltage source 1401. Each anode line is provided with a control transistor 1403 which converts a voltage supplied by control circuitry into a current. The cathode of each micro-LED is connected to a cathode or ground line. Each ground line is provided with a control transistor 1404. When a voltage is supplied by control circuitry to the gate of the ground line control transistors the ground line is shorted to ground. When the control transistor is in the off-state, the ground line is isolated from ground by the high resistance of the transistor in the off state. Individual micro-LEDs are addressable by providing appropriate voltages to the gates of the anode and ground line control transistors. In an example, if a sufficiently high voltage is provided to the control transistor 1403 of the first anode line the control transistor will allow current to pass. If sufficiently high voltage is provided to the control transistor 1404 of the first ground line then the transistor will conduct and short the ground line to ground. The micro-LED 1402 connecting the on-state anode control transistor to the ground line corresponding to the on-state ground-line control transistor 1404 will then be provided with current and emit light. All other micro-LED devices will not emit light because either their anode line is open and not conducting or their ground line is open and not conducting. Because the anode and ground lines are individually addressable via their control transistors, it is possible to run all micro-LEDs in each row simultaneously while keeping them individually addressable. An image can be formed by cycling through rows of micro-LEDs at rates too high for humans to perceive, for example cycling through all rows in less than one twentieth of a second or faster would be sufficient. It should be understood that larger, multiplexed micro-LED arrays are possible.

In another example, FIG. 13H shows a circuit diagram for a multiplexing scheme where positive voltage supply lines or anode lines run from a voltage source 1405. The anode of each micro-LED 1408 is tied to an anode line via a control transistor 1407. The gate of each anode line control transistor is tied to a control line 1409. The cathode of each micro-LED is connected to a cathode or ground line. Each ground line is provided with a control transistor 1406. When a voltage is supplied by control circuitry to the gate of the ground line control transistors the ground line is shorted to ground. When the control transistor is in the off-state, the ground line is isolated from ground by the high resistance of the transistor in the off state. Individual micro-LEDs are addressable by providing appropriate voltages to the gates ground line control transistor and to the control lines. In an example, if a sufficiently high voltage is provided to the control transistor 1407 of the first micro-LED by applying a voltage to the first control line 1409 the control transistor will enter an on-state and will conduct electricity. If sufficiently high voltage is provided to the control transistor 1406 of the first ground line then the transistor will conduct and short the ground line to ground. The micro-LED 1408 connecting the on-state anode control transistor to the ground line corresponding to the on-state ground-line control transistor 1406 will then be provided with current and emit light. All other micro-LED devices will not emit light because either their control transistor is in the off state and not conducting or their ground line is open and not conducting. Because the anode control lines and ground lines are individually addressable, it is possible to run all micro-LEDs in each column simultaneously while keeping them individually addressable. An image can be formed by cycling through columns of micro-LEDs at rates too high for humans to perceive, for example cycling through all columns in less than one twentieth of a second or faster would be sufficient. It should be understood that larger, multiplexed micro-LED arrays are possible.

The multiplexing configuration found in FIG. 13G is advantageous over that in FIG. 13H because significantly fewer transistors need to be fabricated on the backplane. In certain embodiments, the control transistors are provided by a separate control circuit that is not fabricated on the backplane. This embodiment greatly reduces the complexity of the backplane as it becomes only a grid of electrically isolated conductor lines and bond pads. The configuration in FIG. 13H is also limited to transistors that can be fabricated on the backplane. For example, if the backplane is glass or other insulating material, the transistors would be limited to those that can be fabricated on such substrates such as thin-film transistors (TFTs), organic or polymer semiconductor transistors and the like. In another example, if the backplane is a silicon wafer, then the transistors could be TFTs, bipolar junction-transistors (BJTs), metal-oxide-semiconductor field effect transistors (MOSFETs) or the like and could be fabricated either with deposition of semiconducting layers such as with TFTs or fabricated in the backplane wafer using diffusion processes as in BJTs or MOSFETs.

The multiplexing configuration found in FIG. 13H is advantageous over that in FIG. 13G in that control transistors in the FIG. 13G configuration would need to be able to source current for all micro-LED devices in a column. Design limitations of the transistor may therefore limit how big a micro-LED matrix is practical. By employing the FIG. 13H design, where each micro-LED is driven by a separate transistor, each transistor can be designed to source a relatively small current. It should be understood that other multiplexing configurations in accordance with an embodiment of this invention are possible. For example, a larger array of micro-LEDs could be segmented into individually addressable sub-arrays driven by one or more control circuits. Micro-LED apparent brightness can be controlled in several ways. In an example, the voltage on the control transistors is variable such that the current passed to the micro-LEDs is dynamically controllable. In another example, the voltage supplied to the control transistors is pulse-width-modulated with varying duty cycle such that the time average current passed to the micro-LED is dynamically controllable. In another example, the voltage supplied to the control transistors is applied for various amounts of time.

Moreover, techniques used in other methods of forming micro LED arrays can be applied such as that found in U.S. application Ser. No. 17/962,379, filed Oct. 7, 2022, the entire contents of which are incorporated herein by reference.

Of course, the LED based arrays according to this invention could be integrated with the other semiconductor device technologies according to this invention such as transistors, diodes, and laser diodes.

The substrate typically is provided with one or more of the following epitaxially grown elements, but is not limiting:
a buffer layer such as an n-type GaN layer
a sacrificial region such as an InGaN quantum well region
an n-GaN or n-AlGaN cladding region with a thickness of about 50 nm to about 6000 nm with a Si or oxygen doping level of about 5E16 cm⁻³ to about 1E19 cm⁻³
an InGaN SCH region with a molar fraction of indium of between about 1% and about 10% and a thickness of about 30 nm to about 300 nm;
quantum well active region layers comprised of one to five about 1.0 to 7.5 nm InGaN quantum wells separated by about 1.5-15.0 nm GaN or InGaN barriers
optionally, a p-side SCH layer comprised of InGaN with a molar fraction of indium of between about 1% and about 10% and a thickness from about 15 nm to about 250 nm
optionally, an electron blocking layer comprised of AlGaN with molar fraction of aluminum of between about 5% and about 20% and thickness from about 10 nm to about 25 nm and doped with Mg.
a p-GaN or p-AlGaN cladding layer with a thickness from about 400 nm to about 1000 nm with Mg doping level of about 5E17 cm⁻³ to about 1E19 cm⁻³
a p++-GaN contact layer with a thickness from about 10 nm to about 40 nm with Mg doping level of about 2E19 cm⁻³ to about 1E21 cm⁻³

As in LED structures, each of these regions are typically formed using at least an epitaxial deposition technique of metal organic chemical vapor deposition (MOCVD), molecular beam epitaxy (MBE), or other epitaxial growth techniques suitable for GaN growth. The active region can include one to about twenty quantum well regions according to one or more embodiments. As an example, following deposition of the n-type AlᵤInᵥGa₁₋ᵤ₋ᵥN layer for a predetermined period of time, so as to achieve a predetermined thickness, an active layer is deposited. The active layer may comprise a single quantum well or a multiple quantum well, with about 2-10 quantum wells. The quantum wells may comprise InGaN wells and GaN barrier layers. In other embodiments, the well layers and barrier layers comprise Al_{w}InₓGa_{1-w-x}N and Al_{y}In_{z}Ga_{1-y-z}N, respectively, where 0≤w, x, y, z, w+x, y+z≤1, where w<u, y and/or x>v, z so that the bandgap of the well layer(s) is less than that of the barrier layer(s) and the n-type layer. The well layers and barrier layers may each have a thickness between about 1 nm and about 15 nm. In another embodiment, the active layer comprises a double heterostructure, with an InGaN or AlwInxGa1-w-xN layer about 10 nm to about 100 nm thick surrounded by GaN or Al_{y}In_{z}Ga_{1-y-z}N layers, where w<u, y and/or x>v, z. The composition and structure of the active layer are chosen to provide light emission at a preselected wavelength. The active layer may be left undoped (or unintentionally doped) or may be doped n-type or p-type.

The active region can also include an electron blocking region, and a separate confinement heterostructure. In some embodiments, an electron blocking layer is preferably deposited. The electron-blocking layer may comprise AlₛInₜGa₁₋ₛ₋ₜN, where 0≤s, t, s+t≤1, with a higher bandgap than the active layer, and may be doped p-type or the electron blocking layer comprises an AlGaN/GaN super-lattice structure, comprising alternating layers of AlGaN and GaN. Alternatively, there may be no electron blocking layer. As noted, the p-type gallium nitride structure, is deposited above the electron blocking layer and active layer(s). The p-type layer may be doped with Mg, to a level between about 10E16 cm−3 and about 10E22 cm−3 and may have a thickness between about 5 nm and about 1000 nm. The outermost 1-50 nm of the p-type layer may be doped more heavily than the rest of the layer, so as to enable an improved electrical contact.

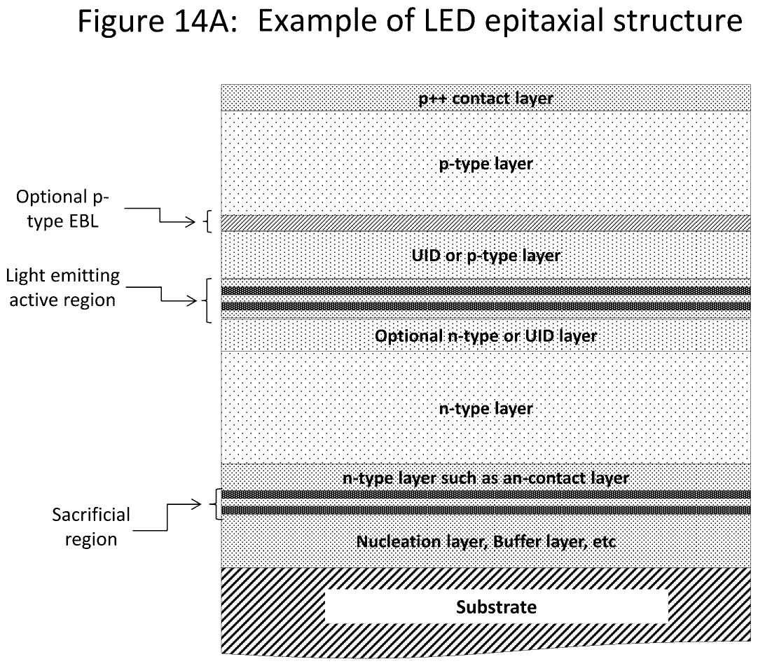

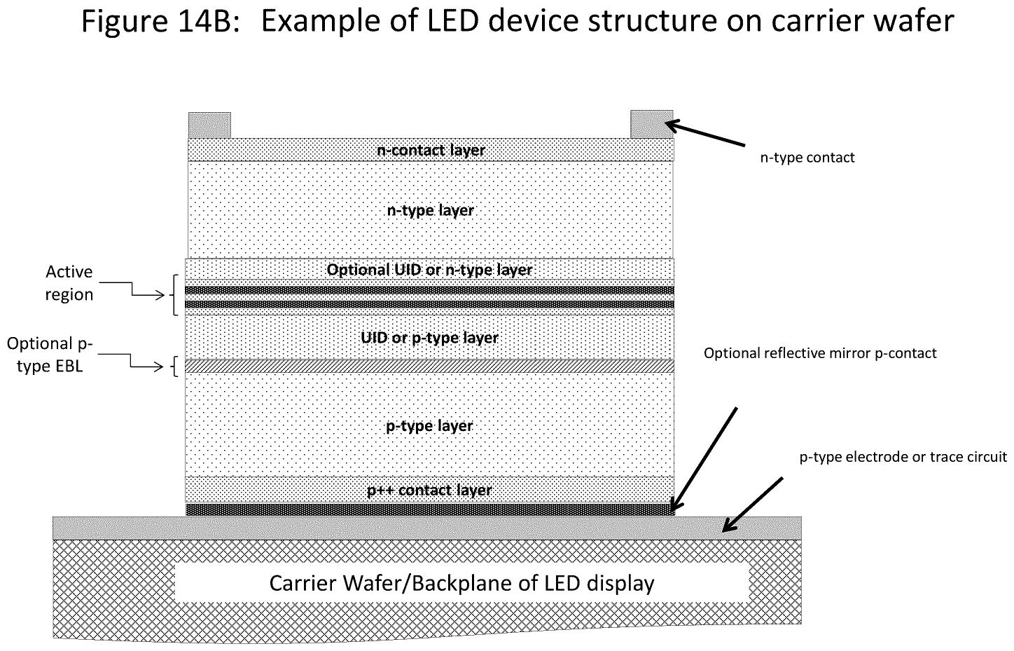

An example of an epitaxial structure for an LED device is shown in FIG. 14A. In this example, a buffer layer followed by a sacrificial region formed along with an n-contact layer that will be exposed after transfer. Overlaying the n-contact layer may be an n-type layer and an optional n-type layer or unintentionally doped (UID) layer, a light emitting active region, a p-type or UID layer, and optional EBL layer, a p-type layer, and a p++ contact region. In one example of this embodiment, an n-type GaN buffer layer is grown on a bulk-GaN wafer. Overlaying the buffer layer is a sacrificial region comprised of InGaN layers separated by GaN layers. Overlaying the sacrificial region is an n-type contact layer consisting of GaN doped with silicon at a concentration of 5E18 cm−3, though in other embodiments the doping may range between 1E18 and 1E19 cm−3. Overlaying the contact layer is an n-type AlGaN layer with a thickness of 1 micron with an average composition of 4% AlN, though in other embodiments the thickness may range from 0.25 to 2 microns with an average composition of 1-8% AlN. Overlaying the n-type layer is an n-type or UID layer. Overlaying the n-type or UID layer are light emitting layers consisting of two 3.5 nm thick In_{0.15}Ga_{0.85}N quantum wells separated by 4 nm thick GaN barriers, though in other embodiments there may be 1 to five light emitting layers consisting of 1 nm to 6 nm thick quantum wells separated by GaN or InGaN barriers of 1 nm to nm thick. Overlaying the light emitting active region is a UID or p-type layer that may be GaN or InGaN. Overlaying the UID or p-type layer is an AlGaN electron blocking layer [EBL] with a composition of 10% AlN, though in other embodiments the AlGaN EBL composition may range from 0% to 30% AlN. Overlaying the EBL a p-type AlGaN layer with a thickness of 0.2 micron with an average composition of 4% AlN, though in other embodiments the thickness may range from 0.25 to 2 microns with an average composition of 1-8% AlN. Overlaying the p-type layer is a highly doped p++ or p-contact layer that enables a high quality electrical p-type contact.

Once the LED epitaxial structure has been transferred to the carrier wafer as described herein, wafer level processing can be used to fabricate the die into LED devices. For example, in many embodiments the bonding media and die will have a total thickness of less than about 7 microns, making it possible to use standard photoresist, photoresist dispensing technology, and contact and projection lithography tools and techniques to pattern the wafers. The aspect ratios of the features are compatible with deposition of thin films, such as metal and dielectric layers, using evaporators, sputter and CVD deposition tools.

An example of an LED epitaxial structure transferred to a carrier wafer or backplane of an LED array is shown in FIG. 14B. In this example, the carrier wafer or backplane may include a p-type electrode or trace circuit on a surface. The p-type electrode or trace circuit may include embedded thin film transistors (TFTs) and pixel drivers. The p-type electrode or trace circuit may be reflective in some embodiments to enhance light extraction. In some embodiments, an optional reflective mirror p-contact may be included for top-side emission. In other embodiments, an optional transparent conductive oxide such as ITO may be included for bottom-side emission. The epitaxial structure may be similar to that of FIG. 14A. An n-type contact such as a top-side ring contact may be formed to enable top-side emission through a top of the epitaxial structure. In some embodiments, the n-type contact may be transparent for top-side emission. In other embodiments, the n-type contact may be a solid n-contact.

In another embodiment of this invention, a p-n diode power electronic device can be fabricated. A p-n diode power device is a two terminal semiconductor diode based upon the p-n junction wherein the diode conducts current in only one direction, and it is made by joining a p-type semiconducting layer to an n-type semiconducting layer. Under a forward bias current flows with a small resistance and in reverse bias little or no current is able to flow until the diode reaches breakdown. Semiconductor p-n diodes have multiple uses including rectification of alternating current to direct current, detection of radio signals, emitting light and detecting light.

An ideal p-n diode should have characteristics such as high breakdown voltage, low leakage current, low forward voltage drop, low on-state resistance, and fast recovery. The key properties to form ideal p-n diodes are the selection of a semiconductor material with optimum intrinsic properties, semiconductor crystal quality with very low defect density, high quality intrinsic layer as drift region with desired thickness, a good ohmic n-contact for low n-type contact resistance for, a good ohmic p-contact for low p-type contact resistance; highly conductive n-type and p-type semiconductor layers sandwiching the intrinsic drift region, proper device structure and design, and good edge termination.

Two typical device geometries for p-n diodes are semi-vertical mesa and vertical. The GaN-based semi-vertical mesa structure typically comprises a mesa structure formed with an etching process into gallium and nitrogen containing material such as GaN. The epitaxial structure can be grown on either native GaN or foreign substrates such as silicon or sapphire. In one example an ohmic metal contact is made to a p-type semiconductor on the top of the mesa and an ohmic metal contact to an n-type semiconductor is made in the region surrounding the mesa. This performance can be limited in the semi-vertical mesa structure by the lateral conductivity of the n-type epi layers connecting n-type ohmic contact to the mesa region where current will flow vertically. With the introduction of native bulk GaN substrates truly vertical p-n diodes were enabled. By forming epitaxial intrinsic drift layers overly a highly doped GaN substrates, forming a p-type gallium and nitrogen containing layer such as p-type GaN overlying the intrinsic layer, and forming ohmic contacts to both the p-type region overlying the intrinsic region and the highly doped n-type substrates high performance truly vertical p-n diodes were realized. In this invention enables a truly vertical p-n diode device without the need for a substrate in the final device by using a highly conductive metal region to laterally conduct to the n-type contact in one configuration or laterally conduct to the p-type contact region in an alternative configuration. Since the metal layers such as gold are highly conductive and can be made several microns thick (1-10 microns or more) the lateral conductivity will be extremely high and even improved over the conductivity in conventional vertical Schottky diodes, which include the resistance of the substrate.

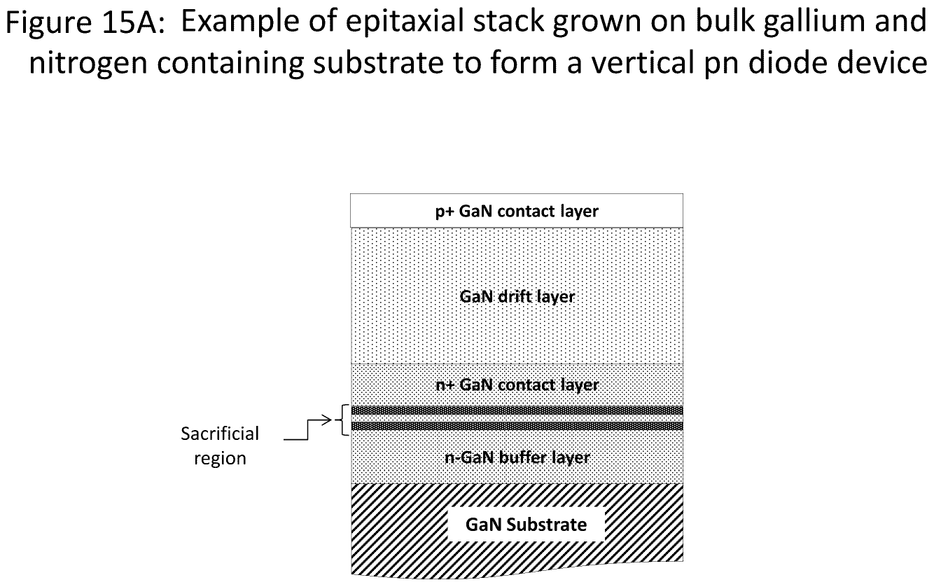

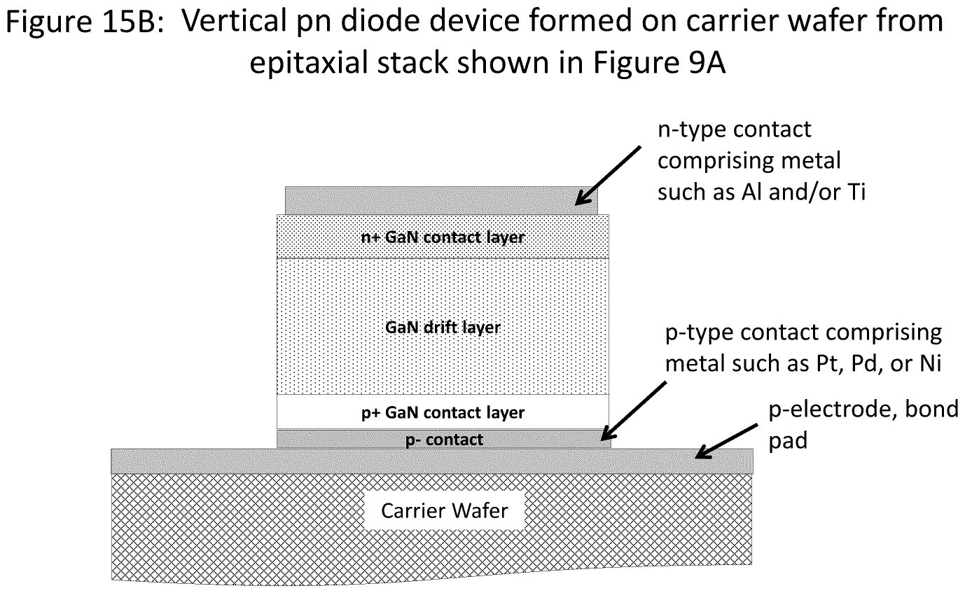

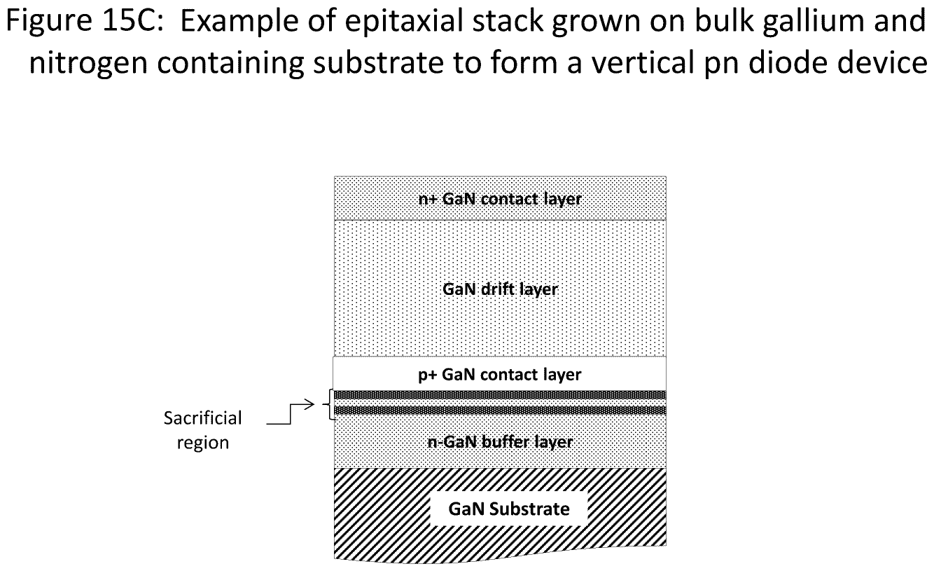

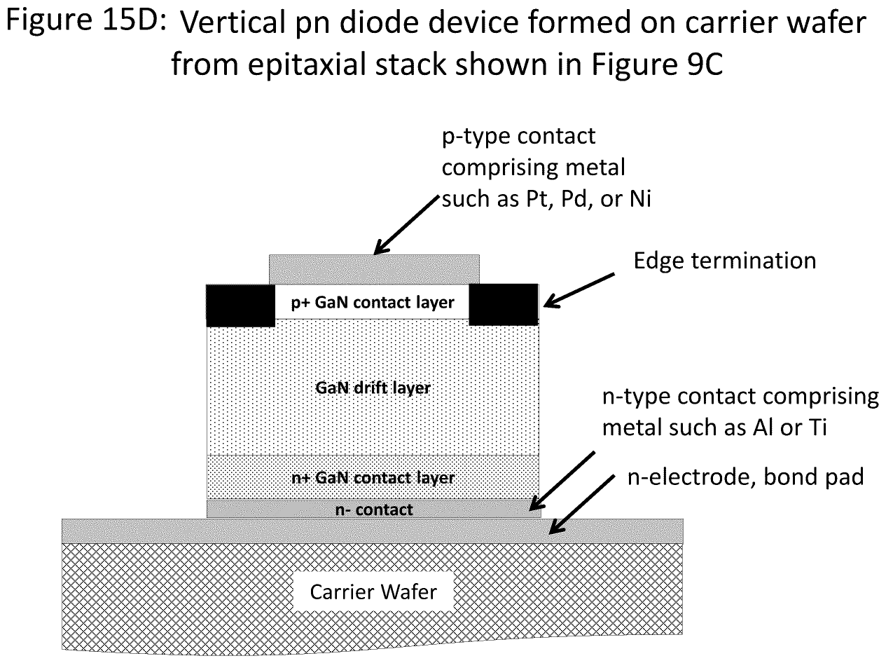

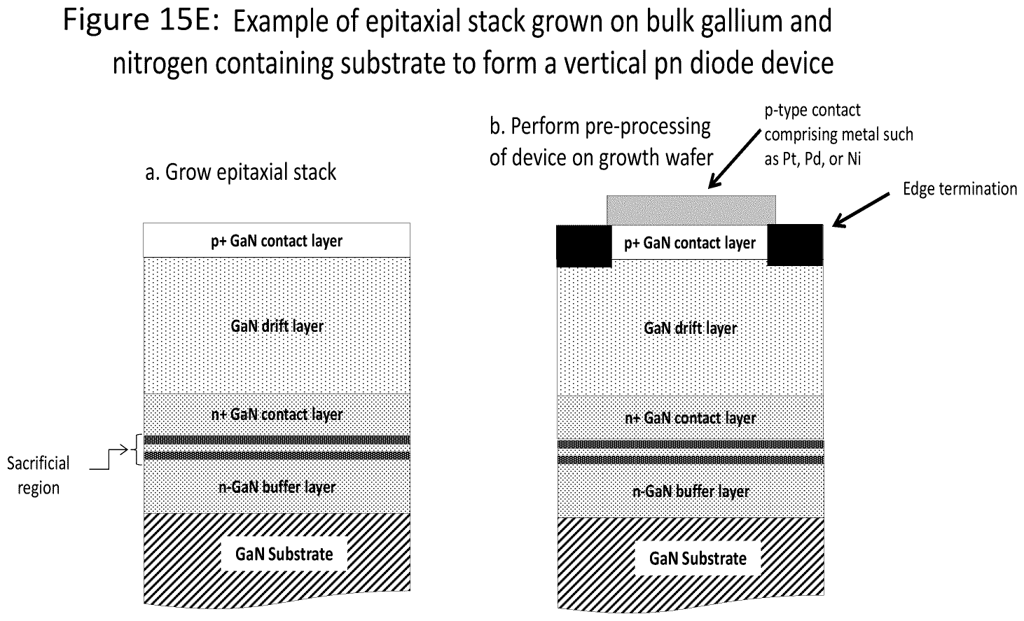

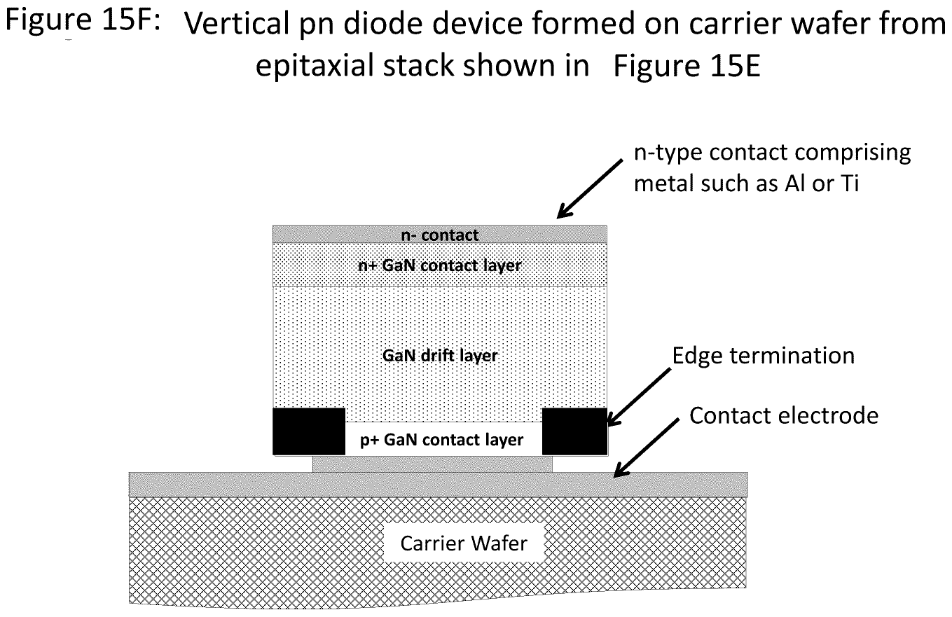

In one embodiment of this invention, a p-n diode epitaxial structure is grown on a bulk gallium and nitrogen containing substrate such as GaN or a foreign substrate. The growth is comprised of an epitaxial technique such as metal organic vapor deposition (MOCVD), molecular beam epitaxy (MBE), hydride vapor phase epitaxy (HYPE), or a combination. As shown in FIG. 15A, the epitaxial structure would comprise a buffer layer grown on top of the GaN substrate. The buffer layer could be comprised of GaN or n-type GaN. Overlying the buffer layer is a sacrificial region as described in this invention. Overlying the sacrificial region are the p-n diode device layers comprising an n-type contact layer such as n-type GaN, a nominally unintentionally doped drift region or intrinsic region comprised of gallium and nitrogen containing material such as GaN overlying the n-type contact region, and an p-type contact layer such as p-type GaN overlying the nominally unintentionally doped drift region or intrinsic region comprised of gallium and nitrogen containing material. In one embodiment the n-contact layer is comprised n-type GaN with a thickness of between 10 nm and 100 nm or 100 nm and 3000 nm. In one embodiment the n-type GaN may be silicon doped GaN with a doping level of greater than 5E17 cm−3 or less than about 1E20 cm−3. In one embodiment the intrinsic region or drift region is comprised of a thickness of 1 um to about 10 um or about 10 um to about 30 um or about 30 um to about 60 um and is comprised of unintentionally doped GaN with a total carrier concentration of less than 1E17 cm−3, less than 5E16 cm−3, less than 2E16 cm−3, or less than 8E15 cm−3. In another embodiment, the intrinsic region is comprised of an intentional dopant intended to compensate the unintentional background dopants to reduce the total carrier concentration and reduce the conductivity. In one embodiment the p-contact layer is comprised p-type GaN with a thickness of between 10 nm and 100 nm or 100 nm and 3000 nm. In one embodiment the p-type GaN may be magnesium doped GaN with a doping level of greater than 5E17 cm−3 or less than about 1E20 cm−3. In one embodiment of this invention the epitaxial layers are formed by MOCVD. In another embodiment the sacrificial region and n-type contact layers are formed by MOCVD and the intrinsic region is formed by HVPE where growth rates are much higher so it is more economical to grow very thick layers.

In one embodiment, a vertical p-n diode device structure is formed from the epitaxial structure in FIG. 15A to result in a device structure as shown in FIG. 15B. In this embodiment, the epitaxial device material is prepared for transfer by forming a mesa region by etching the epitaxial material to a depth at or below the sacrificial region. The etching process can be a dry etching process such as a reactive ion etch (ME), an inductively coupled plasma (ICP) etch, a chemical assisted ion beam etch (CAIBE), or other. Typical gases used in the etching process may include Cl and/or BCl3. Alternatively, the mesa could be defined through a wet etch process. The wet etch process may be selective and designed to terminate on the sacrificial region. In this embodiment, an ohmic contact is formed on top of epitaxial region on the p-type gallium and nitrogen containing material, which can be done either before or after the mesa is defined. The metal for the ohmic contact would be selected, for example, from one of or a combination of platinum, palladium, nickel, nickel-gold, gold, or others. Overlying the p-type contact is a bonding region comprised of a metal, which in some embodiments may be, for example, an p-type contact of the p-n diode device comprised of a metal such as Al, Ti, or the like. The metal may be the same metal as used for the ohmic p-type contact, or in an embodiment, additional layers of metal may be deposited over the p-type contact metal. In one embodiment, this metal would be a gold metal to form a gold-gold bond. Metal depositions can be performed by conventional methods such as electron beam deposition, sputtering, thermal evaporation, or others, and annealing steps may be used to enhance the contact properties. In some embodiments electroplating may be used to deposit a thick layer of a conductive metal such as gold to promote higher conductivity or coverage.

In addition to preparing the epitaxial device layers for the transfer step with the formation of the mesa structures with p-type contacts and comprising bonding regions, the carrier wafer would be prepared for the transfer process. The carrier wafer could be selected from silicon, silicon carbide, sapphire, aluminum nitride, or others. In preparation for the transfer process, bonding regions would be formed on the carrier wafer, which in some embodiments may serve as, for example, a p-electrode or bond pad of the electronic device. In one embodiment the bonding region is a metal bonding region and is comprised of at least gold. Metal deposition can be performed by conventional methods such as electron beam deposition, sputtering, thermal evaporation, or others, and annealing steps may be used to improve the contact quality. In some embodiments electroplating may be used to deposit a thick layer of a conductive metal such as gold to promote high lateral conductivity. The transfer process would comprise a PEC etch to selectively remove the sacrificial release material followed by a bonding step to selectively transfer the epitaxial material to the carrier wafer and release the substrate. In this embodiment the bonding region is configured from a metal layer region comprising metal layers such as gold. The total thickness of this metal bonding region is a critical design aspect since it will be required to laterally conduct all of the device current from bonding pads positioned adjacent to the mesa to the p-type contact. Once bonded, with the substrate released the remainder of the device process would be performed to the epitaxial device material on the carrier wafer. The subsequent processing steps would include forming the n-type ohmic contact with the exposed n-type semiconductor contact layer on the top of the transferred mesa. The n-type contact would comprise a metal to allow for a good ohmic contact such as titanium or aluminum. In many embodiments a metal stack would be deposited with more than one layers wherein the n-type contact layer is in contact with the n-type GaN layer and metals such as gold, nicker, platinum, or palladium are configured in the stack overlying the n-type contact layer. The n-type metal deposition can be performed by conventional methods such as electron beam deposition, sputtering, or thermal evaporation, and annealing steps may be used to improve the contact quality.

Additional processing steps to form the completed p-n diode device could include photolithography, deposition of dielectric passivation regions such as silicon dioxide or silicon nitride. Dry or wet etching or lift off of the dielectric may be necessary to form a patterned region. Additionally, larger bond pad regions may be formed to make the device addressable by electrical power sources. The bond pads would be connected to the p-type contact metal and/or the n-type contact metal and may be configured to be partially or fully formed on the carrier wafer surrounding the epitaxial device material. Additionally, edge termination regions may be formed in the device. Edge termination is one of the key technologies for fabricating high voltage diodes, which functions to reduce the peak electric field along the contact edge and enhance the breakdown voltage. Several methods are used for edge termination including, but not limited to mesa, guard rings, field plates and high resistivity region by ion implantation can be used to reduce the chance of premature breakdown.

In an alternative embodiment of this invention, a p-n diode epitaxial structure is grown on a bulk gallium and nitrogen containing substrate such as GaN or a foreign substrate. The growth is comprised of an epitaxial technique such as metal organic vapor deposition (MOCVD), molecular beam epitaxy (MBE), hydride vapor phase epitaxy (HVPE), or a combination. The epitaxial structure according to this embodiment, as shown in FIG. 15C, comprises a buffer layer grown on top of the GaN substrate. The buffer layer could be comprised of GaN or n-type GaN. Overlying the buffer layer is a sacrificial region as described in this invention. Overlying the sacrificial region are the p-n diode device layers comprising an p-type contact layer such as p-type GaN, a nominally unintentionally doped drift region or intrinsic region comprised of gallium and nitrogen containing material such as GaN overlying the p-type contact region, and an n-type contact layer such as n-type GaN overlying the nominally unintentionally doped drift region or intrinsic region comprised of gallium and nitrogen containing material. In one embodiment the p-contact layer is comprised p-type GaN with a thickness of between 10 nm and 100 nm or 100 nm and 3000 nm. In one embodiment the p-type GaN may be magnesium doped GaN with a doping level of greater than 5E17 cm−3 or less than about 1E20 cm−3. In one embodiment the intrinsic region or drift region is comprised of a thickness of 1 um to about 10 um or about 10 um to about 30 um or about 30 um to about 60 um and is comprised of unintentionally doped GaN with a total carrier concentration of less than 1E17 cm−3, less than 5E16 cm−3, less than 2E16 cm−3, or less than 8E15 cm−3. In another embodiment, the intrinsic region is comprised of an intentional dopant intended to compensate the unintentional background dopants to reduce the total carrier concentration and reduce the conductivity. In one embodiment the n-contact layer is comprised n-type GaN with a thickness of between 10 nm and 100 nm or 100 nm and 3000 nm. In one embodiment the n-type GaN may be silicon doped GaN with a doping level of greater than 5E17 cm−3 or less than about 1E20 cm−3. In one embodiment of this invention the epitaxial layers are formed by MOCVD. In another embodiment the sacrificial region and n-type contact layers are formed by MOCVD and the intrinsic region is formed by HVPE where growth rates are much higher so it is more economical to grow very thick layers.

In this embodiment, a vertical p-n diode device structure is formed from the epitaxial structure in FIG. 15C to result in a device structure as shown in FIG. 15D. In this embodiment, the epitaxial device material is prepared for transfer by forming a mesa region by etching the epitaxial material to a depth at or below the sacrificial region. The etching process can be a dry etching process such as a reactive ion etch (ME), an inductively coupled plasma (ICP) etch, a chemical assisted ion beam etch (CAIBE), or other. Typical gases used in the etching process may include Cl and/or BCl3. Alternatively, the mesa could be defined through a wet etch process. The wet etch process may be selective and designed to terminate on the sacrificial region. In this embodiment, an ohmic contact is formed on top of epitaxial region on the n-type gallium and nitrogen containing material, which can be done either before or after the mesa is defined. The metal for the ohmic contact would be selected, for example, from one of or a combination of aluminum, titanium, platinum, palladium, nickel, nickel-gold, gold, or others. Overlying the n-type contact is a bonding region comprised of a metal, which in some embodiments may be, for example, an n-type contact of the p-n diode device comprised of a metal such as Al, Ti, or the like. The metal may be the same metal as used for the ohmic n-type contact, or in an embodiment, additional layers of metal may be deposited over the n-type contact metal. In one embodiment, this metal would be a gold metal to form a gold-gold bond. Metal depositions can be performed by conventional methods such as electron beam deposition, sputtering, thermal evaporation, or others, and annealing steps may be performed. In some embodiments electroplating may be used to deposit a thick layer of a conductive metal such as gold to promote higher conductivity or coverage.

In addition to preparing the epitaxial device layers for the transfer step with the formation of the mesa structures with n-type contacts and comprising bonding regions, the carrier wafer would be prepared for the transfer process. The carrier wafer could be selected from silicon, silicon carbide, sapphire, aluminum nitride, or others. In preparation for the transfer process, bonding regions would be formed on the carrier wafer, which in some embodiments may serve as, for example, an n-electrode or bond pad of the electronic device. In one embodiment the bonding region is a metal bonding region and is comprised of at least gold. Metal deposition can be performed by conventional methods such as electron beam deposition, sputtering, thermal evaporation, or others, and annealing steps may be used to improve the contact quality. In some embodiments electroplating may be used to deposit a thick layer of a conductive metal such as gold to promote high lateral conductivity. The transfer process would comprise a PEC etch to selectively remove the sacrificial release material followed by a bonding step to selectively transfer the epitaxial material to the carrier wafer and release the substrate. In this embodiment the bonding region is configured from a metal layer region comprising metal layers such as gold. The total thickness of this metal bonding region is a critical design aspect since it will be required to laterally conduct all of the device current from bonding pads positioned adjacent to the mesa to the n-type contact. Once bonded, with the substrate released the remainder of the device process would be performed to the epitaxial device material on the carrier wafer. The subsequent processing steps would include forming the p-type ohmic contact with the exposed p-type semiconductor contact layer on the top of the transferred mesa. The p-type ohmic contact would comprise a metal to allow for a good ohmic contact such as platinum, palladium, nickel, nickel-gold, or a combination thereof. In many embodiments a metal stack would be deposited with more than one layer wherein the ohmic contact layer is in contact with the n-type GaN layer and metals such as gold, nickel, platinum, or palladium are configured in the stack overlying the contact layer. The p-type contact metal deposition can be performed by conventional methods such as electron beam deposition, sputtering, or thermal evaporation, and annealing steps may be used to improve the contact quality.

Additional processing steps to form the completed p-n diode device could include photolithography, deposition of dielectric passivation regions such as silicon dioxide or silicon nitride. Dry or wet etching or lift off of the dielectric may be necessary to form a patterned region. Additionally, larger bond pad regions may be formed to make the device addressable by electrical power sources. The bond pads would be connected to the p-type contact metal and/or the n-type contact metal and may be configured to be partially or fully formed on the carrier wafer surrounding the epitaxial device material. Additionally, edge termination regions may be formed in the device. Edge termination is one of the key technologies for fabricating high voltage diodes, which functions to reduce the peak electric field along the contact edge and enhance the breakdown voltage. Several methods are used for edge termination including, but not limited to mesa, guard rings, field plates and high resistivity region by ion implantation can be used to reduce the chance of premature breakdown.

FIGS. 15E and 15F illustrate a method by which the p-n diode device is formed and partially processed while attached to the gallium and nitrogen containing or foreign wafer, and by which the device is transferred to the carrier wafer.

FIG. 15E is a simplified schematic cross-section of a structure of a device according to an example of the present invention. As illustrated, in FIG. 15E(a), the device is partially formed on the substrate, and as illustrated in FIG. 15E(b), the device is further processed to form edge termination and a p-type contact, for example comprising a metal, such as platinum, nickel and/or palladium. The edge termination and p-type contact are formed using techniques discussed herein and/or otherwise known to those of skill in the art.

FIG. 15F is a simplified schematic cross-section of the device of FIG. 15E after transfer to a carrier wafer according to an example of the present invention. The device is attached to a contact electrode, which has been previously formed on the carrier wafer. The device may be additionally processed after being attached to the carrier wafer. In this example, after the device is attached to the carrier wafer, an n-type contact is formed on the exposed n+ GaN contact layer. The n-type contact may be formed using a metal such as aluminum and/or titanium using processes known to those of skill in the art and/or discussed herein. The n-type contact may then be electrically connected with other contacts formed on the carrier wafer or formed on devices on the carrier wafer, for example using wire interconnects, wire bonding, or other methods.

In an example of die expansion for the micro LED and/or PD devices, the die are transferred to a carrier wafer at a second pitch where the second pitch is greater than the first pitch. This invention enables fabrication of die at very high density on a substrate. This high density being greater than what is practical for a device built using current fabrication processes. Micro LED and/or PD die are transferred to a carrier wafer at a larger pitch (e.g. lower density) than they are found on the substrate. The carrier wafer can be made from a less expensive material, or one with material properties that enable using the carrier as a submount or the carrier wafer can be an engineered wafer including passivation layers and electrical elements fabricated with standard lithographic processes. Once transferred, the die can be processed using standard IC processes. The carrier wafer diameter can be chosen such that die from multiple gallium and nitrogen containing substrates can be transferred to a single carrier and processed in parallel using standard IC processes.

When manufacturing arrays based on micro LEDs and/or PDs, the device count in the arrays can reach thousands, millions, or even tens of millions, so it is helpful to have a manufacturing, testing, and screening strategy that does not lead to excessive numbers of dead or malfunctioning devices that degrade quality, make the yields unacceptable, and manufacturing costs too high. There are several approaches that can be deployed to manage this according to the embodiments described herein. In some embodiments, each LED may have more than one micro LED die and/or each PD may have more than one PD to ensure redundancy in case of a die failure.

In cases where die redundancy is not desired or feasible, an alternative approach may be to test and screen each of the micro LED and/or PD die before they are transferred from the donor wafers to the carrier wafer. In this embodiment, the testing or screening could be based on a visual inspection such as an automated optical inspection technique to identify defects or features indicative of a defective die. In some embodiments, artificial intelligence or machine learning may be deployed in these visual or optical inspection techniques to enhance the effectiveness and efficiency of the inspection and screening. The inspection method and process can be performed with other techniques in addition to or instead of optical or visual inspection. For example, inspection can be performed with different wavelength light sources including ultraviolet, visual, and infrared light sources and combinations thereof. In some embodiments, inspection methods using x-ray or ultrasonic techniques can be used, photoluminescence techniques can be deployed, including others. These techniques are example inspection approaches, but of course there could be others that could be used with the embodiments described herein.

In an embodiment, defective die are identified by an inspection process, and in some examples, the location of the die or the spatial position or coordinates of the die may be logged and stored in memory. In a subsequent step, the defective die may be removed from the donor wafers prior to the bonding and transfer process that transfers the die from the donor wafers to the carrier wafer.

In an embodiment, the defective die may be removed after the sacrificial region has been partially or fully removed. In this embodiment, the die could be detached from the donor wafer and “picked up” since the mechanical attachment of the die to the donor wafer is weak and designed for removal during the transfer process. The inspection step could be performed either before or after the sacrificial region is partially or fully removed depending on the embodiment. In some embodiments, the inspection is done after the sacrificial region has been fully or partially removed so that the inspection step can detect any defects that occur during removal of the sacrificial region. Once the defective die are identified, the die “pick up” process could be performed in a number of ways. In one example, the die are picked up with a precise mechanical clamping tool that mechanically clamps to secure the defective die and then lifts it up. In another example, the pick-up tool uses an adhesive type of attachment on a mechanical finger to secure the die and then lift it off the donor wafer. In yet another example, a precise vacuum tool is used to secure the die and then lift it off the donor wafer. Mechanical tooling and fixtures with precise spatial control coupled with image and pattern recognition capabilities could be used to locate the defective die based on inspection data and then precisely pick the die up off the donor wafer. These pick-up techniques are merely example pick-up or removal approaches, but of course there could be others that may be used with the embodiments described herein.

In another embodiment, the defective die screening approach includes electrical or optoelectrical testing of the micro LED and/or PD die in place of or in addition to the optical or visual inspection step. Such testing could be performed with a direct probing technique or with a contactless technique such as mercury probing. Various electrical tests and characteristics could be used to identify defective die including current versus voltage (IV) curves, turn-on voltage, series resistance, leakage current, reverse bias leakage, and many other characteristics that may be indicative of defective die. Various optoelectrical tests could be used to identify defective die including electroluminescence, spectral characterization such as peak wavelength, spectral intensity, and spectral width, light output versus current injected (LI) curves, polarization, and many other characteristics that may be used to identify defective die. These electrical and optoelectrical screening techniques are merely example techniques, but of course there could be others that may be used with the embodiments described herein.

In the processes described above where the die are screened on the donor wafers and then the defective die are removed prior to being transferred to the carrier wafer, a void or unpopulated area will exist on the carrier wafer or in the array where the die was removed from the donor wafer. This could lead to “dark” pixels in the array with no light output. According to some embodiments described herein, there are many methods to address these dark or incomplete pixels using die replacement or pixel repair techniques.

In an embodiment of die replacement or pixel repair, the missing die on primary donor wafers may be replaced. In this donor level die replacement or pixel repair method, a spare die bank may be created and made available as spare die or replacement die. In an example, extra or “spare” donor wafers having die may be processed and subjected to the same screening processes used for the primary donor wafers. With the defective die removed from the spare donor wafers, only good die remain. In a subsequent step, a pick and place method or an alternative method may be used to move the good die from the spare donor wafers to empty locations on the primary donor wafers. To ensure that the die sufficiently stick or fasten to the primary donor wafer, various methods for attachment can be used including an isolated bond technique such as thermo-compression, interdiffusion, or using an adhesive to act as a glue material between the replacement die and the primary donor wafer. The attachment method may be designed to create a strong bond to remain on the donor wafer throughout the subsequent processing and handling steps, but then detach appropriately during the transfer process from the donor wafer to the carrier wafer. In methods that use an adhesive, a cleaning process may be used after transfer to remove the adhesive and any residual materials.

As described earlier, any tool or tools used to pick up defective die from a donor wafer and/or repair or replace the defective die would need to be a precision tool with location recognition and alignment tolerances acceptable for removing the defective die and/or placing a replacement die into the empty position. The pick-up of the replacement die from the spare donor wafer, tape, or other, could happen in a number of ways and is not limited to those described herein. In one example, the die are picked up from the spare donor wafer or tape with a precise mechanical clamping tool that mechanically clamps to secure the replacement die and then lifts it up. In another example, the pick-up tool uses an adhesive type of attachment on a mechanical finger to secure the replacement die and then lift it off the donor wafer. In yet another example, a precise vacuum tool is used to secure the replacement die and then lift it off the spare donor. Mechanical tooling and fixtures with precise spatial control coupled with image and pattern recognition capabilities could be used to locate the replacement die based on inspection data and then precisely pick the die up off the spare donor wafer. These pick-up techniques are merely example pick-up or removal approaches, but of course there could be others that may be used with the embodiments described herein.

In another embodiment of die replacement or pixel repair, the missing die on the carrier wafer could be replaced. In this carrier level die replacement or pixel repair method, again a spare die bank may be created and would be available as spare die or replacement die. In an example, extra or “spare” donor wafers having micro-LED and/or PD die may be processed and subjected to the same screening processes used for the primary donor wafers. With the defective die removed from the spare donor wafers, only good die remain. In a subsequent step, a pick and place method or an alternative method may be used to move the good die from the spare donor wafers to empty locations on the carrier wafers. In this approach, the replacement die is provided with a bond interface to the carrier wafer that has similar properties to the bond interfaces between the die that were transferred to the carrier wafer from the primary donor wafer. In one example, an interdiffusion bond such as a metallic bond is used both for the primary die bonds and the replacement die bonds. In another embodiment, a solder may be used and a die bonding approach may be used for the die replacement step. For example, if interdiffusion bonding is impractical, an approach such as eutectic bonding or solder bonding may be more practical. A heated pick up tool can be used to remove the die from the spare donor wafer and solder bond it to the carrier wafer. Specialized tooling may be used for this isolated bonding of the die to the carrier wafer.

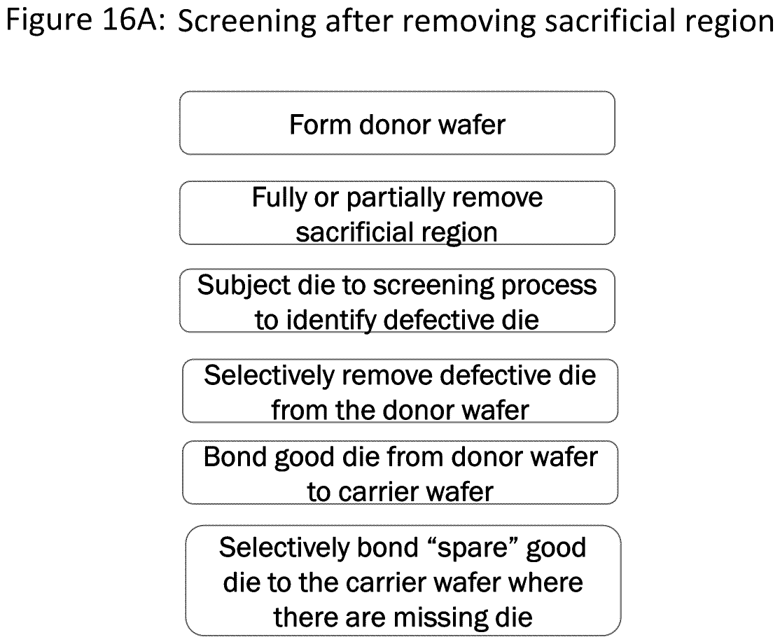

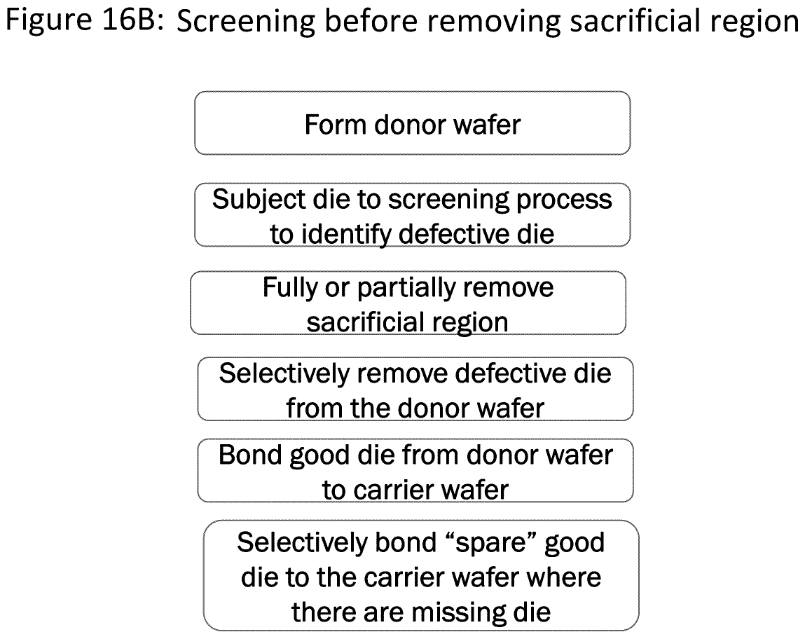

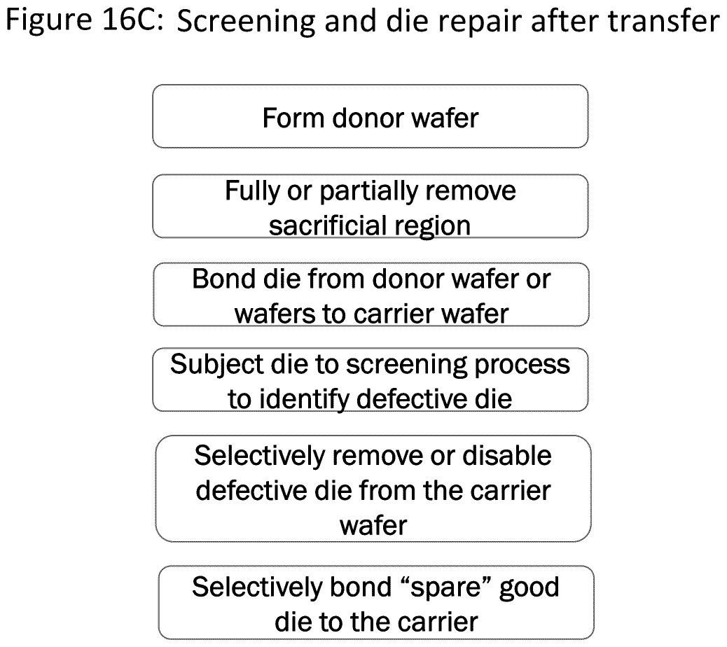

As described herein, there are many sequences and testing methods that can be used for die screening and die repair in accordance with various embodiments. FIGS. 16A-16C are flowcharts of exemplary methods that include screening die during a transfer process in accordance with some embodiments. FIG. 16A provides a method where the screening may be performed after fully or partially removing a sacrificial region. In the FIG. 16A sequence, a donor wafer is formed in a first step. Forming the donor wafer may include forming a sacrificial region (or release material) and an epitaxial material over a surface region of a substrate. The epitaxial material is patterned to form a plurality of dice arranged in an array. Another step includes either fully or partially removing the sacrificial region. This may include subjecting the sacrificial region to an energy source to fully or partially remove the sacrificial region. Another step includes subjecting the die to a screening process to identify defective die. The screening process may include at least one of a visual inspection, an optical inspection, an electrical test, or an optoelectrical test. Another step includes selectively removing the defective die from the donor wafer. This may involve using a pick up technique as described previously. Another step includes bonding at least some of the good die to a carrier wafer. This may include bonding interface regions overlying the plurality of dice with bonding regions on the carrier wafer. Optionally, another step may include selectively bonding “spare” die to the carrier wafer where there are missing die. This may involve using pick and place technique as described previously. Alternatively, rather than selectively bonding spare die to the carrier wafer, the spare die may be selectively bonded to the donor wafer before the good die are bonded to the carrier wafer. The spare die may then be transferred, along with the good die, to the carrier wafer. FIG. 16B provides a method where the screening may be performed before fully or partially removing the sacrificial region. The steps in the method of FIG. 16B are otherwise similar to those of FIG. 16A.

FIG. 16C provides a method where the screening may be performed after transferring the epitaxy material to a carrier wafer. In this embodiment, the screening process may include at least one of a visual inspection, an optical inspection, an electrical test, or an optoelectrical test. The screening process may be performed either immediately after transfer or after additional processing steps are completed. After the screening process, defective die are removed from the carrier wafer, which may involve using a pick up technique as described previously. Alternatively, the defective die could be disabled rather than removed. After removing or disabling the defective die, a “spare” die would be bonded in place of the defective die. Alternatively, the “spare” die could be bonded to a prepared extra bond pad on the carrier. This may involve using pick and place technique as described previously. The screening, die removal, and die replacement can be done after transferring one, several, or all of the intended die to the carrier.

Some embodiments involve massively parallel die transfer processes where donor wafers with a sacrificial region and specified epitaxial stacks that will subsequently form the devices, such as micro LED and/or PD dies, are prepared for transfer to a carrier wafer by performing pre-processing steps such as etching mesas and forming anchor supports to hold the dies in place when the sacrificial region is removed.

Once donor wafers are prepared by growing the epitaxial structures for the micro LEDs to emit at the desired wavelengths and/or the PDs, and sacrificial regions, mesas, and anchor structures are formed, the donor wafers are prepared for die transfer to a carrier wafer. An energy source may be applied to the sacrificial layer (or release material) to fully or partially removed it, reducing the strength at which the die are secured to the donor wafer. In one example, the energy source is a chemical source with a massively selective wet etch to preferentially etch the sacrificial region. The die are held in place by a small unetched portion of the sacrificial region or by small anchors that may be formed by metal or other materials.

In another step, the donor wafers are aligned to a properly prepared carrier wafer with bonding pads that are designed to mate to the die on the donor wafer to which they are intended to bond. The bond pads can be formed with metal such as gold or with other materials such as oxides, dielectrics, ceramics, organic materials, transparent conductive oxides, or other materials. The carrier wafer can be comprised of any type of appropriate carrier wafer material including ceramic, silicon, silicon on insulator, silicon carbide, quartz, purity fused silica, glass, sapphire, diamond, copper, aluminum nitride, aluminum oxynitride, gallium arsenide, gallium nitride, gallium nitride on silicon, indium phosphide, a flexible member, a circuit board, or other types of materials or substrates. The massively parallel die transfer process according to some embodiments may undergo a wafer-to-wafer bonding process with careful alignment to properly align the intended die from the donor wafer to bond onto the intended bond pad on the carrier wafer, within an alignment tolerance according to predetermined design rules. The bond between the die and the pads on the carrier wafer can be formed in many ways. In one approach, an Au—Au interdiffusion bond is used where heat and pressure are applied for an incremental time period such as 15 seconds, 30 seconds, 60 seconds, or more. The bond could also be formed with oxides or dielectrics or could be formed with solders such as eutectic solders, bump bonds, indium bumps, or other types of bonds. Once the bond is formed between the die and the carrier wafer with sufficient strength, the donor wafer and carrier wafer are separated, breaking the anchor features and leaving the epi stack ready for additional device processing.

One challenge with the direct bonding process from the donor wafer to the carrier wafer is the bonding alignment of the die. As the die become smaller in size within the micro LED and/or PD arrays, the alignment becomes more important. For example, in micro LEDs that are less than 25 um in diameter, less than 15 um in diameter, less than 10 um in diameter, or even less than 5 um in diameter, controlling the alignment of the die placement down to +/−5 um, +/−3 um, or even +/−1 um may be required. Bonding processes are typically heated so the coefficient of thermal expansion of the donor wafer and the carrier wafer may play a role in proper alignment. In some embodiments the die spacings on the donor wafer and/or on the carrier wafer are specifically designed with comprehension of the coefficient of thermal expansion, the process temperature, and other factors that may affect the alignment. The die spacing on the donor wafer and/or the bond pad spacing on the carrier wafer has a special design consideration, and could even be chirped, with a varying or non-uniform pitch of the die on the donor wafer and/or on the bond pads of the carrier wafer. Very precise, repeatable, and uniform temperature control of the donor wafer and the carrier wafer may be required during the bonding process. This may be accomplished with heater systems and designs, and/or with heating and cooling sequences. There are many other designs and process improvements that may be implemented with these embodiments to ensure sufficient alignment of the donor die on the carrier wafer during the bonding process.

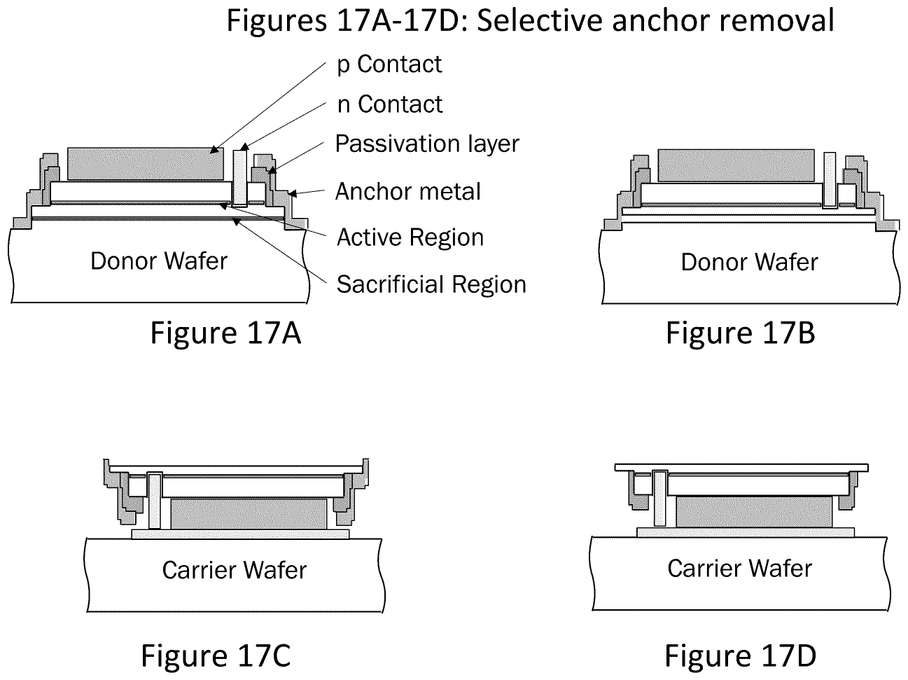

After the die has been transferred, it may be desirable or necessary to remove the anchor features. There are several ways that this can be accomplished. For example, a selective wet etch of the anchor material can remove the anchors without damaging any of the desirable device layers or the epitaxial material. One example workflow is illustrated in FIGS. 17A-17D, which are simplified cross sectional diagrams illustrating a process of selective anchor removal in accordance with an embodiment. In this example, the epitaxial material is prepared for transfer, including forming of p-contacts, n-contacts, passivation layers, and anchor metals by performing steps that may include an active region exposure etch and a sacrificial region exposure etch. Common metals that may be included for the gallium and nitrogen containing die include Pd, Al, Au, Ti, Pt, and others. Passivation layer materials can include SiO2, Al2O3, SiN, AlN, AlON, and others. In this example, TiW is selected as the anchor metal material, but alternative anchor metal materials including Ti, Al, W, SiO2, SiN, Ni, Cr, may be used in some embodiments. After the die is prepared, the sacrificial region is etched, followed by bonding and transfer to the carrier wafer. After transfer the anchors are removed by a wet etch process. In this example, a Ti-Tungsten TiW-30 etchant, a commercially available product from Trasense Company, is used to remove the TiW anchors. This wet etchant is selected for compatibility with all metals in the device structure, and in this case it will not etch Pd, Au, Al, or Al2O3. Alternate wet etchants with selectivity to common metals include, but are not limited to HF, buffered HF, Ti etchant TFT, H2O2, Ni etchant type TFB, chromium etchant, and the like. An alternative method to preventing unwanted etching during anchor removal is to cap an etching-susceptible layer with a non-susceptible layer to prevent the etchant from coming in contact with the etching-susceptible layer. In addition to wet etching processes, selective anchor removal can be performed by dry etching methods as well. These dry etching methods can be chemically selective, or masking using photoresist may be used to avoid unwanted material removal.

As described herein, the die on the donor wafers may be arranged with a first set of spacings or pitch, and then they may be transferred to the carrier wafer at a second pitch that could be larger than the first set of spacings or pitch. This configuration is referred to as die expansion since the transferred die have a larger or expanded pitch on the carrier wafer than the first pitch on the donor wafer. This die expansion enables increased epi and donor substrate area utilization for improved cost and manufacturing efficiency. In addition, since some embodiments enable a direct wafer to wafer bond process to transfer die from the donor to the carrier wafer in a single step, a massively parallel or ultra-massively parallel transfer of epitaxial die to the carrier wafer may be provided.

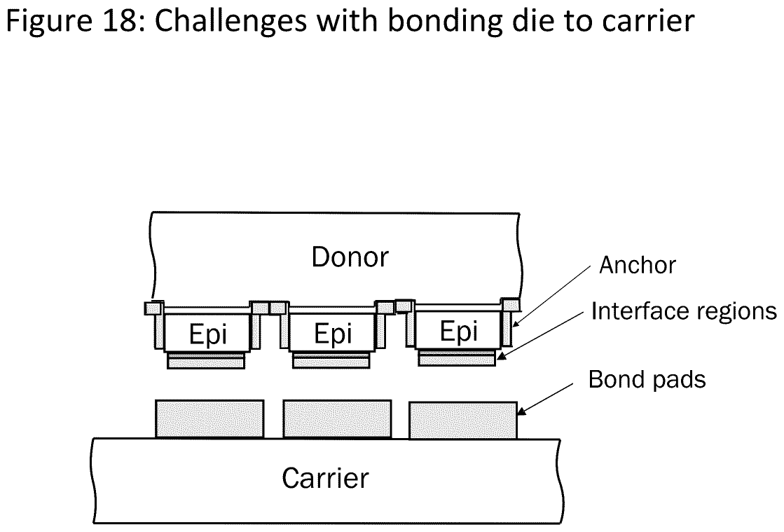

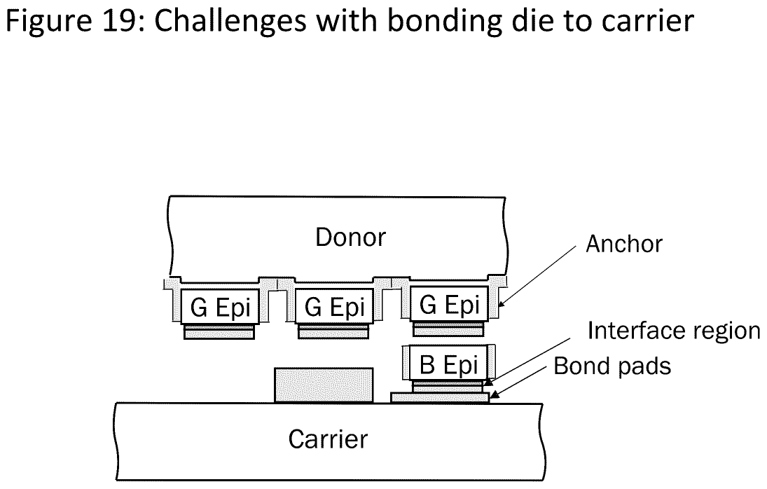

FIGS. 18-19 are simplified cross sectional diagrams illustrating some of the challenges with bonding die to a carrier wafer in a transfer process. The challenges include unintentionally bonding adjacent die from the donor wafers to the carrier wafer. This kind of defect or process malfunction will arise if adjacent die to the intended die on the donor wafer contact the bond pads on the carrier wafer and undergo the bonding process. This challenge is illustrated in FIG. 18, where a center die is targeted for bonding to the carrier wafer, but adjacent die on the left and right will contact corresponding bond pads on the carrier wafer. Another challenge is encountered when bonding die from the second, third, or any subsequent donor wafers after the first die are transferred to the carrier. The challenge in this case is mechanical interference between the die that have already been bonded to the carrier wafer and the die on the second and subsequent donor wafers that are adjacent to the die intended to be bonded as illustrated in FIG. 19. In FIG. 19, the center G die is targeted for bonding to the carrier wafer, but an adjacent G die will collide with an already transferred B die before the center G die contacts the bond pad on the carrier wafer. If there are already bonded die on the carrier wafer whose locations are spatially overlapping with die on the donor wafer, there will be a collision between the die during the bonding process. This may impact both the carrier wafer with the bonded die and the donor wafer with the die that are being transferred.

In an embodiment, a bonding prevention layer may be selectively formed on the donor wafer and/or the carrier wafer so die on the donor wafer that are not being transferred (or are not intended to be transferred) do not bond to bond pads on the carrier wafer. For example, the bonding prevention layer may be formed on the interface regions of some die on the donor wafer so that the interface regions of those die do not bond to the carrier wafer (or do not bond to bond pads on the carrier wafer). Similarly, the bonding prevention layer may be formed on the bond pads of the carrier wafer to prevent them from bonding with die on the donor wafer. The bonding prevention layers may be any material that prevents a bond from forming with the bond material. For example, a dielectric layer may be used as a bonding prevention layer for a metal bond material in some embodiments.

In some embodiments, various measures can be utilized to preferentially prevent certain die from bonding or sticking to the carrier wafer according to a predetermined sequence. In one example, a layer of non-stick material could be deposited onto either the carrier wafer bond pads or to interface regions of the die to prevent certain die on the donor wafers from bonding to the carrier wafer. In this embodiment, various materials can be used to prevent bonding or sticking such as polymer materials like photoresist that can be patterned on the donor wafer or carrier wafer with an expose and develop process. After the bonding step, the polymer material can be removed with a stripping or developing agent. This sequence can be repeated for subsequent bonding steps to achieve desired bonding. Other materials can also be used such as waxes, liquids, dielectrics, ceramics, or other types of materials that prevent bonding or sticking.

In yet another embodiment, die on the donor wafer can be preferentially prevented from bonding to the carrier wafer by controlling the strength of anchor regions or controlling the attachment strength of the die to the donor wafer. This can be achieved by using adhesives such as polymers that can be preferentially patterned on the donor wafer such that they are only contained in regions where the die are not intended to be released from the donor wafer. In another embodiment, metal, dielectric, plastic, or other materials are used for maintaining die attachment to the donor wafer, and they are specifically designed for a certain attachment strength to enable the die to transfer to a carrier wafer in an intended sequence. Of course, other means of modulating attachment strength of the die to the donor wafer can be deployed, and the above examples are not intended to be limiting.

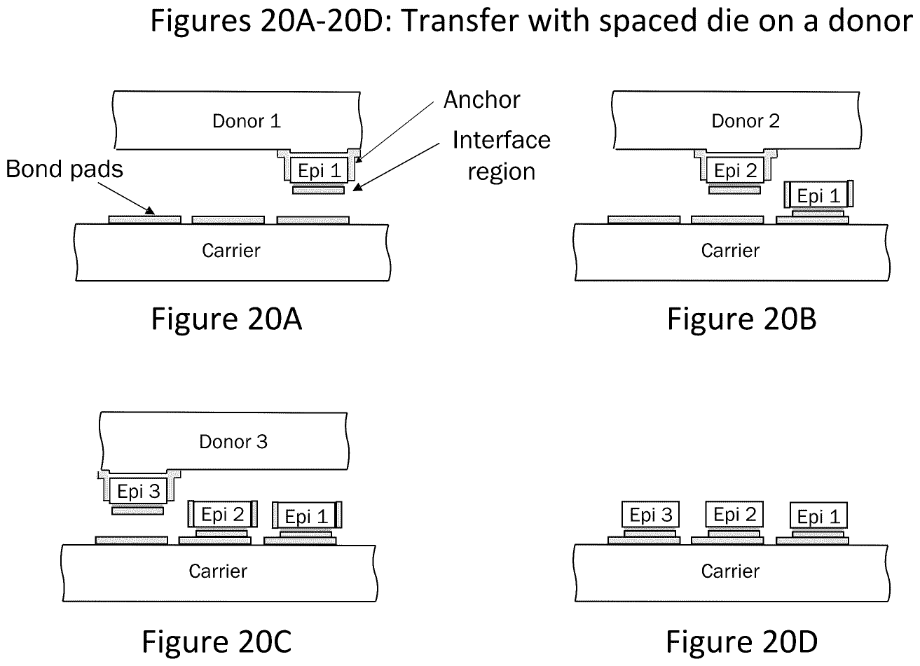

FIGS. 20A-20D are simplified cross sectional diagrams illustrating a process for transferring die having a large pitch on donor substrates to a carrier substrate at a smaller pitch in accordance with an embodiment. This embodiment may overcome some of the challenges described above where unintended die from the donor wafer may inadvertently bond to the carrier wafer or where already bonded die on the carrier wafer may inadvertently collide with die on the donor wafer. In some embodiments, die expansion may not be necessary and the die can be transferred from the donor wafers at a first pitch to the carrier at the same pitch or a smaller pitch. In this embodiment, the space between adjacent die on the donor wafers is sufficient to avoid having die on the donor wafer bond to the carrier wafer and sufficient to avoid interference with the already bonded die on the carrier wafer. In this embodiment, the pitch on donor wafer for a particular die may be equal to the pitch on the carrier wafer for that particular die. This process is illustrated in FIGS. 20A-20D, where a first die Epi 1 is bonded to the carrier wafer, a second die Epi 2 is bonded to the carrier wafer, and a third die Epi 3 is bonded to the carrier wafer. Each of the die Epi 1, Epi 2, and Epi 3 may represent sets of dies that are transferred simultaneously or sequentially from a donor wafer to the carrier wafer. Of course, this sequence is merely an example, as there could be other orders, sequences, geometries, spatial arrangements, or processes for this approach according to the various embodiments. One benefit of this process is that it is simple and minimizes process steps on the carrier and donor wafers. One disadvantage is that it does not enable die expansion, so it does not maximize the use of the epi and substrate area on the donor wafer.

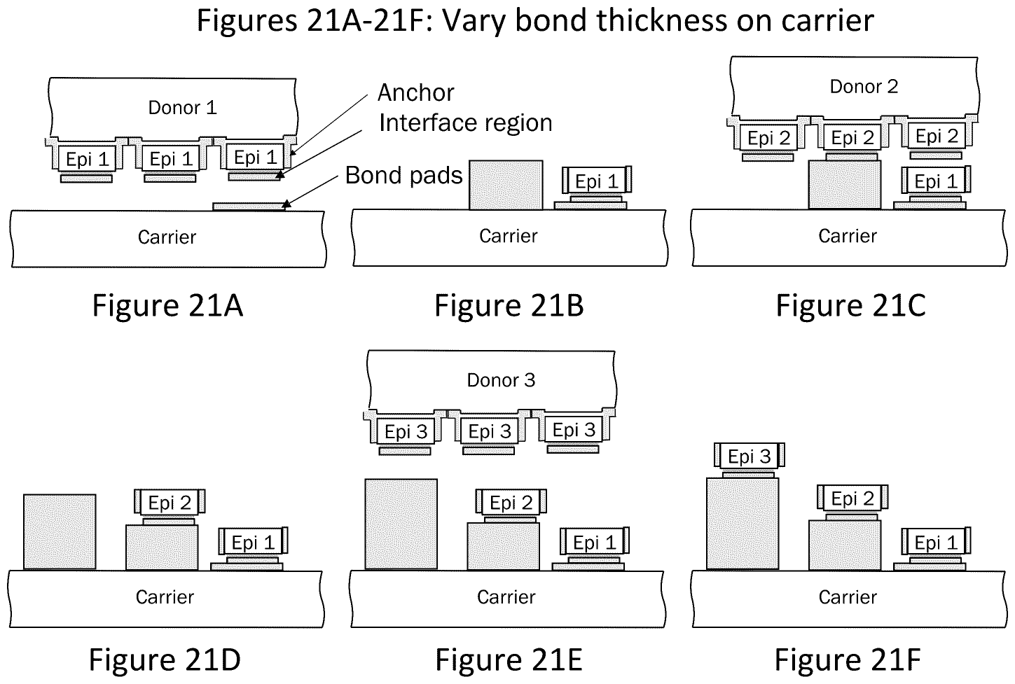

FIGS. 21A-21F are simplified cross sectional diagrams illustrating a process for transferring die from donor substrates to a carrier substrate by varying bond pad thickness on the carrier substrate in accordance with an embodiment. In this alternative embodiment, the bond metal on the carrier wafer is varied in thickness and deposited in subsequent steps. In this approach, both issues of adjacent die on the donor wafer inadvertently sticking to the carrier wafer and adjacent die on the donor wafer colliding with already bonded die on the carrier wafer can be avoided. This is accomplished by varying the bond metal thickness or some other material thickness making up the bond pad height on the carrier wafer. The bond pads with different thicknesses may be subsequently formed on the carrier wafer after the preceding die transfer step. This is illustrated in FIGS. 21A-21F. In this example, after the first set of die represented by Epi 1 are transferred to the first set of bond pads on the carrier wafer, a second set of bond pads are formed on the carrier wafer. The second set of bond pads are taller in height than the first bond pad plus the first die Epi 1 that was already transferred. The bond pads can be created by a deposition process, a plating process, or some other process to form a bond pad comprised of a metal or other material like a dielectric, ceramic, or polymer. The second set of bond pads are thick enough that a second set of die represented by Epi 2 can be bonded to the second bond pads without adjacent die sticking to the carrier wafer or colliding with already bonded die on the carrier wafer such as the first die Epi 1. Subsequently, after the second set of die represented by Epi 2 are transferred to the second set of bond pads on the carrier wafer, a third set of bond pads are formed on the carrier wafer. The third set of bond pads are taller in height than the second bond pad plus the second die Epi 2 that was already transferred to the carrier wafer. The third set of bond pads are thick enough that a third set of die represented by Epi 3 can be bonded to the third bond pads without adjacent die sticking to the carrier wafer or colliding with already bonded die on the carrier wafer. This sequence can be repeated n times where n can be any integer number. Each of the die Epi 1, Epi 2, and Epi 3 may represent sets of dies that are transferred simultaneously or sequentially from a donor wafer to the carrier wafer. The illustrations in FIGS. 21A-21F are merely examples and are not intended to be limiting since there could be other sequences and arrangements according to the embodiments described herein. It should be appreciated that a different number of donor substrates (more or less) may be used in some embodiments.

One advantage of this embodiment where the bond pad height is varied on the carrier wafer for each set of die is that it allows dense packing of die on the donor wafers and die expansion for maximum use of the valuable epi and substrate area. One disadvantage is that it requires subsequent depositions of metal bond pads or other material on the carrier wafer after each color die is bonded. Moreover, it may also necessitate tall bonding pads depending on epi thickness so that the ending topology can be high. If the epi stack thickness of the die that are transferred can be maintained at a minimal level, the topology can be minimized. For example, if the transferred epi thickness or height is less than 0.25 um, less than 0.5 um, less than 1.0 um, or less than 2.0 um, the topology variation can be minimized. There are several techniques that can be used to vary the bond pad height on the carrier wafer. In one approach, a thick metal is deposited or plated using techniques such as e-beam evaporation, thermal evaporation, sputtering, plating, or the like. The metal may be gold, copper, aluminum, silver, molybdenum, or any other metal. In some configurations, the bond pad height is created with materials other than metals such as oxides, dielectrics, ceramics, polymers, semiconductors, or other materials. Of course, there can be many different methods used to achieve the varied height of bond pads and the configurations described here are not intended to be limiting.

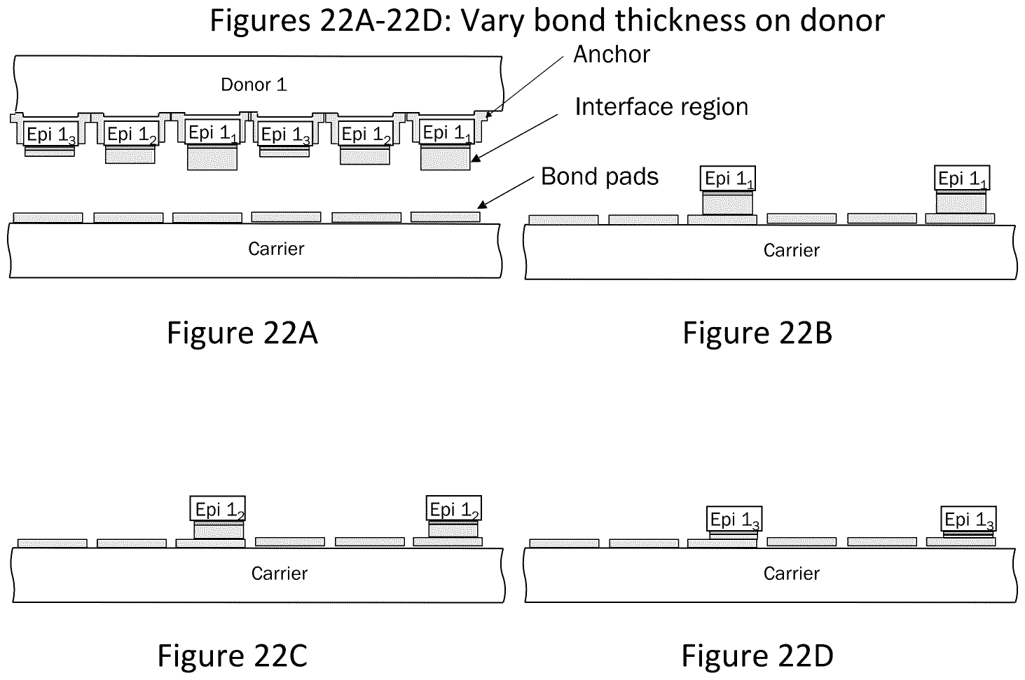

FIGS. 22A-22D are simplified cross sectional diagrams illustrating a process for transferring die from donor substrates to a carrier substrate by varying die height in accordance with an embodiment. In this embodiment, the bond metal (or interface region) thickness or thickness of another layer or material on the donor wafer die is varied to create different heights of the different sets of die to be transferred. Incrementally increasing heights of the sets of die on the donor wafer will prevent inadvertent sticking or bonding of unintended die to the carrier wafer. In this embodiment, the thickness or height variation of the die on the donor wafer is selected to prevent the adjacent die on the donor wafer from inadvertently bonding to adjacent bond pads on the carrier wafer. This method is illustrated in FIGS. 22A-22D, where a first set of die Epi 1₁ that are the tallest with the thickest bond metal or other material are bonded to the carrier wafer in a first bonding step. Since there is vertical clearance between the bond pads on the other die and the bond pads on the carrier wafer, the second and third set of die Epi 1₂ and Epi 1₃ are prevented from inadvertently bonding to the carrier in the first step intended to bond the first set of die Epi 1₁. Then, in the second bonding step, the second set of die Epi 1₂ with the second thickest metal or other material are bonded to a second carrier wafer or to a different region on the first carrier wafer. In the third bonding step, the third set of die Epi 1₃ with the third thickest metal or other material are bonded to a third carrier wafer or to a different region on the first or second carrier wafers. Of course, this process can be extended to a fourth thickness or height which is less than the third thickness or height, fifth thickness or height which is less than the fourth thickness or height, and an N thickness or height which is less than an N−1 thickness of the bond metal or other material on the donor wafer so that a third set of die, a fourth set of die, or an Nth set of die can be bonded to the same or a different carrier wafer in subsequent steps. Some embodiments combine variances in die height with variances in bond pad thickness as explained with regard to FIGS. 21A-21F. In these embodiments, die height and/or bond pad thickness may be varied to provide vertical clearance to avoid inadvertent bonding and inadvertent collisions. Of course, the illustration of FIGS. 22A-22D are merely for example purposes. One benefit of this process is that it enables close packing of the die with a small pitch on the donor wafer and then a selective transfer to the carrier wafer at an expanded pitch. In short, this approach can enable die expansion from the donor wafer to the carrier wafer. One disadvantage is the extra processing required to create the sets of die having different heights on the donor wafers. Also, with only incrementally taller die on the carrier wafer, this process may not be sufficient to avoid collisions between adjacent die on the donor wafer and the already bonded die on the carrier wafer.

There are several techniques that can be used to vary the die height on the donor wafers according to the embodiments described herein. In one approach, thick metal is deposited or plated to different heights on the different sets of dies using techniques such as e-beam evaporation, thermal evaporation, sputtering, plating, or the like. The metal can be gold, copper, aluminum, silver, molybdenum, or any other metal. In another approach a thickness of the epi material is varied. In some configurations, the height difference between the different set of dies is created with other materials such as oxides, dielectrics, ceramics, polymers, semiconductor materials, or the like. Of course, there can be many different methods used to achieve the varied die height, and the configurations described herein are not intended to be limiting.

In a further embodiment where die height on the donor wafer is varied, the bond metal thickness or thickness of another layer or material is varied to a more extreme level to create substantially different heights of the different sets of die on the donor wafers that are bonded to the carrier wafer subsequent to the first set of die being bonded to the carrier wafer. In this embodiment, the variation in the die height is sufficient to create enough vertical clearance to avoid both inadvertent sticking or bonding of the unintended die and collisions or mechanical interference between the adjacent die on the donor wafer and already bonded die on the carrier wafer. In this embodiment, the thickness or height variation of the second set of die on the second and successive donor wafers is sufficiently high to enable full vertical clearance of the die that have already been bonded to the carrier wafer. Thus, in this embodiment, the height difference between the different sets of die on the donor wafers not only prevents the adjacent die on the donor wafers from inadvertently bonding to adjacent bond pads on the carrier wafer, but the height difference also prevents the adjacent die on the donor wafers from contacting the die that are already bonded to the carrier.

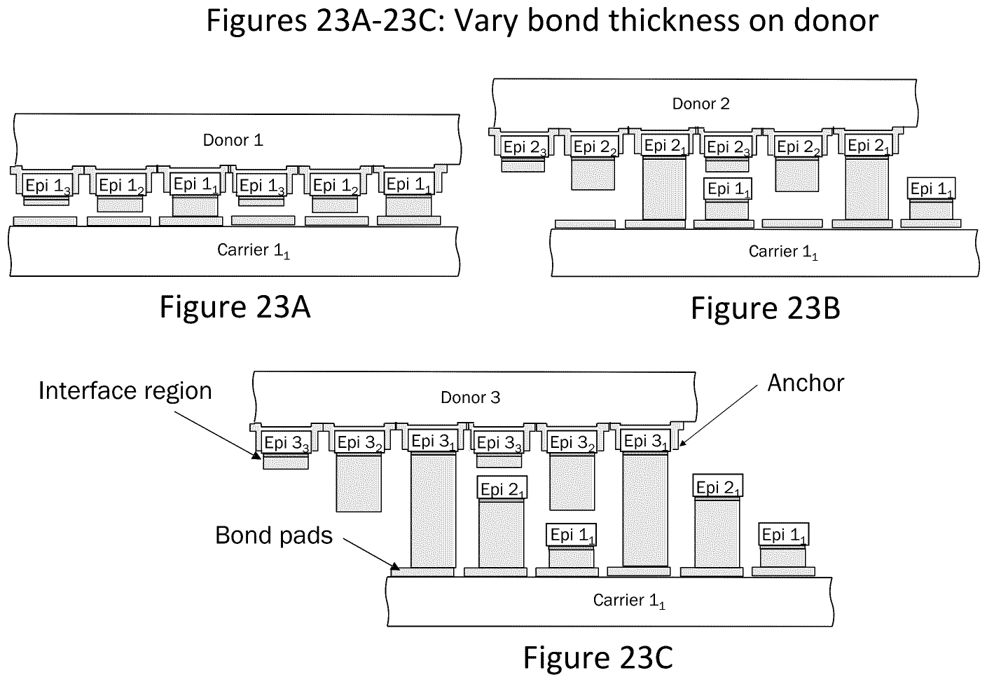

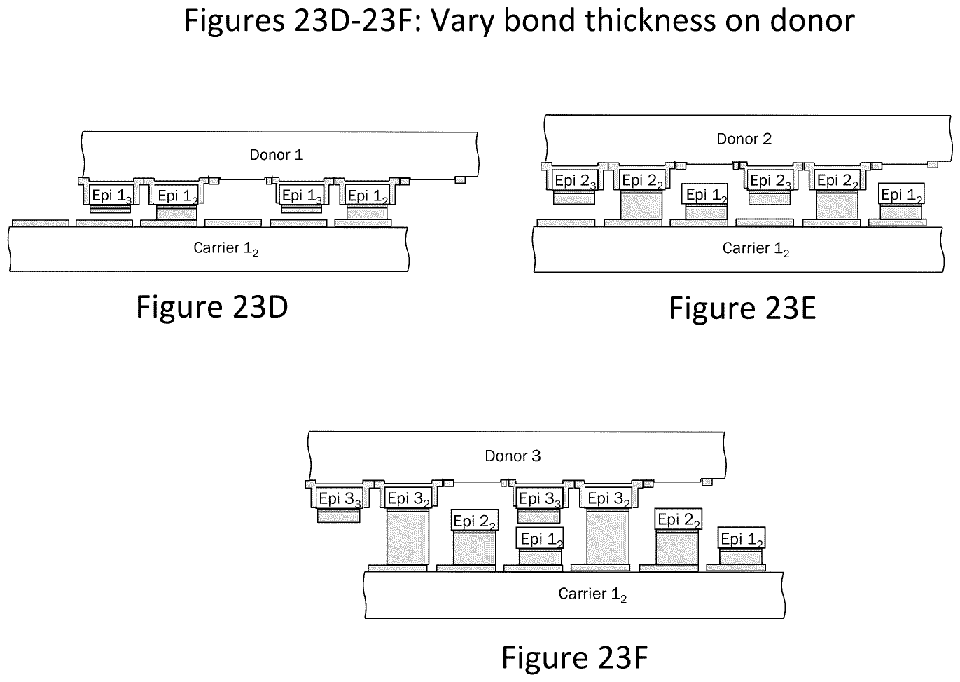

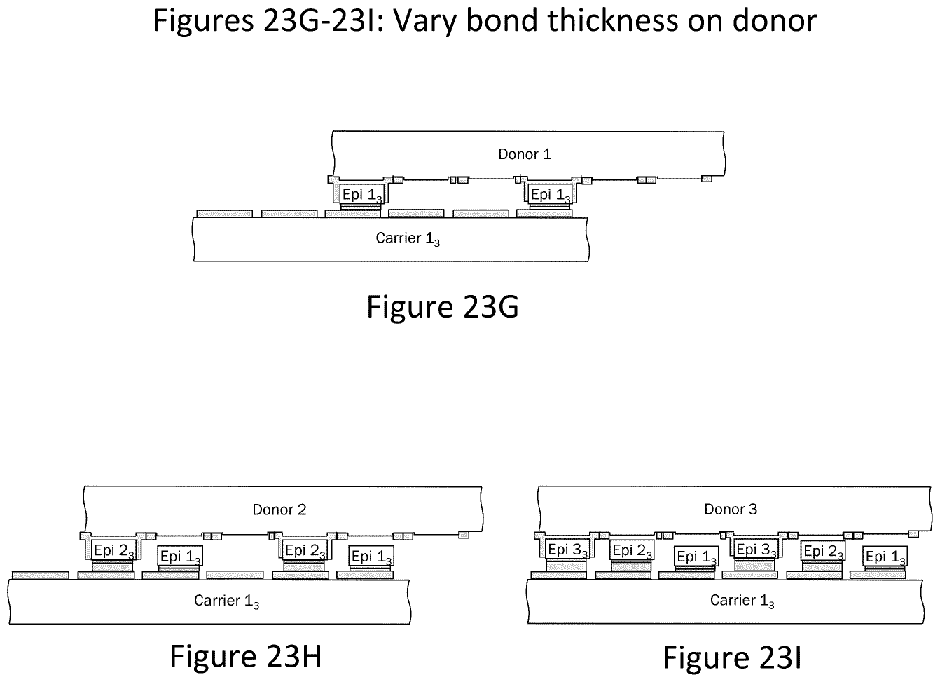

An example of this embodiment is shown in FIGS. 23A-23I. These figures are simplified cross sectional diagrams illustrating a process for transferring die from donor substrates to a carrier substrate by varying die height. As shown in FIG. 23A, there are three sets of die (Epi 1₁, Epi 1₂, Epi 1₃) on a first donor wafer (Donor 1) that have varying heights with different thicknesses of bond metals or other materials. The first set of die Epi 1₁ with the tallest height are bonded to a first carrier wafer (Carrier 1₁). The die height on Donor 1 is configured to be tall enough such that adjacent die do not interfere with the other bond pads on Carrier 1₁. FIG. 23B shows three sets of die (Epi 2₁, Epi 2₂, Epi 2₃) on a second donor wafer (Donor 2) that have varying heights with different thicknesses of bond metals or other materials. The first set of die Epi 2₁ with the tallest height from Donor 2 are bonded to Carrier 1₁. The die height on Donor 2 is configured to be tall enough such that the adjacent die Epi 2₂, Epi 2₃ on Donor 2 do not interfere with the first set of die Epi 1₁ from Donor 1 that have already been bonded to Carrier 1₁. FIG. 23C shows three sets of die (Epi 3₁, Epi 3₂, Epi 3₃) on a third donor wafer (Donor 3) that have varying heights with different thicknesses of bond metals or other materials. The first set of die Epi 3₁ with the tallest height from Donor 3 are bonded to Carrier 1₁. The die height on Donor 3 is configured to be tall enough such that the adjacent die Epi 3₂, Epi 3₃ on Donor 3 do not interfere with the first set of die Epi 1₁ from Donor 1 and the first set of die Epi 2₁ from Donor 2 that have already been bonded to Carrier 1₁.

FIG. 23D shows that a second set of die Epi 1₂ with a second tallest height from Donor 1 are bonded to a second carrier wafer or a different area on the first carrier wafer (Carrier 1₂). The die height on Donor 1 is configured to be tall enough such that adjacent die do not interfere with the other bond pads on Carrier 1₂. FIG. 23E shows that a second set of die Epi 2₂ with a second tallest height from Donor 2 are bonded to Carrier 1₂. The die height on Donor 2 is configured to be tall enough such that the adjacent die Epi 2₃ on Donor 2 do not interfere with the second set of die Epi 1₂ that have already been bonded to Carrier 1₂. FIG. 23F shows that a second set of die Epi 3₂ with a second tallest height from Donor 3 are bonded to Carrier 1₂. The die height on Donor 3 is configured to be tall enough such that the adjacent die Epi 3₂ on Donor 3 do not interfere with the second set of die Epi 1₂ from Donor 1 and the second set of die Epi 2₂ from Donor 2 that have already been bonded to Carrier 1₂.

FIG. 23G shows that a third set of die Epi 1₃ with a third tallest height from Donor 1 are bonded to a third carrier wafer or a different area on the first carrier wafer (Carrier 1₃). FIG. 23H shows that a third set of die Epi 2₃ with a third tallest height from Donor 2 are bonded to Carrier 1₃. FIG. 23I shows that a third set of die Epi 3₃ with a third tallest height from Donor 3 are bonded to Carrier 1₃. Of course, FIGS. 23A-23I provide an example sequence according to an embodiment, but there could be many other sequences and orders of operations consistent with the principles described herein.

In the embodiment illustrated in FIGS. 23A-23I, the different donor wafers Donor 1, Donor 2, Donor 3 may each have the same or different die. It should be appreciated that a different number of donor substrates (more or less) may be used in some embodiments. This embodiment is not limited to three donor wafers and instead includes any number of donor wafers. Also, the embodiment illustrated in these figures can be extended to a fourth die height which is less than the third die height, a fifth die height which is less than the fourth die height, and an Nth die height which is less than an N−1 die height on each donor wafer Donor 1, Donor 2, Donor 3 so that a fourth set of die, fifth set of die, or an Nth set of die can be bonded to different carrier wafers or to different areas on the same carrier wafer in subsequent steps. Some embodiments combine variances in die height with variances in bond pad thickness as explained with regard to FIGS. 21A-21F. In these embodiments, die height and/or bond pad thickness may be varied to provide vertical clearance to avoid inadvertent bonding and inadvertent collisions. One benefit to this process is that it enables close packing of the die with a small pitch on the donor wafers and a selective transfer to the carrier wafer at an expanded pitch. In short, this approach can enable die expansion. One disadvantage to this process is the extra processing required to create the different die heights on the donor wafers.

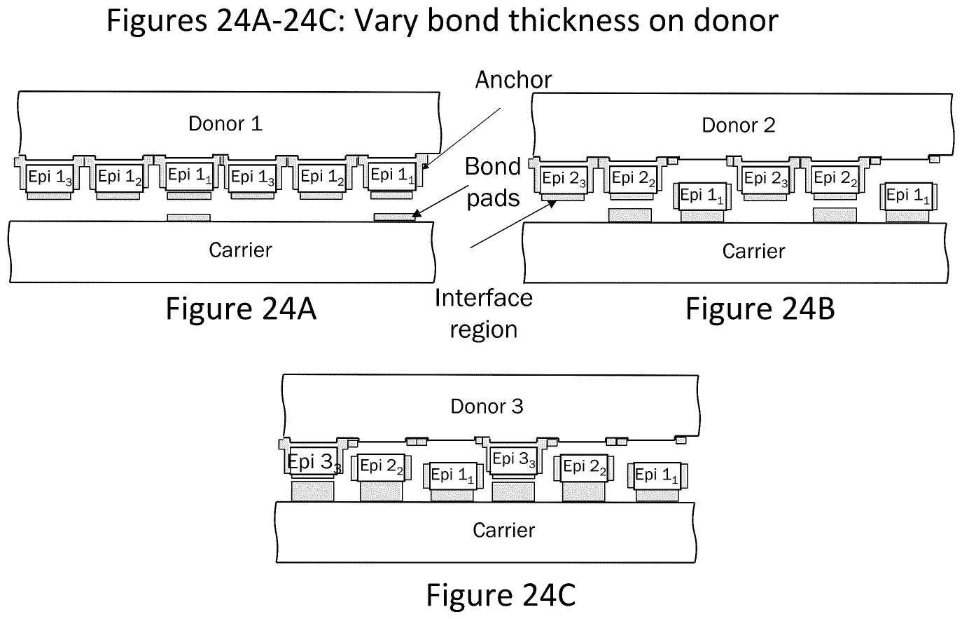

FIGS. 24A-24C are simplified cross sectional diagrams illustrating a round robin sequence for transferring die from donor substrates to a carrier substrate in accordance with an embodiment. In this embodiment, a kind of a round robin workflow sequence with the donor wafers and carrier wafers is implemented to avoid having adjacent die on the donor wafer collide with die that have already been bonded to the carrier wafer. In this example of sequencing, there may be three different carrier wafers or three different regions or areas on the same carrier wafer. In order to achieve die expansion and to avoid both adjacent die from the donor wafer sticking to the carrier wafer and to prevent collisions or mechanical interference between the adjacent die on the donor wafer and die already bonded to the carrier, the round robin sequencing may be combined with an additional technique such as sequentially forming the bond pads on the carrier wafer, similar to the process of FIGS. 21A-21F, or by varying the height of the different sets of die on the donor wafers, similar to the process of FIGS. 22A-22D or FIGS. 23A-23I. The specific approach shown in FIGS. 24A-24C utilizes the successive formation of the bond pads with the appropriate height, but this is just for illustration and of course other methods could be combined with the round robin workflow approach.

In the example shown in FIGS. 24A-24C, the sequence is comprised of three different carrier wafers or three different regions on the same carrier wafer. An objective of this round robin sequence is to utilize the “gaps” that are formed on the donor wafers where there are missing die as the different sets of die are bonded from the donor wafers to the carrier wafers. By aligning these gaps on the donor wafers with the die that are already bonded to the carrier wafer, there is sufficient clearance to prevent adjacent die on the donor wafers from colliding with die that are already bonded to the carrier wafer. As shown in FIGS. 24A-24C, a first set of die Epi 1₁ is bonded from Donor 1 to the first carrier wafer, a second set of die Epi 2₂ is bonded from Donor 2 to a second carrier wafer or another area on the first carrier wafer, and a third set of die Epi 3₃ is bonded from Donor 3 to a third carrier wafer or another area on the first carrier wafer. In another bonding sequence, a second set of die Epi 1₂ is bonded to the carrier wafer, a third set of die Epi 2₃ is bonded to the carrier wafer, and a first set of die Epi 3₁ is bonded to the carrier wafer. In yet another bonding sequence, a third set of die Epi 1₃ is bonded to the carrier wafer, a first set of die Epi 2₁ is bonded to the carrier wafer, and a second set of die Epi 3₂ is bonded to the carrier wafer.

It should be understood that the method described above and partially illustrated in FIGS. 24A-24C is merely one example of this round robin bonding sequence. Other sequences and number of donor wafers and carrier wafers may be used in accordance with the principles described. There are many configurations, sequences, arrangements, spatial layouts, geometries, and processes that could utilize this round robin approach. For example, FIGS. 24A-24C show a cross sectional view of die arranged in a side-by-side or linear configuration. This linear configuration is one such arrangement for die in an array, but of course there could be others. In this linear approach, there is a horizontal or vertical translational bonding method to execute the round robin bonding sequence. In other configurations, the sequence could be performed using a rotational method where the bonding from the donor wafers to the carrier wafer occurs with rotational symmetry. It should be appreciated that a different number of donor substrates (more or less) may be used in some embodiments.

As used herein, the term GaN substrate is associated with Group III-nitride based materials including GaN, InGaN, AlGaN, or other Group III containing alloys or compositions that are used as starting materials. Such starting materials include polar GaN substrates (i.e., substrate where the largest area surface is nominally an (h k l) plane wherein h=k=0, and l is non-zero), non-polar GaN substrates (i.e., substrate material where the largest area surface is oriented at an angle ranging from about 80-100 degrees from the polar orientation described above towards an (h k l) plane wherein l=0, and at least one of h and k is non-zero) or semi-polar GaN substrates (i.e., substrate material where the largest area surface is oriented at an angle ranging from about +0.1 to 80 degrees or 110-179.9 degrees from the polar orientation described above towards an (h k l) plane wherein l=0, and at least one of h and k is non-zero).

While the present invention has been described in terms of specific embodiments, it should be apparent to those skilled in the art that the scope of the present invention is not limited to the embodiments described herein. For example, features of one or more embodiments of the invention may be combined with one or more features of other embodiments without departing from the scope of the invention. The specification and drawings are, accordingly, to be regarded in an illustrative rather than a restrictive sense. Thus, the scope of the present invention should be determined not with reference to the above description but should be determined with reference to the appended claims along with their full scope of equivalents.

What is claimed is:

1. A system with optical interconnects, comprising:
a first optical transceiver comprising:
a first array of micro light emitting diodes (LEDs) arranged on a first carrier substrate, each micro LED of the first array of micro LEDs including a first epitaxial material different from a material of the first carrier substrate, the first epitaxial material comprising at least an n-type gallium and nitrogen containing region, a light emitting gallium and nitrogen containing region configured to emit electromagnetic radiation, and a p-type gallium and nitrogen containing region;
a first array of photodetectors (PDs) configured to detect the electromagnetic radiation;
a first driver integrated circuit (IC) electrically coupled to the first array of micro LEDs and configured to individually drive each micro LED of the first array of micro LEDs to generate first data signals using the electromagnetic radiation;
a second optical transceiver comprising:
a second array of micro LEDs arranged on a second carrier substrate, each micro LED of the second array of micro LEDs including a second epitaxial material different from a material of the second carrier substrate, the second epitaxial material comprising at least an n-type gallium and nitrogen containing region, a light emitting gallium and nitrogen containing region configured to emit electromagnetic radiation, and a p-type gallium and nitrogen containing region;
a second array of PDs configured to detect the electromagnetic radiation;
a second driver IC electrically coupled to the second array of micro LEDs and configured to individually drive each micro LED of the second array of micro LEDs to generate second data signals using the electromagnetic radiation;
at least one multicore fiber cable arranged to optically couple the first array of micro LEDs with the second array of PDs so that the first data signals generated by the first array of micro LEDs are transmitted to the second array of PDs, and to optically couple the second array of micro LEDs with the first array of PDs so that the second data signals generated by the second array of micro LEDs are transmitted to the first array of PDs.

2. The system of claim 1 wherein at least some of the micro LEDs of the first array of micro LEDs are configured to emit the electromagnetic radiation at a first wavelength in a range of between 400 nm to 480 nm or between 500 nm to 560 nm, and at least some of the micro LEDs of the second array of micro LEDs are configured to emit the electromagnetic radiation at a second wavelength in the range of between 400 nm to 480 nm or between 500 nm to 560 nm.

3. The system of claim 1 wherein the first carrier substrate and the second carrier substrate are each selected from a silicon wafer, a sapphire wafer, a glass wafer, a glass ceramics wafer, a quartz wafer, a high purity fused silica wafer, a silicon carbide wafer, an aluminum nitride wafer, a germanium wafer, an aluminum oxynitride wafer, a gallium arsenide wafer, a diamond wafer, a gallium nitride wafer, an indium phosphide wafer, a flexible member, a circuit board member, a silicon wafer with CMOS circuitry, silicon on insulator (SOI) wafer, or a gallium nitride on silicon wafer.

4. The system of claim 1 wherein the at least one multicore fiber cable optically couples each micro LED of the first array of micro LEDs with one corresponding PD of the second array of PDs, and optically couples each micro LED of the second array of micro LEDs with a corresponding PD of the first array of PDs.

5. The system of claim 1 wherein the at least one multicore fiber cable includes a first multicore fiber cable and a second multicore fiber cable, first multicore fiber cable optically coupling each micro LED of the first array of micro LEDs with one corresponding PD of the second array of PDs, and the second multicore fiber cable optically coupling each micro LED of the second array of micro LEDs with a corresponding PD of the first array of PDs.

6. The system of claim 1 wherein the first array of micro LEDs and the first array of PDs are part of a first interdigitated array of micro LEDs and PDs, and the second array of micro LEDs and the second array of PDs are part of a second interdigitated array of micro LEDs and PDs.

7. The system of claim 1 further comprising a first IC electrically coupled to the first driver IC, and a second IC electrically coupled to the second driver IC, wherein the first driver IC is configured to drive the first array of micro LEDs to generate the first data signals based on first electrical signals received from the first IC, and the second driver IC is configured to drive the second array of micro LEDs to generate the second data signals based on second electrical signals received from the second IC.

8. The system of claim 7 wherein the first driver IC is configured to convert the second data signals received at the first array of PDs to first electrical signals and to provide the first electrical signals to the first IC, the second driver IC is configured to convert the first data signals received at the second array of PDs to second electrical signals and to provide the second electrical signals to the second IC.

9. The system of claim 1 wherein each PD of the first array of PDs includes a first gallium and nitrogen containing material, and each PD of the second array of PDs includes a second gallium and nitrogen containing material, and wherein the first array of PDs is arranged on the first carrier substrate, and the second array of PDs is arranged on the second carrier substrate.

10. The system of claim 1 further comprising an interposer substrate, wherein the first optical transceiver and the second optical transceiver are coupled to the interposer substrate.

11. The system of claim 1 further comprising a first optical interconnect configured to couple the first optical transceiver to the at least one multicore fiber cable, and a second optical interconnect configured to couple the second optical transceiver to the at least one multicore fiber cable.

12. The system of claim 1 further comprising:
a first interposer electrically coupled to the first optical transceiver;
a first plurality of ICs electrically coupled to the first interposer;
a second interposer electrically coupled to the second optical transceiver; and
a second plurality of ICs electrically coupled to the second interposer;
wherein first electrical signals from the first plurality of ICs are transmitted to the first optical transceiver via the first interposer, and the first optical transceiver is configured to generate the first data signals based on the first electrical signals; and
wherein second electrical signals from the second plurality of ICs are transmitted to the second optical transceiver via the second interposer, and the second optical transceiver is configured to generate the second data signals based on the second electrical signals.

13. The system of claim 12 further comprising a printed circuit board (PCB), wherein the first interposer and the second interposer are coupled to the PCB.

14. The system of claim 1 wherein the first optical transceiver is part of a first server and the second optical transceiver is part of a second server, and the multicore fiber cable optically couples the first server to the second server.

15. The system of claim 1 wherein the first optical transceiver is part of a first server rack and the second optical transceiver is part of a second server rack, and the multicore fiber cable optically couples the first server rack to the second server rack.

16. A system with optical interconnects, comprising:
a first array of micro light emitting diodes (LEDs) arranged on a first carrier substrate, each micro LED of the first array of micro LEDs including a first epitaxial material different from a material of the first carrier substrate, the first epitaxial material comprising at least an n-type gallium and nitrogen containing region, a light emitting gallium and nitrogen containing region configured to emit electromagnetic radiation, and a p-type gallium and nitrogen containing region;
a first array of photodetectors (PDs) configured to detect the electromagnetic radiation;
a first driver integrated circuit (IC) electrically coupled to the first array of micro LEDs and configured to individually drive each micro LED of the first array of micro LEDs to generate first data signals using the electromagnetic radiation;
a second array of micro LEDs arranged on a second carrier substrate, each micro LED of the second array of micro LEDs including a second epitaxial material different from a material of the second carrier substrate, the second epitaxial material comprising at least an n-type gallium and nitrogen containing region, a light emitting gallium and nitrogen containing region configured to emit electromagnetic radiation, and a p-type gallium and nitrogen containing region;
a second array of PDs configured to detect the electromagnetic radiation;
a second driver IC electrically coupled to the second array of micro LEDs and configured to individually drive each micro LED of the second array of micro LEDs to generate second data signals using the electromagnetic radiation; and
at least one waveguide arranged to optically couple the first array of micro LEDs with the second array of PDs so that the first data signals generated by the first array of micro LEDs are transmitted to the second array of PDs, and to couple the second array of micro LEDs with the first array of PDs so that the second data signals generated by the second array of micro LEDs are transmitted to the first array of PDs.

17. The system of claim 16 wherein the at least one waveguide comprises a two-dimensional (2D) planar waveguide or a three-dimensional (3D) waveguide.

18. The system of claim 16 wherein the at least one waveguide comprises an optical fiber.

19. A system with optical interconnects, comprising:
a first integrated circuit (IC);
a first optical transceiver electrically coupled to the first IC, the first optical transceiver comprising:
a first array of micro light emitting diodes (LEDs) arranged on a first carrier substrate, each micro LED of the first array of micro LEDs including a first epitaxial material different from a material of the first carrier substrate, the first epitaxial material comprising at least an n-type gallium and nitrogen containing region, a light emitting gallium and nitrogen containing region configured to emit electromagnetic radiation, and a p-type gallium and nitrogen containing region;
a first array of photodetectors (PDs) configured to detect the electromagnetic radiation; and
a first driver IC electrically coupled to the first array of micro LEDs and configured to individually drive each micro LED of the first array of micro LEDs to generate first data signals using the electromagnetic radiation, the first data signals generated based on first electrical signals received from the first IC;
a second IC;
a second optical transceiver electrically coupled to the second IC, the second optical transceiver comprising:
a second array of micro LEDs arranged on a second carrier substrate, each micro LED of the second array of micro LEDs including a second epitaxial material different from a material of the second carrier substrate, the second epitaxial material comprising at least an n-type gallium and nitrogen containing region, a light emitting gallium and nitrogen containing region configured to emit electromagnetic radiation, and a p-type gallium and nitrogen containing region;
a second array of PDs configured to detect the electromagnetic radiation; and
a second driver IC electrically coupled to the second array of micro LEDs and configured to individually drive each micro LED of the second array of micro LEDs to generate second data signals using the electromagnetic radiation, the second data signals generated based on second electrical signals received from the second IC;
at least one multicore fiber cable arranged to optically couple the first array of micro LEDs with the second array of PDs so that the first data signals generated by the first array of micro LEDs are transmitted to the second array of PDs, and to couple the second array of micro LEDs with the first array of PDs so that the second data signals generated by the second array of micro LEDs are transmitted to the first array of PDs.

20. The system of claim 19 wherein the first IC comprises a plurality of first ICs, and the second IC comprises a plurality of second ICs.
